(19) United States
(12) Patent Application Publication
(10) Pub. No.: US 2024/0135180 A1
(43) Pub. Date: Apr. 25, 2024

(54) SYSTEMS OF NEURAL NETWORKS COMPRESSION AND METHODS THEREOF

(71) Applicant: Rutgers, The State University of New Jersey, New Brunswick, NJ (US)

(72) Inventors: Bo Yuan, New Brunswick, NJ (US); Miao Yin, New Brunswick, NJ (US)

(21) Appl. No.: 18/516,213

(22) Filed: Nov. 21, 2023

Related U.S. Application Data
(63) Continuation of application No. PCT/US22/30864, filed on May 25, 2022.
(60) Provisional application No. 63/193,692, filed on May 27, 2021.

(51) Int. Cl. G06N 3/08

(52) U.S. Cl. CPC G06N 3/08

(57) ABSTRACT

Systems and methods provide improved neural network compression by training, based on training data and an optimization problem, a deep neural network to produce a trained deep neural network by iteratively updating a weight matrix of the deep neural network according to, at each iteration, minimizing a rank value of the weight matrix until a memory capacity metric is satisfied, minimizing a loss function based on the training data and the weight matrix and updating the weight matrix, and terminating the iterations upon the loss function being minimized within the memory capacity metric. Tensor decomposition is used to compress the trained deep neural network based on the rank value and the weight matrix to obtain a trained tensor decomposition format deep neural network. The trained tensor decomposition format deep neural network is retrained with the training data to obtain a fine-tuned trained tensor decomposition format deep neural network.

### CLAIM TO PRIORITY

This application is a Continuation Application relating to and claiming the benefit of commonly-owned, co-pending PCT International Application No. PCT/US2022/030864, filed May 25, 2022, which claims priority to and the benefit of commonly-owned U.S. Provisional Application 63/193,692 filed on May 27, 2021, which is incorporated herein by reference in its entirety.

### STATEMENT REGARDING FEDERALLY SPONSORED RESEARCH OR DEVELOPMENT

This invention was made with government support under grant number 1955909 awarded by the National Science Foundation. The government has certain rights in the invention.

### FIELD OF THE TECHNOLOGY

The present disclosure generally relates to computer-based platforms and systems configured for neural network compression including tensor decomposition-based compression techniques for training and inferencing with tensorized neural networks and methods thereof.

### BACKGROUND

Deep Neural Network (DNNs) have widespread applications in many tasks, such as image classification, video recognition objective detection, and image caption. For most embedded and Internet-of-Things (IoT) systems, the sizes of DNN models are too large, thereby causing high storage and computational demands and severely hindering the practical deployment of DNNs.

### SUMMARY OF THE DISCLOSURE

This invention proposes a systematic framework for tensor decomposition-based model compression by applying an optimization technique including a dual problem approach, such as, e.g., Alternating Direction Method of Multipliers (ADMM). By formulating TT decomposition-based model compression as an optimization problem with constraints on tensor ranks, it leverages ADMM technique to systemically solve the optimization problem in an iterative way. During this procedure, the entire DNN model is trained in the original structure instead of tensor decomposed, but gradually enjoys the desired low tensor rank characteristics. The model may be decomposed to tensor decomposed and fine-tuned to finally obtain a high-accuracy tensor decomposed format DNN model.

In some aspects, the techniques described herein relate to a method including: receiving, by at least one processor, at least: i) a memory capacity metric defining a maximum memory size available; ii) a model identifier that identifies a deep neural network, the deep neural network including at least one weight matrix that is arranged in at least one layer and includes a plurality of weights; iii) a training data including a plurality of input data records and a plurality of ground truth data records; wherein each input data record is associated with a corresponding ground truth data record; wherein the corresponding ground truth data record defines a ground truth output; training, by the at least one processor, based on the training data and an optimization problem, the deep neural network to produce a trained deep neural network by iteratively updating the at least one layer of the deep neural network, at each iteration, with: a rank value representing a tensor rank to apply to the at least one weight matrix, and the plurality of weights of the at least one weight matrix upon decomposition to the tensor of the rank value; wherein the optimization problem is configured to: minimize the rank value at each iteration until the memory capacity metric is satisfied, minimize a loss function based at least in part on the training data and the plurality of weights, backpropagate the loss function to the plurality weights, and stop iteratively updating the at least one layer upon the memory capacity metric being satisfied and the loss function being minimized within the memory capacity metric; utilizing, by the at least one processor, a tensor-based decomposition to compress the trained deep neural network based at least in part on the rank value and the plurality of weights to obtain a trained tensor decomposition format deep neural network; training, by the at least one processor, the trained tensor decomposition format deep neural network based at least in part on the training data to obtain a fine-tuned trained tensor decomposition format deep neural network; and deploying, by the at least one processor, the fine-tuned trained tensor decomposition format deep neural network to at least one hardware device that satisfies the memory capacity metric.

In some aspects, the techniques described herein relate to a method, wherein the tensor-based decomposition includes at least one of: tensor train decomposition, tensor ring decomposition, singular value decomposition (SVD) higher-order singular value decomposition (HOSVD), Tucker decomposition, hierarchical Tucker decomposition, or block term decomposition.

In some aspects, the techniques described herein relate to a method, wherein the optimization problem includes a dual problem optimization method.

In some aspects, the techniques described herein relate to a method, wherein the dual problem optimization method includes dual ascent method (DAM).

In some aspects, the techniques described herein relate to a method, wherein the dual problem optimization method includes dual decomposition.

In some aspects, the techniques described herein relate to a method, wherein the dual problem optimization method Alternating Direction Method of Multipliers (ADMM).

In some aspects, the techniques described herein relate to a method, further including: determining, by the at least one processor, a minimum tensor rank based at least in part on the memory capacity metric; and terminating, by the at least one processor, the iteratively updating of the at least one layer of the deep neural network upon the rank value reaching the minimum tensor rank.

In some aspects, the techniques described herein relate to a method, wherein the deep neural network includes at least one of: a transformer, a multi-layer perceptron, a convolutional neural network, or a recurrent neural network.

In some aspects, the techniques described herein relate to a method, wherein the transformer includes at least one vision transformer.

In some aspects, the techniques described herein relate to a method, wherein the at least one hardware device includes an embedded internet-of-things (IoT) device.

In some aspects, the techniques described herein relate to a system including: at least one processor; and at least one non-transitory computer readable medium having software instructions stored thereon, wherein, upon execution of the software instructions, the at least one processor is configured to: receive at least: i) a memory capacity metric defining a maximum memory size available; ii) a model identifier that identifies a deep neural network, the deep neural network including at least one weight matrix that is arranged in at least one layer and includes a plurality of weights; iii) a training data including a plurality of input data records and a plurality of ground truth data records; wherein each input data record is associated with a corresponding ground truth data record; wherein the corresponding ground truth data record defines a ground truth output; train based on the training data and an optimization problem, the deep neural network to produce a trained deep neural network by iteratively updating the at least one layer of the deep neural network, at each iteration, with: a rank value representing a tensor rank to apply to the at least one weight matrix, and the plurality of weights of the at least one weight matrix upon decomposition to the tensor of the rank value; wherein the optimization problem is configured to: minimize the rank value at each iteration until the memory capacity metric is satisfied, minimize a loss function based at least in part on the training data and the plurality of weights, backpropagate the loss function to the plurality weights, and stop iteratively updating the at least one layer upon the memory capacity metric being satisfied and the loss function being minimized within the memory capacity metric; utilize a tensor-based decomposition to compress the trained deep neural network based at least in part on the rank value and the plurality of weights to obtain a trained tensor decomposition format deep neural network; train the trained tensor decomposition format deep neural network based at least in part on the training data to obtain a fine-tuned trained tensor decomposition format deep neural network; and deploy the fine-tuned trained tensor decomposition format deep neural network to at least one hardware device that satisfies the memory capacity metric.

In some aspects, the techniques described herein relate to a system, wherein the tensor-based decomposition includes at least one of: tensor train decomposition, tensor ring decomposition, singular value decomposition (SVD) higher-order singular value decomposition (HOSVD), Tucker decomposition, hierarchical Tucker decomposition, or block term decomposition.

In some aspects, the techniques described herein relate to a system, wherein the optimization problem includes a dual problem optimization system.

In some aspects, the techniques described herein relate to a system, wherein the dual problem optimization system includes dual ascent system (DAM).

In some aspects, the techniques described herein relate to a system, wherein the dual problem optimization system includes dual decomposition.

In some aspects, the techniques described herein relate to a system, wherein the dual problem optimization system Alternating Direction System of Multipliers (ADMM).

In some aspects, the techniques described herein relate to a system, wherein, upon execution of the software instructions, the at least one processor is further configured to: determine a minimum tensor rank based at least in part on the memory capacity metric; and terminate the iteratively updating of the at least one layer of the deep neural network upon the rank value reaching the minimum tensor rank.

In some aspects, the techniques described herein relate to a system, wherein the deep neural network includes at least one of: a transformer, a multi-layer perceptron, a convolutional neural network, or a recurrent neural network.

In some aspects, the techniques described herein relate to a system, wherein the transformer includes at least one vision transformer.

In some aspects, the techniques described herein relate to a system, wherein the at least one hardware device includes an embedded internet-of-things (IoT) device.

### BRIEF DESCRIPTION OF THE DRAWINGS

Various embodiments of the present disclosure may be further explained with reference to the attached drawings, wherein like structures are referred to by like numerals throughout the several views. The drawings shown are not necessarily to scale, with emphasis instead generally being placed upon illustrating the principles of the present disclosure. Therefore, specific structural and functional details disclosed herein are not to be interpreted as limiting, but merely as a representative basis for teaching one skilled in the art to variously employ one or more illustrative embodiments.

FIG. 1 illustrates a system for implementing an efficient dual problem optimization-based tensor decomposed format model in a resource constrained environment according to one or more embodiments of the present disclosure.

FIG. 2A illustrates a matrix via using the TT decomposition of its reshaped tensor in accordance with some embodiments of the present disclosure.

FIG. 2B illustrates a tensor decomposed inference scheme in accordance with some embodiments of the present disclosure.

FIG. 3 illustrates a converting computation on CONV layer to matrix multiplication in accordance with some embodiments of the present disclosure. Here H′=H−f+1 and W′=W−f+1.

FIG. 4 illustrates an example of redundant computations in conventional tensor decomposed inference scheme in accordance with some embodiments of the present disclosure.

FIG. 5 illustrates a partially paralleling the inputs in Stage-3 in accordance with some embodiments of the present disclosure. Redundant computations are partially reduced.

FIGS. 6A and 6B illustrate an example of compact tensor decomposed inference scheme in accordance with some embodiments of the present disclosure.

FIG. 7 illustrates an example 2-PE processing scheme with 3 MAC units in each PE in accordance with some embodiments of the present disclosure.

FIG. 8 illustrates a convolution using an input 3D tensor, and d-dimensional tensor kernel and output 3D tensor in accordance with some embodiments of the present disclosure.

FIG. 9 illustrates a TT convolutional computation in accordance with some embodiments of the present disclosure.

FIG. 10 illustrates the compact TT convolutional computation in accordance with some embodiments of the present disclosure.

FIG. 11 illustrate a general case diagram for the reduced TT convolutional computation in accordance with some embodiments of the present disclosure.

FIG. 12 illustrates an overall architecture of TIE in accordance with some embodiments of the present disclosure.

FIG. 13 illustrates a data allocation in weight SRAM in accordance with some embodiments of the present disclosure. In some embodiments, the SRAM may be defined by a data-path and weight SRAM.

FIG. 14 illustrates a perform-on-the-fly transform using well-designed working SRAM read access scheme in accordance with some embodiments of the present disclosure.

FIG. 15 illustrates a layout and performance metrics of TIE in accordance with some embodiments of the present disclosure.

FIG. 16 illustrates performance comparison between EIE and TIE on different benchmarks in accordance with some embodiments of the present disclosure.

FIG. 17 illustrates a flexibility of TIE on different decomposition ranks in accordance with some embodiments of the present disclosure.

FIG. 18 depicts an illustration of an example Tensor Train Decomposition with four Tensor Train (TT) cores in accordance with one or more embodiments of the present disclosure.

FIG. 19 illustrates the steps of the framework of embodiments of the present disclosure.

FIG. 20A, FIG. 20B, and FIG. 20C illustrate training loss, Frobenius norm and test accuracy in dual optimization problem-regularized training procedure with different p in accordance with one or more embodiments of the present disclosure.

FIG. 21A, FIG. 21B, and FIG. 21C illustrate a change of (a) training loss and (b) Top-1 test accuracy, and (c) number of parameters during the training process for ResNet-18 on ImageNet dataset in accordance with aspects of embodiments of the present disclosure.

FIGS. 22A and 22B illustrate (a) Rank variations for two example component convolutional layer during training, and (b) final rank distribution using embodiments of the present method of ResNet-18 on ImageNet dataset in accordance with aspects of embodiments of the present disclosure.

FIG. 23 illustrates a block diagram of an exemplary computer-based system and platform.

FIG. 24 illustrates a block diagram of another exemplary computer-based system and platform.

FIGS. 25 and 26 illustrate schematics of exemplary implementations of the cloud computing/architecture(s) in which the exemplary inventive computer-based systems/platforms, the exemplary inventive computer-based devices, and/or the exemplary inventive computer-based components of the present disclosure may be specifically configured to operate.

### DETAILED DESCRIPTION

The present disclosure describes systems and methods to enable deployment of Deep Neural Networks (DNNs) to chip sets having constrained resources. DNNs may be employed in widespread applications for machine learning-based recognition, prediction and segmentation, such as, e.g., in many computers vision tasks including image classification, video recognition objective detection, and image caption, prediction tasks, and other modelling, prediction, segmentation, classification, regression and other tasks or any combination thereof. Such applications may advantageously be deployed to resource constrained environments, such as embedded and Internet-of-Things (IoT) systems (e.g., smart home devices and security systems, wearable health monitors, ultra-high speed wireless internet, etc.), portable computing devices (e.g., smartphones, tablets, laptop computers, wearable devices, etc.), or other power, energy, memory, and/or processing constrained environments or any combination thereof.

Providing DNN models that have storage and processing requirements within the bounds of such resource-constrained environments is a difficult challenge due to the many parameters and nodes of DNNs. Compression of DNNs provides a potential avenue to producing DNNs with resource requirements within resource-constrained environments. Current implementations of compression may include:
Sparsification of trained models, which is the most popular but may have uneven effects on hardware;
Quantization of trained models, which is inherently hardware friendly but has limited compression ratios; and
Tensor decomposition of trained models, which has very high compression ratios, but often has bad performance, particularly with convolutional neural networks (CNN).

In some embodiments, the compression, inferencing and training techniques of the present disclosure solves the problems of existing methods using the optimization technique as an approach to the tensor decomposition compression approach.

Tensor decomposition, uniquely, may provide ultra-high compression ratio, especially for recurrent neural network (RNN) models. The advanced tensor decomposition approaches, such as tensor train (TT) and tensor ring (TR) and including dual problem singular value decomposition (SVD), higher-order singular value decomposition (HOSVD), Tucker decomposition, hierarchical Tucker decomposition, block term decomposition among others or any combination thereof, may bring more than 1,000 times parameter reduction to the input-to-hidden layers of RNN models. Tensor-decomposed models are also well suited for hardware-based acceleration. However, current TT-based approaches have significant accuracy losses. The technique has much less loss for all neural network models and especially for CNN models.

In some embodiments, a systematic framework is described for tensor decomposition-based model compression by applying an optimization technique such as ADMM. By formulating TT decomposition-based model compression as an optimization problem with constraints on tensor ranks, it leverages ADMM technique to systemically solve this optimization problem in an iterative way. During optimization, the DNN model is trained in the original structure instead of tensor decomposed, while leveraging decreased tensor rank characteristics. In some embodiments, the uncompressed model may be decomposed to tensor decomposed and fine-tuned to obtain a final high-accuracy tensor decomposed format DNN model.

This framework is general in applicability, and therefore works for both CNNs and RNNs, among other neural networks, and may be modified to fit other tensor decomposition approaches. The present disclosure provides the framework for different DNN models for image classification and video recognition tasks as examples, though any suitable neural network task may be employed. Experimental results show that dual problem optimization-based tensor decomposed format models demonstrate very high compression performance with high accuracy.

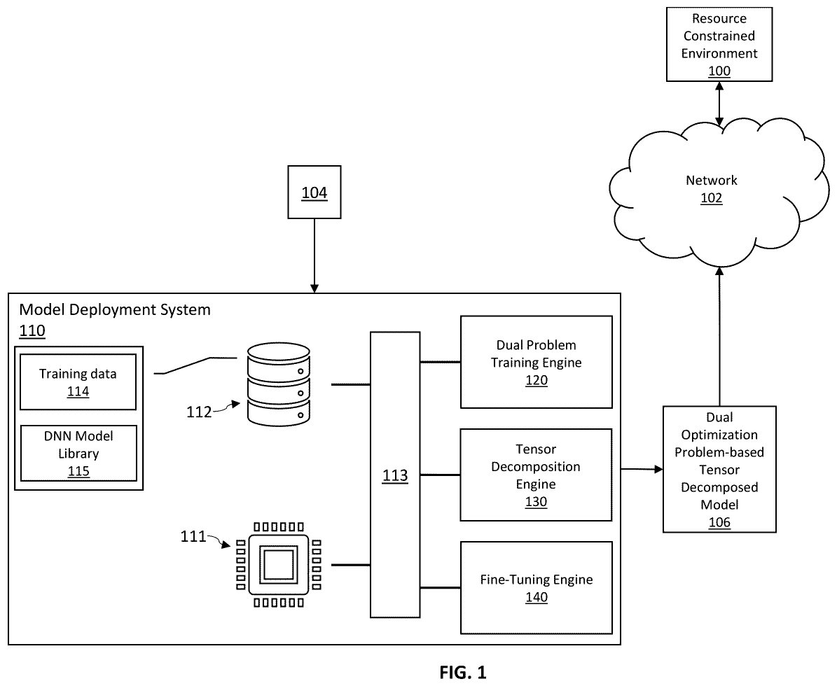

FIG. 1 illustrates a system for implementing an efficient dual problem optimization-based tensor decomposed format model in a resource constrained environment according to one or more embodiments of the present disclosure.

In some embodiments, a model deployment system 110 may be configured to train, compress and deploy machine learning models, such as DNNs, to a resource constrained environment 100. In some embodiments, the model deployment system 110 may communicated with the resource constrained environment 100 via a network 102, or by any other suitable direct or indirect communication (e.g., a suitable wired and/or wireless hardware interface and/or via portable storage devices such as flash drives or USB storage drives, etc.). In some embodiments, the network 102 may include any suitable wired or wireless network with any suitable hardware and/or software configurations, such as, e.g., WiFi, Local Area Network (LAN), telecommunications network, the Internet, Bluetooth, among other networking hardware and/or protocols or any combination thereof.

In some embodiments, the resource constrained environment 100 may include any suitable device and/or system of devices having constraints on resources, such as, e.g., energy constraints, storage constraints, memory constraints, processor constraints, or any other suitable constraints that limit the performance of the resource constrained environment 100 in inferencing tasks using a DNN model. For example, the resource constrained environment 100 may include, e.g., a user computing device (a laptop computer or desktop computer), a mobile computing device (smartphone, tablet, wearable device, augmented reality device, virtual reality device, etc.), an Internet-of-Things (IoT) device (e.g., security camera, smart assistant device, smart TV, smart lights, smart thermostat, smart appliance, etc.), networking equipment, or any other suitable resource constrained device or system of devices or any combination thereof

In some embodiments, the model deployment system 110 may include hardware components such as a processor 111, which may include local or remote processing components. In some embodiments, the processor 111 may include any type of data processing capacity, such as a hardware logic circuit, for example an application specific integrated circuit (ASIC) and a programmable logic, or such as a computing device, for example, a microcomputer or microcontroller that include a programmable microprocessor. In some embodiments, the processor 111 may include data-processing capacity provided by the microprocessor. In some embodiments, the microprocessor may include memory, processing, interface resources, controllers, and counters. In some embodiments, the microprocessor may also include one or more programs stored in memory.

Similarly, the model deployment system 110 may include storage 112, such as one or more local and/or remote data storage solutions such as, e.g., local hard-drive, solid-state drive, flash drive, database or other local data storage solutions or any combination thereof, and/or remote data storage solutions such as a server, mainframe, database or cloud services, distributed database or other suitable data storage solutions or any combination thereof. In some embodiments, the storage 111 may include, e.g., a suitable non-transient computer readable medium such as, e.g., random access memory (RAM), read only memory (ROM), one or more buffers and/or caches, among other memory devices or any combination thereof

In some embodiments, the model deployment system 110 may implement a Dual problem training engine 120 configured for training a DNN, a tensor decomposition engine 130 configured for compressing a trained DNN and a trained compressed DNN fine-tuning engine 140 configured for fine-tuning the compressed trained DNN before deploying a dual optimization problem-based tensor decomposed format model 106. In some embodiments, the terms “computer engine” and “engine” identify at least one software component and/or a combination of at least one software component and at least one hardware component which are designed/programmed/configured to manage/control other software and/or hardware components (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi- core, or any other microprocessor or central processing unit (CPU). In various implementations, the one or more processors may be dual-core processor(s), dual-core mobile processor(s), and so forth.

Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

In some embodiments, the model deployment system 110 may receive a request 104 for a trained DNN for deployment to the resource constrained environment 100. In some embodiments, the request 104 may include parameters for the trained DNN such as, e.g., a model identifier identifying a DNN architecture or DNN type or DNN task or any combination thereof, a resource capacity metric identifying a maximum amount of resources for a local DNN model, a training data set and/or training data set identifier associated with input data records and ground truth data records for training the DNN model to perform the DNN task, among other parameters or any suitable combination thereof. In some embodiments, the resource capacity metric may include, e.g., a memory capacity metric defining a maximum memory size available, a processing capacity metric defining a maximum processing performance available, an energy capacity metric defining a maximum energy use available, among others or any combination thereof

In some embodiments, the DNN model identified by the model identifier may include a suitable deep neural network having at least one weight matrix that is arranged in at least one layer. Each layer of the model may have weights that may be trained to correlate an input to an output.

In some embodiments and, optionally, in combination of any embodiment described above or below, an exemplary implementation of a deep neural network may be executed as follows:
a. define Neural Network architecture/model,
b. transfer the input data to the exemplary neural network model,
c. train the exemplary model incrementally,
d. determine the accuracy for a specific number of timesteps,
e. apply the exemplary trained model to process the newly-received input data,
f. optionally and in parallel, continue to train the exemplary trained model with a predetermined periodicity.

In some embodiments and, optionally, in combination of any embodiment described above or below, the exemplary trained neural network model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the exemplary trained neural network model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the exemplary aggregation function may be a mathematical function that combines (e.g., sum, product, etc.) input signals to the node. In some embodiments and, optionally, in combination of any embodiment described above or below, an output of the exemplary aggregation function may be used as input to the exemplary activation function. In some embodiments and, optionally, in combination of any embodiment described above or below, the bias may be a constant value or function that may be used by the aggregation function and/or the activation function to make the node more or less likely to be activated.

In some embodiments, the model deployment system 110 may instantiate the DNN training 120 to train a DNN according to the request 104. In some embodiments, based on the model identifier, the Dual problem training engine 120 may access a DNN model library 115 in the storage 112. In some embodiments, the DNN model library 115 may include uninitialized DNN models having one or more architectures. For example, the DNNs in the DNN model library 115 may include, e.g., one or more architectural designs of a support vector machine, transformer, a multi-layer perceptron, autoencoder, a convolutional neural network (CNN), or a recurrent neural network (RNN), among others or any combination thereof. Thus, based on the DNN architecture, type, and/or model identified by the model identifier of the request 104, the Dual problem training engine 120 may query and retrieve the associated DNN model in the DNN model library 115. Alternatively, the request 104 may include the DNN model itself rather than or in addition to the model identifier. Thus, the Dual problem training engine 120 may retrieve the DNN model directly from the request 104.

In some embodiments, the Dual problem training engine 120 may also load a training data set based on the training data parameter of the request 104. In some embodiments, the storage 112 may include a library of training data 114, e.g., organized by task, training data set identifier, or any other suitable catalog of training data set. Thus, based on the request 104, the Dual problem training engine 120 may query the storage 112 and retrieve the training data set associated with the request 104 for training the DNN model. Alternatively, the request 104 may include the training data set itself. Thus, the Dual problem training engine 120 may retrieve the training data set directly from the request 104.

In some embodiments, the training data set may include a set of input data records and a set of ground truth, or target or output, data records, where each pair of input to ground truth records defines a known input and output. Accordingly, the Dual problem training engine 120 may initialize the DNN model and use the training data set to train the DNN model.

In some embodiments, to overcome the current limitations of tensor decomposition and fully unlock its potentials for model compression, the dual problem training engine 120 may employ a dual problem optimization problem, such as, e.g., dual problem optimization method, dual ascent method (DAM), dual decomposition, Alternating Direction Method of Multipliers (ADMM), among other suitable dual problem optimization problems or any combination thereof. By formulating tensor decomposition-based model compression to an optimization problem with constraints on tensor ranks, the dual problem optimization problem may be leveraged to systemically solve the optimization problem in an iterative way. During this procedure the entire DNN model is trained in the original structure instead of tensor decomposed structure, but gradually enjoys the desired low tensor rank characteristics. The trained uncompressed model may then be decomposed to tensor decomposed format, and fine-tuned to finally obtain a high-accuracy trained tensor decomposed format DNN model.

In some embodiments, the systematic framework may include formulating and solving the tensor decomposition-based model compression problem. With formulating this problem to a constrained non-convex optimization problem, embodiments of the present framework gradually restricts the DNN model to the target tensor ranks without explicitly training on the tensor decomposed format, thereby maintaining the model capacity as well as minimizing approximation error and increased network depth.

In some embodiments, the systematic framework employs a dual optimization problem such as ADMM to efficiently solve the reformulated optimization problem via separately solving two sub-problems. In some embodiments, a first sub-problem may be to directly optimize the loss function with a regularization of the DNN, e.g., by stochastic gradient descent or other suitable optimization method. In some embodiments, the second sub-problem may use the introduced projection to constrain the tensor ranks analytically.

Thus, in some embodiments, the dual problem training engine 120 may produce a trained DNN model by iteratively updating the at least one layer of the deep neural network, at each iteration, with: a rank value representing a tensor rank to apply to the at least one weight matrix, and the weights of the weight matrix upon decomposition to the tensor of the rank value. To do so, the Dual problem training engine 120 may, at each training iteration, minimize the rank value at each iteration, decompose the weight matrix to a tensor having the rank value, minimize a loss function based on the training data and the weights, backpropagate a loss to the plurality weights, and stop iteratively updating the at least one layer upon the resource capacity metric being satisfied and the loss function being minimized within the resource capacity metric.

In some embodiments, the resource capacity metric may define a maximum memory available for the DNN model. Thus, the dual problem training engine 120 may perform training iterations until the tensor rank is minimized to below the resource capacity metric such that the DNN model being decomposed to have one or more tensors of the tensor rank satisfies the maximum memory capacity. Accordingly, the dual problem training engine 120 may determine the minimum tensor rank associated with the available memory capacity and terminate training iterations where the minimization of the loss converges after the tensor rank is minimized to the minimum tensor rank associated with the available memory capacity.

In some embodiments, upon training the DNN model, the trained DNN model may be provided to a tensor decomposition engine 130 to compress the trained DNN model via tensor decomposition to obtain a trained tensor decomposition format DNN. Because the optimization procedure has already imposed the desired low tensor decomposed rank structure to the uncompressed model, such direction decomposition may avoid significant approximation error.

Thus, in some embodiments, the tensor decomposition engine 130 may utilize the tensor rank determined during training to decompose the weight matrix of the DNN model to a tensor having the tensor rank. In some embodiments, the tensor decomposition technique employed by the tensor decomposition engine 130 may include, e.g., tensor train decomposition, tensor ring decomposition, singular value decomposition (SVD), higher-order singular value decomposition (HOSVD), Tucker decomposition, hierarchical Tucker decomposition, or block term decomposition.

In some embodiments, upon compressing the trained DNN model to a trained tensor decomposition format DNN model, the fine-tuning engine 140 may refine the training of the trained tensor decomposition format DNN model to recover any losses due to the compression process. Thus, the fine-tuning engine 140 may employ the training data set to train the trained tensor decomposition format DNN model, e.g., using a suitable optimization technique such as, e.g., stochastic gradient descent, backtracking line search, coordinate descent, stochastic hill climbing, stochastic variance reduction, among others or any combination thereof. In some embodiments, the fine-tuning phase may be very fast relative to the initial training, e.g., requiring only a few iterations. In some embodiments, the speed of tine-tuning may be because the trained tensor decomposition format DNN model at the starting point of the fine-tuning phase may benefit from decreased accuracy loss relative to the original uncompressed DNN model.

In some embodiments, upon fine-tuning, the model deployment system 110 may deploy the fine-tuned trained tensor decomposition format DNN model to the resource constrained environment 100 such that the fine-tuned trained tensor decomposition format DNN model may be implemented in, e.g., memory constrained environment of the device and/or system of devices associated with the resource constrained environment. In some embodiments, to address the fundamental challenges, the trained tensor decomposition format DNN model and inferencing engine of the present disclosure enables the hardware-friendly inference scheme. In some embodiments, a theoretical limit for minimum number of multiplications needed for tensor decomposed-format inference may be calculated, a computation-efficient inference scheme may be developed. The inference scheme may be configured for the tensor decomposition of the fine-tuned trained tensor decomposition format DNN model, which may have two benefits: 1) it is very compact because the required number of multiplications of this scheme is identical to the theoretical limit, thus eliminating all the unnecessary redundant computations; and 2) based on its multi-stage processing style, the computing engine only needs to access one tensor core in each stage, thereby leading to significant saving in memory access.

In some embodiments, an inferencing engine based on the inferencing scheme may be developed to form a tensor decomposed format DNN inference engine (“TIE”), which may include a specialized hardware architecture based on tensor decomposed-DNN. TIE is designed to fully reap the benefits of embodiments of the present hardware-friendly inference scheme and achieves high computation efficiency as well as simple memory access. Also, TIE 15 flexible and may be adapted to various network types, values of ranks, number of tensor dimensions, and combinations of factorization factors, thereby making itself well suited for various application scenarios and tasks.

### Example—Energy-Efficient Tensor Train-Based DNN Inferencing

In order to facilitate and promote the widespread deployment of DNNs in broader scope of application scenarios, both ML and hardware communities have conducted extensive investigations on compressing DNNs with affordable accuracy loss. Specifically, due to the well-recognized and verified redundancy of DNN models, different compression approaches, such as pruning, clustering, low rank decomposition and low bit-width etc., have been and adopted to remove the redundancy on structure, layer, weight or number precision of DNN models. Correspondingly, several compression-oriented DNN accelerators have also been customized for those compression approaches to achieve high hardware performance.

Among various DNN compression techniques, tensor decomposition is unique due to its extremely high compression ratios. Tensor decomposition may include one or more tensor-based compression techniques such as, e.g., tensor train (TT) decomposition, tensor ring (TR) decomposition, dual problem singular value decomposition (SVD), higher-order singular value decomposition (HOSVD), Tucker decomposition, hierarchical Tucker decomposition, block term decomposition among others or any combination thereof

For instance, experiments in show that applying tensor decomposition to the fully-connected (FC) layers of VGG-16 on ImageNet dataset may bring record-breaking 50000 times compression ratio, while other compression approaches typically only achieve much less compression on FC layers. Moreover, due to the generality of tenso decomposition, this approach may also be applied to compressing convolutional (CONV) layers via decomposing the weight tensors of CONV layers. In some embodiments, tensor decomposition may be effective in several representative types of DNNs, such as convolutional neural networks (CNNs) and recurrent neural networks (RNNs).

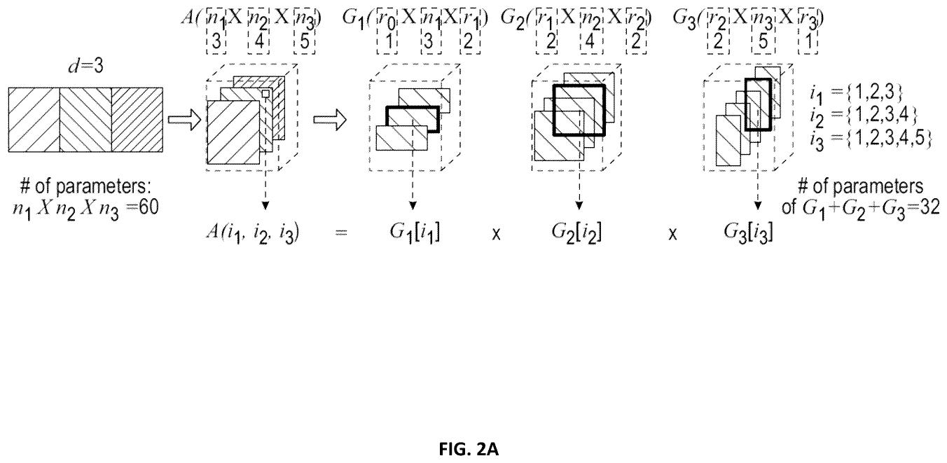

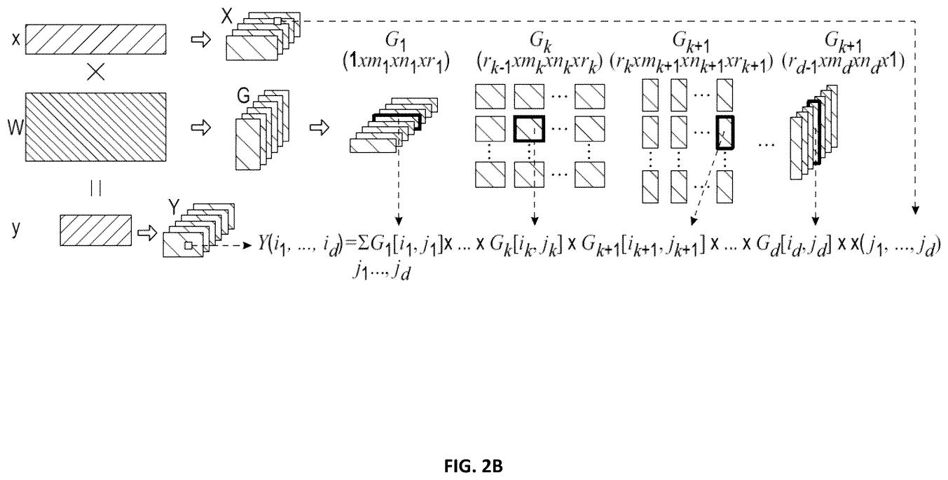

From the perspective of tensor theory, the impressive compression capability of tensor decomposition such as TT decomposition may come from its unique tensor factorization scheme. As illustrated in FIG. 2A, TT decomposition may decompose a d-dimensional n₁×n₁×. . . ×n_{d} tensor [symbol] to d 3-dimensional rₖ₋₁×nₖ×rₖ tensor cores, where rₖ is the preset rank value. Thanks to this special representation scheme, only Σₖ₌₁^{d}nₖrₖ₋₁rₖ parameters need to be stored in the tensor decomposed while Conventionally ┌ₖ₌₁^{d}nₖ parameters were required for an explicit representation. Since in practice r k is typically small, the compression ratio, as defined as Πₖ₌₁^{d}nₖ/Σₖ₌₁^{d}nₖrₖ₋₁rₖ may be very significant and hence brings orders of magnitude reduction in storage cost.

Due to the advantages of TT decomposition on model compression, exploiting efficient DNN hardware architecture based on TT decomposition (referred as TT-DNN) may provide a solution to the drawbacks of typically DNN compression techniques. Considering the high compression ratios that TT decomposition may bring, such specialized architecture may execute the state-of-the-art CNN and RNN models using smaller memory resources than typically DNNs including DNNs compressed by typical means, thereby leading to more area and energy efficient solutions for resource-constrained DNN accelerator design.

In some embodiments, realizing a high-performance TT-DNN accelerator may overcome the challenge on an inefficient inference scheme based on a tensor decomposed format DNN model. In some embodiments, a tensor decomposed inference scheme may have a larger amount of redundant computations, leading to higher computational cost in the inference phase relative to a standard DNN model. Moreover, those inherent redundant computations also incur intensive memory accesses because the tensor cores need to be frequently accessed when calculating each element of output tensor, thereby causing high energy consumption. As a result, despite the high compression ratios, the inherent inefficiency of a tensor decomposed inference scheme may directly impede the potential deployment of TT-DNN accelerator in energy-constrained applications.

In some embodiments, to address the fundamental challenges, the tensor composed DNN, and inferencing engine of the present disclosure enables the hardware-friendly inference scheme. In some embodiments, a theoretical limit for minimum number of multiplications needed for tensor decomposed-format inference may be calculated, a computation-efficient inference scheme may be developed. The tensor decomposed-format inference scheme has two benefits: 1) it is very compact because the required number of multiplications of this scheme is identical to the theoretical limit, thus eliminating all the unnecessary redundant computations; and 2) based on its multi-stage processing style, the computing engine only needs to access one tensor core in each stage, thereby leading to significant saving in memory access.

In some embodiments, an inferencing engine based on the inferencing scheme may be developed to form a tensor decomposed format DNN inference engine (“TIE”), which may include a specialized hardware architecture based on tensor decomposed-DNN. TIE is designed to fully reap the benefits of embodiments of the present hardware-friendly inference scheme and achieves high computation efficiency as well as simple memory access. Also, TIE 15 flexible and may be adapted to various network types, values of ranks, number of tensor dimensions, and combinations of factorization factors, thereby making itself well suited for various application scenarios and tasks.

In some embodiments, an example of the TIE design may include a prototype TIE design using CMOS 28 nm technology for tensor train format DNNs (TT-DNNs). With 16 processing elements (PEs) operating on 1000 MHz, the TIE accelerator consumes 1.74 mm₂ and 154.8 mW. Compared to the typical compressed DNN-oriented accelerators using other compression methods, such as sparsification and structured matrices (C_{IR}CNN), the TT decomposition-based TIE exhibits significant advantages in hardware performance. Compared with EIE, TIE achieves 7.22×˜10.66× better area efficiency and 3.03×˜4.48× better energy efficiency on different workloads, respectively. Compared with C_{IR}CNN, TIE achieves 5.96× and 4.56× higher throughput and energy efficiency, respectively.

### 1 TT-Based DNN Compression

### 1.1 TT Decomposition & Tensor Decomposed

FIG. 2A illustrates a matrix via using the TT decomposition of its reshaped tensor in accordance with some embodiments of the present disclosure.

FIG. 2B illustrates a tensor decomposed inference scheme in accordance with some embodiments of the present disclosure.

In some embodiments, TT decomposition is an efficient compression approach to reduce DNN model sizes. In general, TT decomposition may decompose a large-size multidimensional tensor into a set of small-size 3-dimensional tensors.

Specifically, for a d-dimensional n₁×n₁×. . . ×n_{d} tensor of [symbol] , after TT decomposition [symbol] is stored in the tensor decomposed using d tensor cores [symbol] ₖ∈ [symbol] ^{r}^{_{k−1}}^{×n}^{ₖ}^{×r}^{ₖ}, where k=1, 2, . . . ,d, and each element in [symbol] may be reconstructed as follows:

[symbol]

(j₁, . . . ,j_{d})=G₁[j₁]×G₂[j₂]×. . . ×G_{d}[j_{d}], Equation (1)

where [symbol] ₖ[jₖ]∈ [symbol] ^{r}^{_{k−1}}^{×r}^{ₖ} is the jₖ-th slice of the k-th tensor core [symbol] ₖ with jₖ=1, 2, . . . , nₖ and rₖ is the rank of a tensor core. Accordingly, the number of parameters to represent [symbol] is reduced from Πₖ₌₁^{d}nₖ to Σₖ₌₁^{d}nₖrₖ₋₁rₖ. In some embodiments, the value of r_{k may} vary since TT-decomposition for arbitrary tensor is not unique, r₀ and r_{d} are always set as 1 to satisfy the boundary condition.

In some embodiments, the value of rₖ may be set as a small value, so that the parameter saving resulting from TT decomposition may be very significant. Consequently, leveraging TT decomposition to perform efficient compression on DNN models is very attractive since the fully-connected (FC) and convolutional (CONV) layers of DNNs are in the format of matrix and tensor, which may be decomposed and represented in the tensor decomposed. In some embodiments, in order to maintain high test accuracy, the TT decomposition is typically not directly applied to the 2D weight matrix or 4D weight tensor but to their reshaped format. For instance, as illustrated in FIG. 2A, in order to store a 5×12 weight matrix in the tensor decomposed, the weight matrix is first reshaped to a 3-dimensional tensor as d=3, and then it is decomposed and stored in the three tensor cores ( [symbol] ₁˜ [symbol] ₃).

### 1.2 Tensor Decomposed Inference & Training on DNNs

In some embodiments, when a DNN model is stored in the tensor decomposed, the corresponding inference and training schemes may be re-formulated since the underlying representation for weight matrix and tensor of FC and CONV layers have been changed.

In some embodiments inference on tensor decomposed FC layers. In some embodiments, with weight matrix W∈ [symbol] ^{M×N}, input vector x∈ [symbol] ^{N} and output vector y∈ [symbol] ^{M}, the inference procedure on FC layer is y=Wx, where bias is combined with W for simplicity. In the scenario of representing weight matrix in the tensor decomposed, such inference scheme may be re-formulated as follows:

$$𝓎 ( {i}_{1} , … , {i}_{d} ) = {\sum }_{{j}_{1} , … , {j}_{d}} {G}_{1} [ {i}_{1} , {j}_{1} ] {G}_{2} [ {i}_{2} , {j}_{2} ] , \\ … , {G}_{d} [ {i}_{d} , {j}_{d} ] 𝒳 ( {j}_{1} , … , {j}_{d} ) , \qquad Equation ( 2 )$$

where [symbol] ∈ [symbol] ^{m}^{₁}^{×m}^{₂}^{×, . . . ,xm}^{_{d}} and [symbol] ∈ [symbol] ⁿ^{₁}^{×n}^{₂}^{×, . . . ,×n}^{_{d}} are the reshaped y and x in the tensor format with M=Πₖ₌₁^{d}nₖ, respectively. In some embodiments, weight matrix W may be first reshaped into a d-dimensional tensor [symbol] , and then [symbol] is decomposed and represented in the tensor decomposed format with d tensor cores [symbol] ₖ, where k=1, 2, . . . ,d. Notice that here [symbol] ₖ∈ [symbol] ^{r}^{_{k−1}}^{×m}^{ₖ}^{×n}^{ₖ}^{×r}^{ₖ} is different from the representation in Equation (1) in Section 2.1. This is because, as indicated in, this 4D representation of tensor cores is better for describing the matrix-vector multiplication in the tensor decomposed format, where 3D-based tensor cores may still be used in the described inference scheme. The drawback is the complicated indexing. The 4D representation may be viewed as folding the original 3D tensor. Accordingly, as illustrated in FIG. 2B, [symbol] _{k may} be viewed as a 2D mₖ-by-nₖ array, where each element ( [symbol] ₖ[iₖ,jₖ]) in Equation (2)) of this array is an rₖ₋₁-by-rₖ matrix.

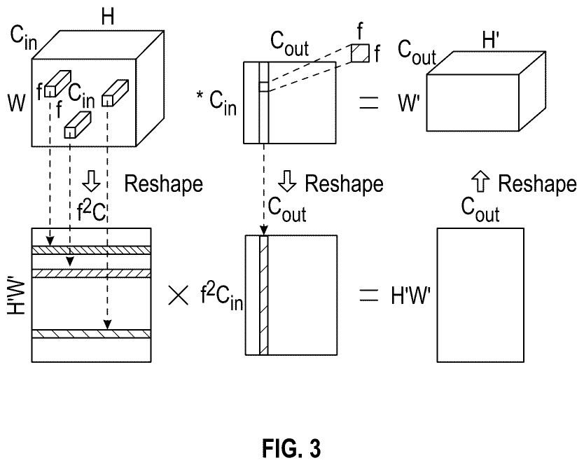

FIG. 3 illustrates a converting computation on CONV layer to matrix multiplication in accordance with some embodiments of the present disclosure. Here H′=H−f+1 and W′=W−f+1.

In some embodiments, due to its generality for arbitrary tensor, tensor decomposition may also enable efficient inference on CONV layer that is affiliated with a weight tensor. In some embodiments, there are two methods to represent the conventional 4D weight tensor of CONV layer in the tensor decomposed format. The first one is to directly apply tensor decomposition to the 4D tensor and obtain the corresponding tensor cores. However, as indicated in, such method is not very efficient for CONV layer with small kernel sizes (e.g., 1×1 convolution). In some embodiments, another method is to reshape the 4D weight tensor to 2D matrix, and then use the same procedure for inference on FC layer to perform inference on CONV layer. As illustrated in FIG. 3, such transform is mathematically rigid since the 2D convolution between the 3D input tensor and 4D weight tensor is equivalent to the matrix-by-matrix multiplication. Consequently, both the inference on FC layers and CONV layers may be executed on the same tensor decomposed inference engine.

In some embodiments, regarding training tensor decomposed format DNN models, in general, after the sizes of tensor cores [symbol] ₖ have been determined, a DNN model in the tensor decomposed format may be either trained from the scratch or obtained from a pretrained non-tensor decomposed format model. In some embodiments, the train-from-scratch strategy assigns initial values for each tensor core and then performs backward propagation scheme in to update them. On the other hand, if converting a non-tensor decomposed trained model to the tensor decomposed format is needed, the standard TT decomposition in is first applied to the weight matrix/tensor of the FC/CONV layer of model to form the initial values of tensor cores. Then backward propagation-based fine-tuning process is performed to retain original high accuracy. In some embodiments, other techniques for training a tensor decomposed format neural network are described further below.

### 1.3 Compression & Accuracy Performance

In some embodiments, based on the training and inference described in above, the tensor decomposed format DNN models may be trained and tested. Table 1-Table 3 list the test accuracy and compression ratio (CR) of different types of DNN models (convolutional neural network (CNN) and recurrent neural network (RNN)) on different datasets. Here the CR is measured as the reduction of number of parameters of the model. Specifically, the experimental settings are shown in Tables 1 through 3 as follows:

TABLE 1
FC-dominated CNN on ImageNet.

| FC-dominated | | | |
|---|---|---|---|
| CNN | Accuracy | CR for FC | CR for overall |
| (NIPS′16) | (%) | layers | network |
| VGG-16 (baseline) | 69.1 | 1× | 1× |
| TT-VGG-16 | 67.8 | 30.9× | 7.4× |

TABLE 2
CONV-dominated CNN on CIFAR-10.

| CONV-dominated | Accuracy | CR for | CR for overall |
|---|---|---|---|
| CNN (NIPS′17) | (%) | CONV layers | network |
| CNN (baseline) | 90.7 | 1× | 1× |
| TT-CNN | 89.3 | 3.3× | 3.27× |

TABLE 3
RNN on Youtube Celebrities Face Data.

| | | | CR for |
|---|---|---|---|
| RNN | Accuracy | CR for FC | overall |
| (ICML′17) | (%) | layers | network |
| LSTM (baseline) | 33.2 | 1× | 1× |
| TT-LSTM | 75.5 | 15283× | 196× |
| GRU (baseline) | 34.2 | 1× | 1× |
| TT-GRU | 80.0 | 11683× | 195× |

a. FC-dominated CNN: Two FC layers (FC6 and FC7) are in the tensor decomposed format, where d=6, m₁˜m₆=4, r₁˜r₅=4. For FC6 and FC7, n₁˜n₆=[2,7,8,8,7,4] and [4,4,4,4,4,4], respectively.
b. CONV-dominated CNN: The 2nd˜6h CONV layers are in the tensor decomposed format, where d=4,m=[3,4,4,4] and [3,4,8,4] for the 2nd and the 3rd˜6th layers, respectively, n=[3,4,4,4] and [3,4,8,4] for the 2nd˜3rd and the 4th˜6th layers, respectively, r₁˜r₂=[22,20,20], [27,22,22], [23,23,23] for the 2nd, the 3rd and the 4th˜6th layers, respectively.
c. LSTM or GRU-based RNN: All the input-to-hidden layers are in the tensor decomposed format, where d=4, m=[4,4,4,4], n=[4,20, 20,36] and r₂˜r₄=4.

In some embodiments, as shown in Table 1-Table 3, TT decomposition enables significant reduction in the number of parameters of the decomposed layers and the entire DNN model sizes. Meanwhile, it preserves high task accuracy on different datasets, facilitating practical deployment of DNN models, e.g., in resource constrained environments. However, a drawback of typical tensor decomposition including low computational efficiency in the inference phase, which may be elaborated in Section 3.1, impedes wide adoption in practical systems. Indeed, the TT-decomposed models achieve similar test accuracy with the state-of-the-artwork having 80.8% accuracy.

### 2 Efficient tensor decomposed Inference: Challenge and Solution

### 2.1 Challenge of Tensor Decomposed Inference

In some embodiments, as described in Equation (2), the inference on the tensor decomposed layers of DNN models may be performed via multi-dimensional summation of the products of slices of different tensor cores. This implementation, though classical and straightforward, incurs severe challenge that leads to low computational efficiency.

In general, the low computational efficiency of tensor decomposed inference scheme comes from its inherent redundant computations. Recall that in Equation (2), calculating a specific element of output tensor ( [symbol] (i₁, . . . , i_{d}))requires consecutive multiplications of [symbol] ₖ[iₖ,jₖ] over all jₖ's. Since each [symbol] (i₁, . . . , i_{d}) always has the partially same indices iₖ with many other [symbol] (i₁, . . . , i_{d})'s, calculating those indices shared elements inherently contains multiple times of consecutive multiplication among the same [symbol] ₖ[iₖ,jₖ], thereby causing unnecessary computational redundancy.

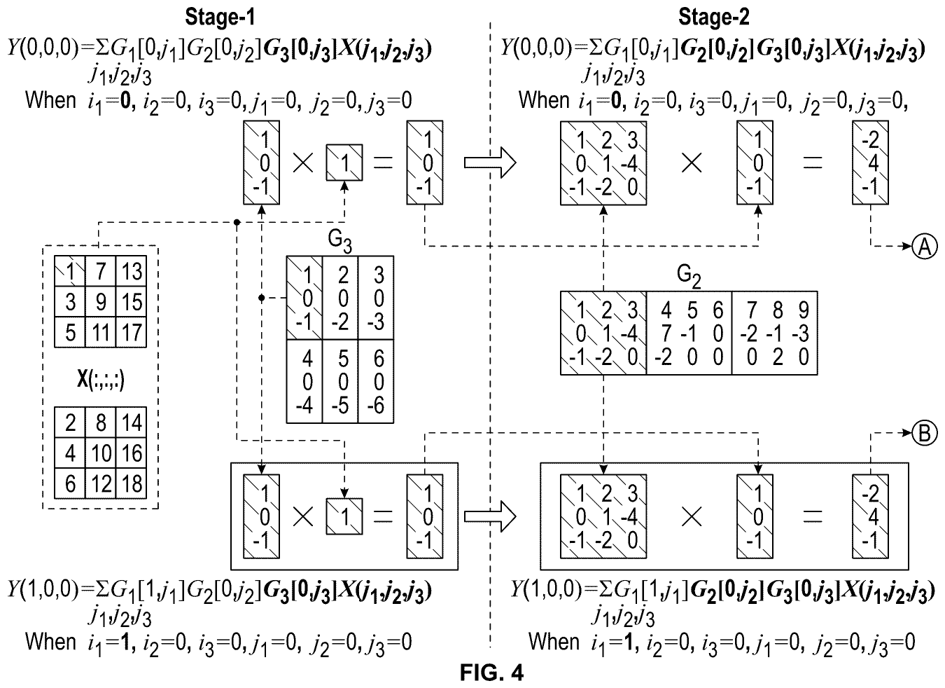

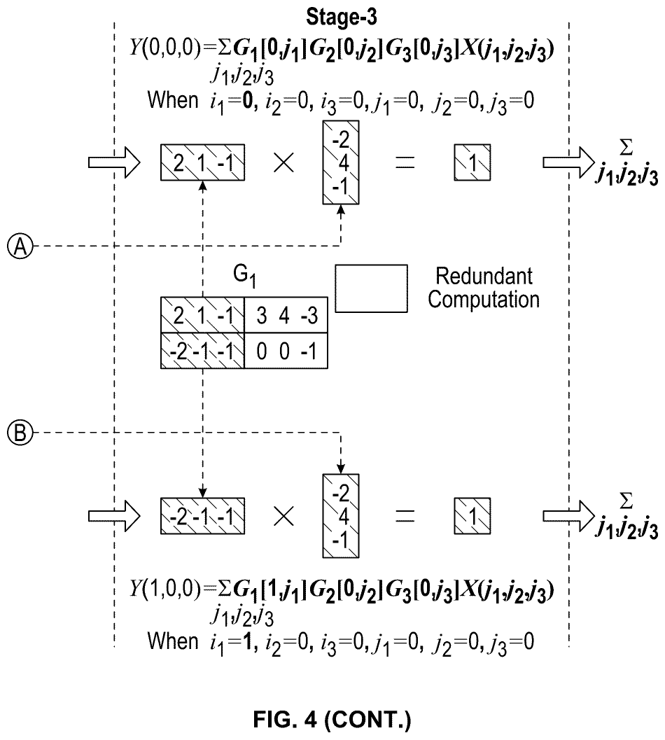

FIG. 4 illustrates an example of redundant computations in conventional tensor decomposed inference scheme in accordance with some embodiments of the present disclosure. Thus, FIG. 4 illustrates the existence of such redundancy in the calculation of 3-dimensional tensor. As shown, the calculation procedure of [symbol] (0,0,0) and [symbol] (1,0,0) have two identical matrix-vector multiplication stages out of all three stages. FIG. 4 only shows the computational redundancy for these two specific output tensor elements. In general, such replicate multiplications in Equation (2) always exist for any pair of tensor elements that shares part of the indices.

### Tensor Decomposed

To further quantify the computational redundancy, an analytic evaluation on the total number of multiplications consumed in Equation (2) and the minimum required number of multiplications for calculating all [symbol] (i₁, . . . ,i_{d}), respectively, may be performed. For simplicity, only multiplication is counted for computational cost.

Analysis on total number of multiplications in Equation (2): First, the total required number of multiplications consumed in Equation (2) may be examined. As indicated in FIG. 4, computing one [symbol] (i₁, . . . ,i_{d}) needs I stages of matrix-vector multiplication between a length-rᵢ and rᵢ-by-rᵢ₋₁ matrix. Therefore, total number of multiplications to calculate all M [symbol] (i₁, . . . ,i_{d})'s is:

$${MUL}_{naive} = MN {\sum }_{i = 1}^{d} {r}_{i} {r}_{i - 1} . \qquad Equation ( 3 )$$

Analysis on minimum number of multiplications for [symbol] (i₁, . . . , i_{d}): Next the minimum number of required multiplications for calculating all [symbol] (i₁, . . . , i_{d})∈ [symbol] may be analyzed. The general procedure is to first determine the computational cost for [symbol] (i₁, . . . , i_{d-1}, :)⁴ when i₁˜i_{d-1} are specific. In some embodiments, the ‘:’ is used in the i-th dimension of tensor to denote all elements in the i-th dimension of this tensor. The number of non-redundant multiplications for calculating [symbol] (i₁, . . . , i_{d-2}, :, :) when i₁˜i_{d-2} are specific is determined based on the computation cost when i₁˜i_{d-1} are specific. As result, the computations involved with [symbol] _{d}[i_{d},j_{d}] are not considered since such computations have been included before, thereby avoiding counting repeated computation. The similar analysis from the (d−2)-th dimension to the 1-st dimension of [symbol] may be performed, and finally the minimum required number of multiplications for calculating all [symbol] (i₁, . . . , i_{d})'s as [symbol] (:, . . . , :, :) may be obtained. In general, such recursive counting method ensures that all the multiplications involved with the calculation of all [symbol] (i₁, . . . , i_{d})'s are included and meanwhile those multiplications are not counted repeatedly.

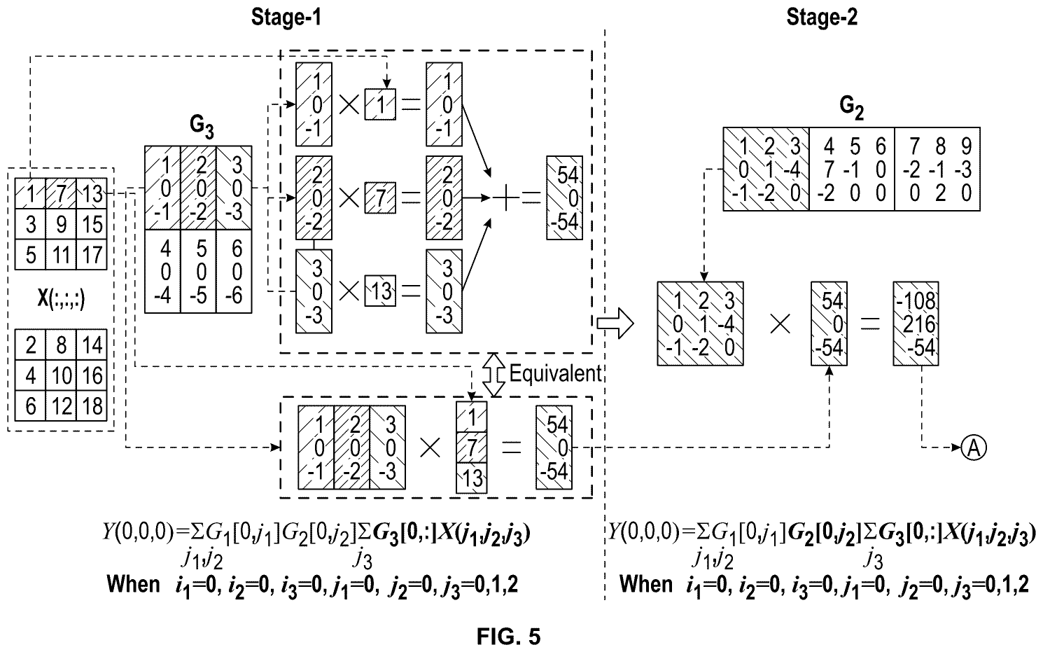

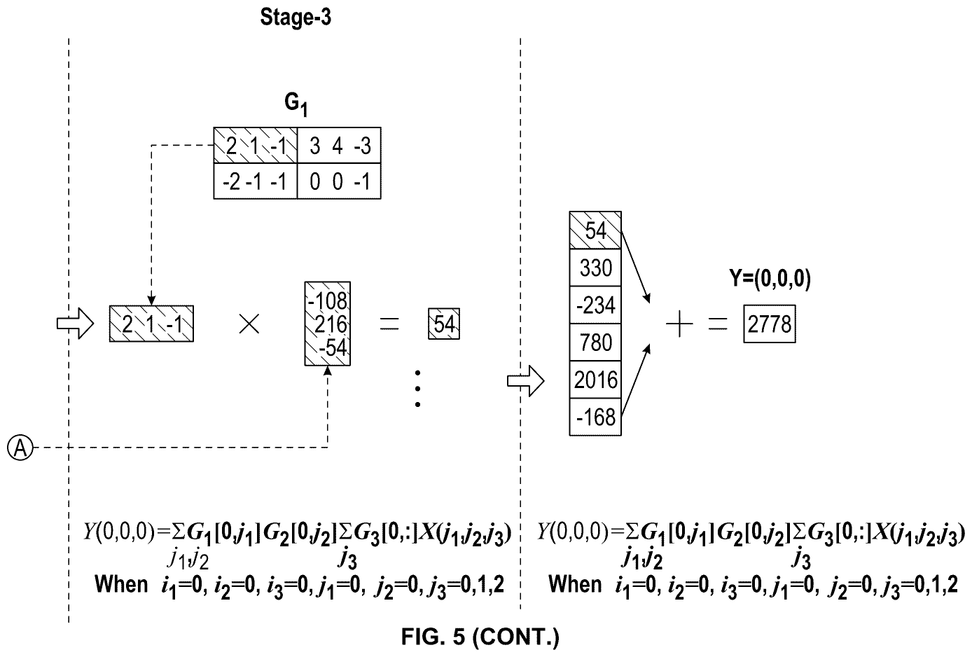

FIG. 5 illustrates a partially paralleling the inputs in Stage-3 in accordance with some embodiments of the present disclosure. Redundant computations are partially reduced.

Specifically, the detail of above analysis procedure is described as follows. First consider the computational cost for [symbol] (i₁, . . . , i_{d-1}, :) (referred as stage-1). Recall that Equation (2) indicates calculating one [symbol] (i₁, . . . , i_{d-1}, i_{d}) requires all [symbol] (j₁, . . . , j_{d-1}, j_{d})'s and d [symbol] ₖ[iₖ,jₖ]'s where k=1,2, . . . , d. Additionally, as illustrated in FIG. 4, [symbol] (j₁, . . . , j_{d-1}, j_{d}) only shares one common index jₖ with one slice of tensor core [symbol] ₖ[iₖ,jₖ]. Based on these two observations, in order to facilitate the analysis on [symbol] (i₁, . . . , i_{d-1}, :) the counting procedure may be partitioned into d steps, where in the k-th step the involvement of [symbol] (j₁, . . . , j_{d-k}, :, :, . . . , :) is considered. Accordingly, when considering the number of multiplications involved with [symbol] (j₁, . . . , j_{d-1}, :) and [symbol] _{d}[i_{d},j_{d}] for calculating [symbol] (i₁, . . . , i_{d-1}, :), the computational cost is r_{d-1}r_{d}n_{d}. This cost corresponds to paralleling the d-th dimension of input [symbol] (j₁, . . . ,j_{d-1},j_{d}) (as shown in stage-1 of FIG. 5).Though such paralleled input scheme does not reduce any computational redundancy involved with [symbol] _{d}[i_{d},j_{d}] (stage-1 in FIG. 5), it saves the computation involved with [symbol] _{d-1}[i_{d-1},j_{d-1}] (stage-2 in FIG. 5) because now only one, instead of n_{d}, length-r₁ vector is multiplied with [symbol] _{d-1}[i_{d-1},j_{d-1}]. Besides, since all the computations involved with [symbol] _{d}[i_{d},j_{d}] has been considered before, the additional computational cost for [symbol] (i₁, . . . , i_{d-1}, :), with specific j_{d-1} is r_{d-1}r_{d}n_{d}+r_{d-2}r_{d-1}. Therefore, the number of multiplications of calculating [symbol] (i₁, . . . , i_{d-1}, :) with [symbol] (j₁, . . . , j_{d-2}, :, :) is (r_{d-1}r_{d}n_{d}+r_{d-2}r_{d-1})n_{d-1}. By recursively applying this analysis, the number of multiplications for calculating [symbol] (i₁, . . . , i_{d-1}, :) may be derived with [symbol] (:, . . . , :, :) as:

$${MUL}_{𝓎 ( {i}_{1} , … , {k}_{d - 1} , : )} = {m}_{d} {\sum }_{i = 1}^{d} ( {r}_{i} {r}_{i - 1} {\prod }_{t = 1}^{i} {n}_{t} ) . \qquad Equation ( 4 )$$

Next, the additional computational cost for calculating [symbol] (i₁, . . . , i_{d-2}, :, :) (referred as stage-2) may be determined. Similar to the previous analysis on recursive computation, when computing [symbol] (i₁, . . . , i_{d-2}, :, :), the computation involved with [symbol] (i₁, . . . , i_{d-2}, i_{d-1}, :) has already been considered and may be not be re-counted again. Therefore, the additional number of multiplications for calculating [symbol] (i₁, . . . , i_{d-2}, :, :) with [symbol] (:, . . . , :, :) is:

$${MUL}_{extra for 𝓎 ( {i}_{1} , … , {i}_{d - 2} , : , : )} = ( {m}_{d - 1} {m}_{d} - {m}_{d} ) {\sum }_{i = 1}^{d - 1} ( {r}_{i} {r}_{i - 1} {\prod }_{t = 1}^{i} {n}_{t} ) . \qquad Equation ( 5 )$$

By generalizing Equation 5, the additional number of multiplications for calculating [symbol] (i₁, . . . , iₗ, :, . . . , :) withinn stage-1 may be derived as:

$$\begin{matrix}{MUL}_{extra for 𝓎 ( : , … , : , : )} = {MUL}_{𝓎 ( {i}_{1} , … , {i}_{d - 1} , : )} + \\ {MUL}_{extra for 𝓎 ( {i}_{1} , … , {i}_{d - 2} , : , : )} + \\ … + {MUL}_{extra for 𝓎 ( {i}_{1} , … , : , : )} \\ = {\sum }_{l = 1}^{d} ( ( {m}_{l} - 1 ) {\prod }_{j = l + 1}^{d} {m}_{j} {\sum }_{i = 1}^{l} ( {r}_{i} {r}_{i - 1} {\prod }_{t = 1}^{i} {n}_{t} ) )\end{matrix} . \qquad Equation ( 6 )$$

Consequently, because Y has d dimensions, the total minimum number of multiplications for calculating [symbol] (i₁, . . . , iₗ, :, . . . , :) in all d stages is:

$$\begin{matrix}{MUL}_{extra for 𝓎 ( : , … , : , : )} = {MUL}_{𝓎 ( {i}_{1} , … , {i}_{d - 1} , : )} + \\ {MUL}_{extra for 𝓎 ( {i}_{1} , … , {i}_{d - 2} , : , : )} + \\ … + {MUL}_{extra for 𝓎 ( {i}_{1} , … , : , : )} \\ = {\sum }_{l = 1}^{d} ( ( {m}_{l} - 1 ) {\prod }_{j = l + 1}^{d} {m}_{j} {\sum }_{i = 1}^{l} ( {r}_{i} {r}_{i - 1} {\prod }_{t = 1}^{i} {n}_{t} ) )\end{matrix} . \qquad Equation ( 7 )$$

Equation 7 gives the analytical result of minimum number of multiplications for performing tensor decomposed inference. Comparing this theoretical limit with Equation 3, the conventional tensor decomposed scheme contains computational redundancy. For instance, for the FC-6 layer in VGG-16 with d=6 and rᵢ=4, the number of multiplications consumed in Equation 3 is 1073 times than that in Equation 7. Such redundancy in multiplication results in reduced computational efficiency of conventional approaches.

### 2.2 Compact Tensor Decomposed Inference Scheme

In some embodiments, to address the challenge of low computational efficiency, a computation-efficient tensor decomposed inference scheme is configured to calculate all the elements of output tensor [symbol] in parallel without any redundant computations in a compact inference scheme, thereby improving computational efficiency over the conventional tensor decomposed inference scheme.

In some embodiments, the design of the compact inference scheme leverages the theoretical analysis on the minimum required number of computations in Section 3. Recall that in the previous analysis the minimum number of multiplications is counted based on the assumption that all the computations involved with [symbol] ₖ[iₖ,jₖ] are not included for the future computations involved with [symbol] ₖ₋₁[iₖ₋₁,jₖ₋₁]. To achieve this, in embodiments, the computation on different [symbol] ₖ's may be performed one by one. In other words, different from Equation 2 that calculates one output tensor element using d [symbol] ₖ[iₖ,jₖ]'s where k=1, 2, . . . ,d, in some embodiments, the compact inference scheme may perform computation using all mₖ,nₖ [symbol] ₖ[iₖ,jₖ]'s with one specific k, and then not use all mₖ,nₖ [symbol] ₖ[iₖ,jₖ]'s in the future for other k's. Consequently, such computing arrangement breaks the original data dependency and eliminates the potential computational redundancy.

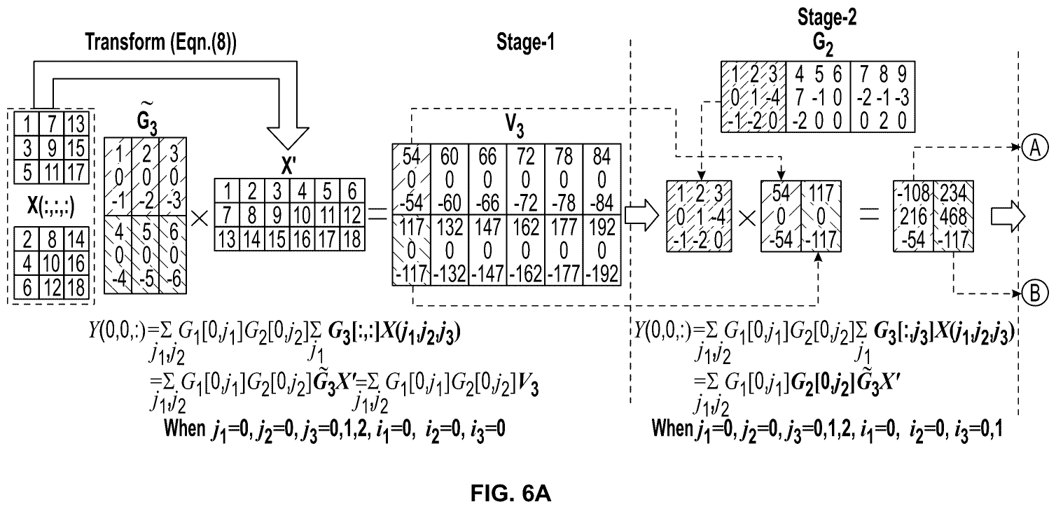

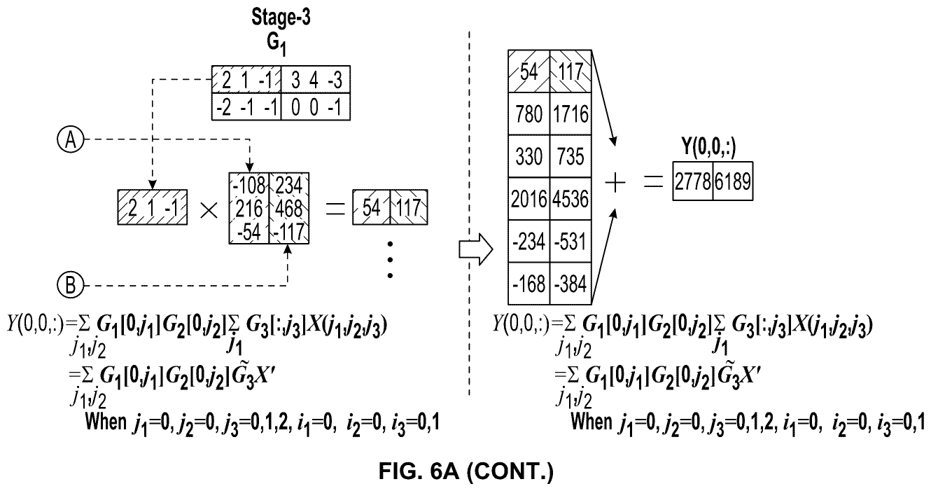

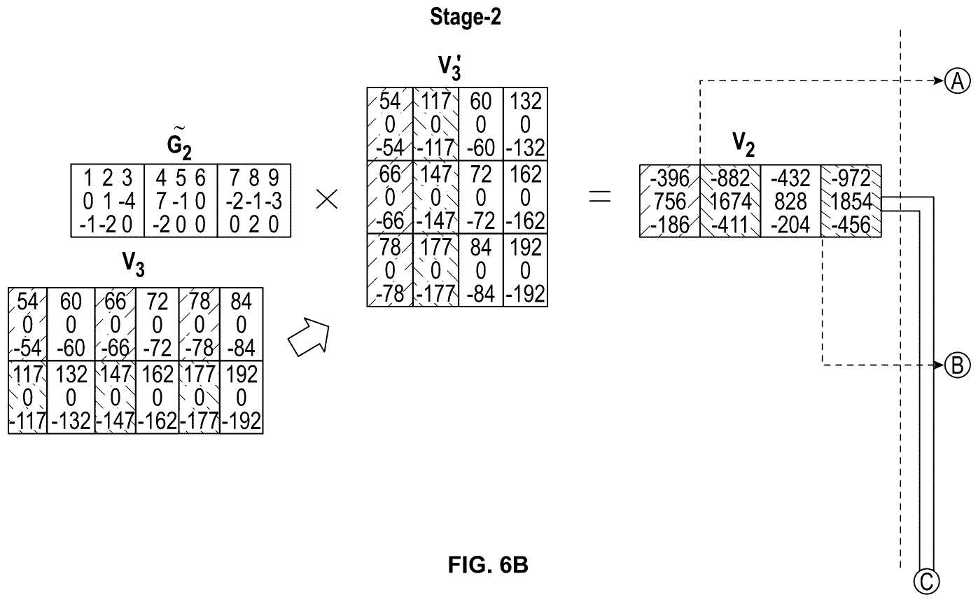

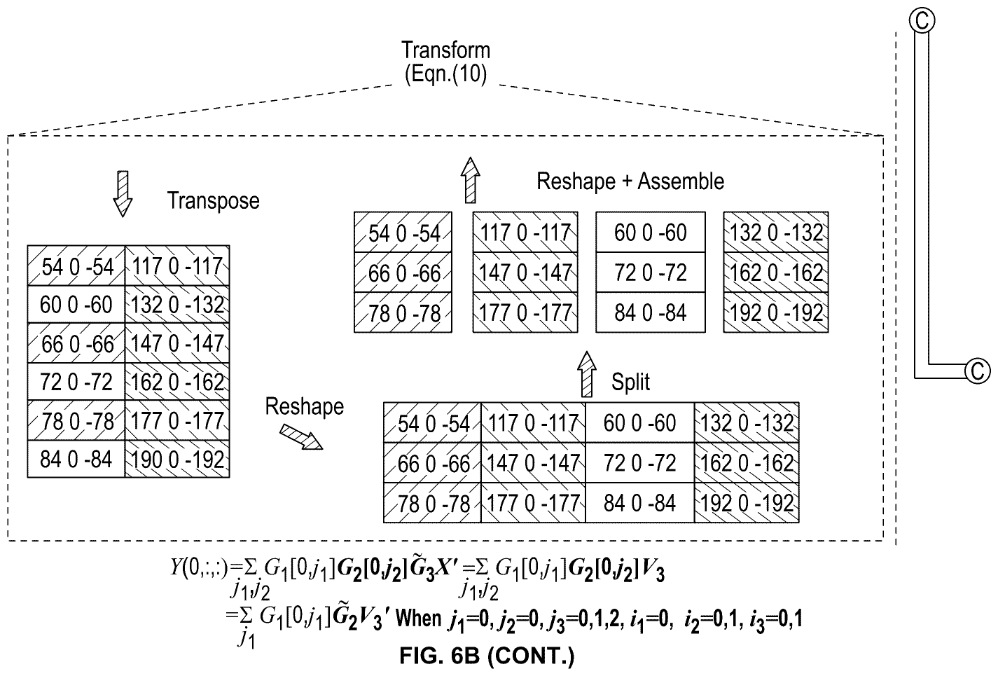

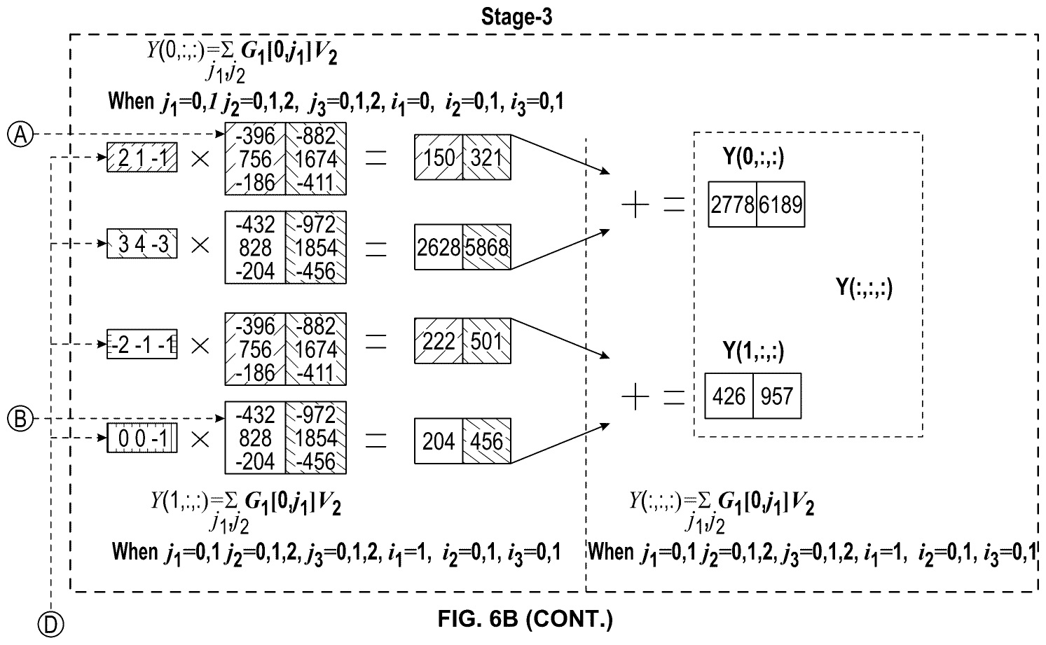

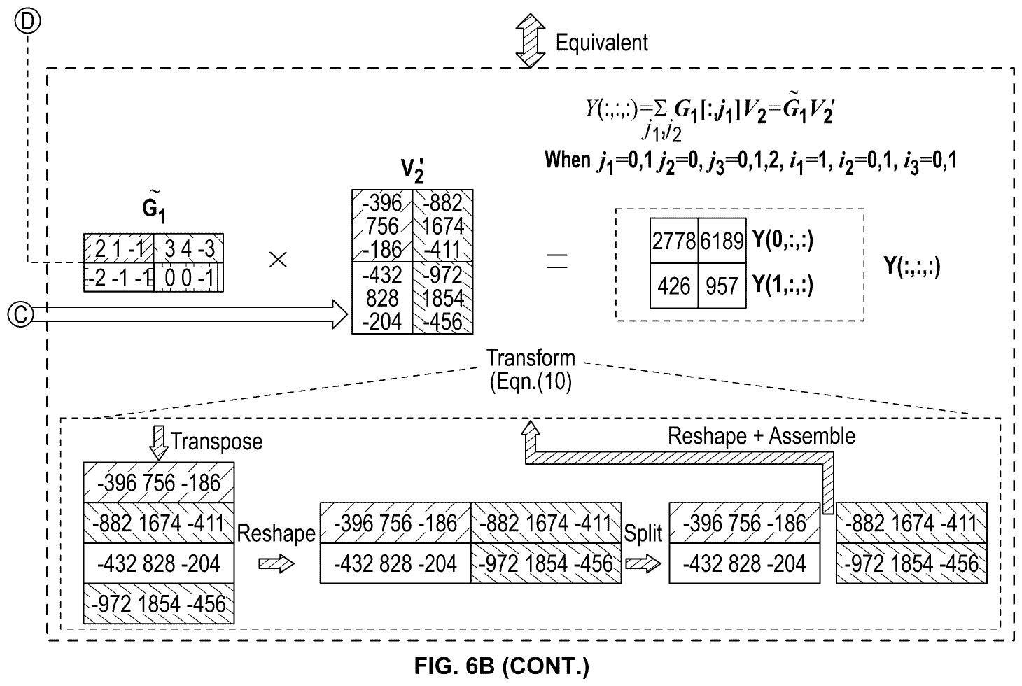

FIG. 6A and FIG. 6B illustrate an example of compact tensor decomposed inference scheme in accordance with some embodiments of the present disclosure.

In some embodiments, as described in Section 2.1 above and shown in FIG. 5, partial paralleling input multiple [symbol] (j₁, . . . , j_{d-1}, j_{d})'s as [symbol] (j₁, . . . , j_{d-1}, :) reduces redundant computations involved with [symbol] _{d-1}[i_{d-1},j_{d-1}]. To be consistent with this, the computation involved with all the input [symbol] (j₁, . . . , j_{d-1}, j_{d})'s (as [symbol] (:, . . . , :, :)) and all the slices of [symbol] _{d} (see FIG. 6A) may be made fully parallel. As shown in FIGS. 6A and 6B, such parallel computation is associated with a compact matrix-format multiplication that replaces the original summations in Equation 2 over index j_{d}. Different from FIG. 5, the computations in stage-1 of FIG. 6A are for every [symbol] (j₁, . . . , j_{d-1}, j_{d}) and every slice of [symbol] _{d}; therefore, the input tensor [symbol] ∈ [symbol] ⁿ^{₁}^{×n}^{₂}^{×. . . ,×n}^{_{d}} may be properly transformed to a new matrix format to ensure the functional validity and suited for matrix multiplication. In some embodiments, such transform converts a tensor [symbol] ∈ [symbol] ⁿ^{₁}^{×n}^{₂}^{×. . . ,×n}_{d} to a matrix [symbol] ∈ [symbol] ⁿ^{_{d}}^{×Π}^{_{t=1Πd−1}}ⁿ^{ₜ}, and the mapping principle for this transform is as follows:

[symbol]

(j₁, . . . , j_{d-1}, j_{d})→X′(p,q), Equation (8)

where p=j_{d} and q=Σₗ₌₁^{d-1}Πᵢ₌₁^{l-1}nᵢ. Then, a compact matrix format multiplication may be performed as:

V_{d}=\tilde{G}_{d}X′, Equation (9)

where V_{d} is the intermediate matrix to be sent to stage-2, and \tilde{G}_{d} is the matrix format of unfolded [symbol] _{d} (see FIG. 6A).

In some embodiments, FIG. 6A depicts compact matrix-format computation in stage-1; while in stage-2 and stage-3 [symbol] ₂[i₂,j₂] and [symbol] ₁[i₁,j₁] may be fetched for processing in serial, thereby causing redundant computations. As analyzed in Section 2.1, avoiding the redundant computations in each computing stage may be mitigated using the involvement of the output values from previous stages (e.g., V₃) and the matrix format of the unfolded tensor core (e.g., \tilde{G}₂). However, as illustrated in FIGS. 6A and 6B, \tilde{G}₂ and V₃, or \tilde{G}₁ and V₂, may not be simply multiplied because 1) the sizes do not fit for direct matrix multiplications; and 2) the elements of Vₕ, as the intermediate values from stages-(d−h+1), and \tilde{G}ₕ₋₁, as the matrix format of unfolded tensor core in the stage-(d−h+2), may not be in the correct positions to produce correct results even if \tilde{G}₂ and V₃, or \tilde{G}₁ and V₂ may be multiplied. In some embodiments, therefore, transforming Vₕ before it is multiplied with \tilde{G}ₕ₋₁ may resolve such complications. In some embodiments, in the stage-(d−h+1) such transform is to convert Vₕ∈ [symbol] ^{(m}^{ₕ}^{×r}^{_{h−1}}^{)×(Π}^{_{k=1Πh−1}}ⁿ^{ₖ}^{×Π}^{_{k=1Πd−h}}^{m}^{_{d−k−1}}) to V′ₕ∈ [symbol] ⁽ⁿ^{_{h−1}}^{×r}^{_{h−1}}^{)×(Π}^{_{k=1Πh−1}}ⁿ^{ₖ}^{×Π}^{_{k=1Πd−h+1}}^{m}^{_{d−k−1}}⁾, and the mapping principal for this transform is as follows:

Vₕ(p,q)→V′ₕ(p′,q′),

where p=iₕrₕ₋₁+tₕ₋₁, p′=jₕ₋₁rₕ₋₁+tₕ₋₁,

q=(Σₗ₌₁^{h-1}jtΠᵢ₌₁^{l-1}nᵢ)Πₖ₌₁^{d-h}m_{d-k+1}+Σ_{g=2}^{d-h}(Π_{k=g}^{d-h}m_{d-k+1})i_{d-g+2},

q′=(Σₗ₌₁^{h-2}jtΠᵢ₌₁^{l-1}nᵢ)Πₖ₌₁^{d-h+1}m_{d-k+1}+Σ_{g=2}^{d-h+1}(Π_{k=g}^{d-h+1}m_{d-k+1})i_{d-g+2}. Equation (10)

After performing this transform, a compact matrix-format computation for stage-(d−h+2) is as:

Vₕ₋₁=\tilde{G}ₕ₋₁V′ₕ Equation (11)

where Vₕ₋₁ may be then be sent to stage-(d−h+3) and being transformed again.

In some embodiments, as illustrated in FIG. 6B, the entire compact tensor decomposed inference scheme contains d computation stages, where each stage performs transform and multiply with the output Vₕ from previous stages. In each stage, matrix multiplication between transformed input V′ₕ and corresponding \tilde{G}ₕ₋₁. By using this scheme, all the elements of final output tensor Y may be obtained simultaneously at the output end of stage-1 without any redundant computations. In some embodiments, for practical implementation, the transformation described in Equation(2) may be equivalently achieved by performing 4-step matrix-wise multiplications (see Transform in FIG. 6B). Putting all together, the compact tensor decomposed inference scheme may be as described in Algorithm 1.

Algorithm 1: Compact Tensor Decomposed Inference Scheme

| | Input :X, \tilde{G}₁, . . . , \tilde{G}_{d}, m = [m₁, . . . , m_{d}], n = |
|---|---|
| | [n₁, . . . , n_{d}], r = [r₀, r₁, . . . , r_{d}] |
| | Output : Y |
| 1 | X’=Reshape(X, [n_{d}, −1]) |
| 2 | V’_{d+1}=X’ |
| 3 | for h = d to \|1 do |
| 4 | \| Vₕ = MatMul(\tilde{G}ₕ, V’ₕ₊₁) |
| 5 | └ V’ₕ = Transform(Vₕ, h) |
| 6 | Function Transform(V, h) |
| 7 | \| V’ = Transpose(V) |
| 8 | \| V’ = Rehape(V’, [nₕ₋₁, −1]) |
| 9 | \| // split |
| 10 | \| t’ = new [nₕ₋₁, rₕ₋₁] |
| 11 | \| T′ = new [Πₖ₌₁^{h-2} nₖ Πₖ₌ₕ^{d} mₖ] t’ |
| 12 | \| for j = 1 to [Πₖ₌₁^{h-2} nₖ Πₖ₌ₕ^{d} mₖ] do |
| 13 | \| \| T′[j] = V’[:, (j − 1) * rₕ₋₁ : j * rₕ₋₁] |
| 14 | \| └ T′[j] = Reshape(T′[j],[nₕ₋₁ * rₕ₋₁]) |
| 15 | \| // assemble |
| 16 | \| V’ = new [nₕ₋₁ * rₕ₋₁, Πₖ₌₁^{h-2} nₖ Πₖ₌ₕ^{d} mₖ] |
| 17 | \| for j = 1 to [Πₖ₌₁^{h-2} nₖ Πₖ₌ₕ^{d} mₖ] do |
| 18 | \| └ V’[:, j] = T′[j] |
| 19 | └ Return V’ |

In some embodiments, at each stage of compact tensor decomposed inference scheme, the intermediate values may be buffered on-chip for the processing of next stage. In some embodiments, the storage capacity to store the intermediate values from state-(d−h+1) is max(rₕ₋₁Πₖ₌₁^{k-1}nₖ)Πₖ₌ₕ^{d}mₖ, where h=1 . . . d. In some embodiments, both the input and output of each stage may be stored. The overall storage overhead is 2×max(rₕ₋₁Πₖ₋₁^{k-1}nₖ)Πₖ₌ₕ^{d}mₖ, where h=1 . . . d. In some embodiments, the activation size is much less than weights size in other compression techniques, thus, the storage overhead brought by compact tensor decomposed inference scheme is low enough to be implemented in an embedded or other resource constrained device.

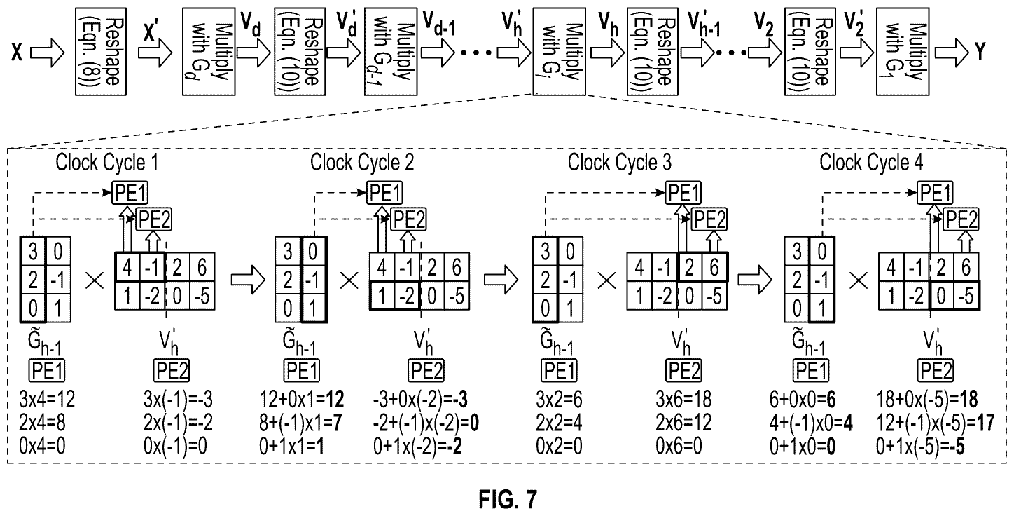

FIG. 7 illustrates an example 2-PE processing scheme with 3 MAC units in each PE in accordance with some embodiments of the present disclosure.

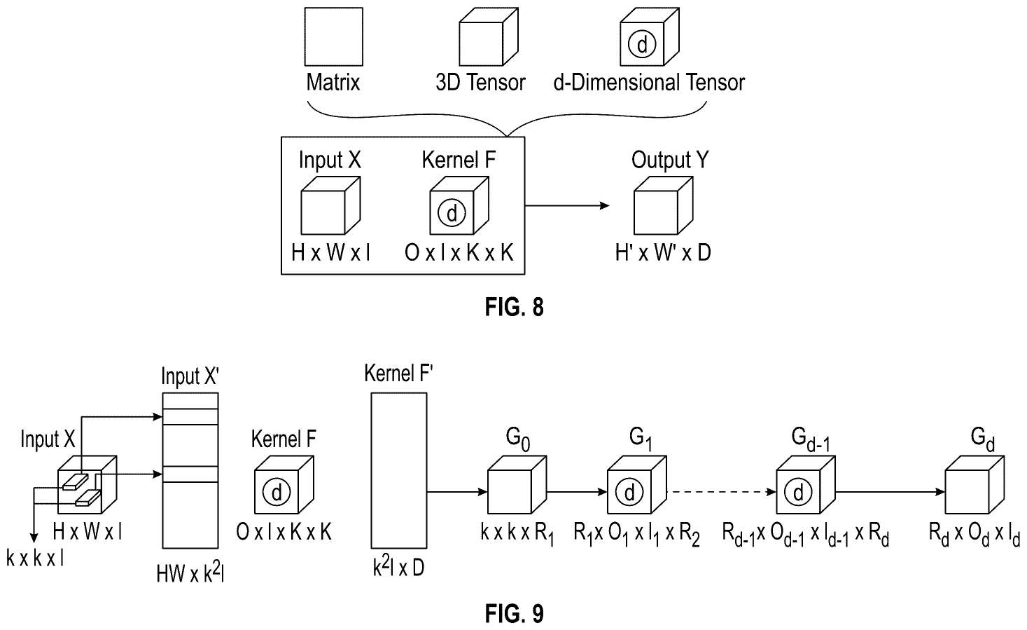

FIG. 8 illustrates a convolution using an input 3D tensor, and d-dimensional tensor kernel and output 3D tensor in accordance with some embodiments of the present disclosure.

FIG. 9 illustrates a TT convolutional computation in accordance with some embodiments of the present disclosure.

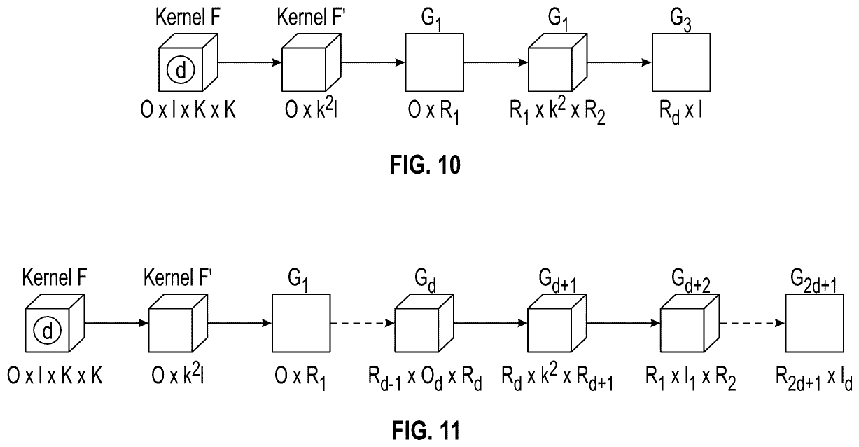

FIG. 10 illustrates the compact TT convolutional computation in accordance with some embodiments of the present disclosure.

FIG. 11 illustrate a general case diagram for the reduced TT convolutional computation in accordance with some embodiments of the present disclosure.

A standard convolution includes performing each of Equations 12 and 13 below:

Y(h′,w′,o)=Σₖ_{₁}^{k}Σₖ_{₂}^{k}Σᵢ^{I}F(o,\dot{v},k₁,k₂)x(h,w,ż), Equation (12)

h=(h′−1)s+k₁−p,w=(w′−1)s+k₂−p Equation (13)

where s is the stride, and p is the zero-padding size. As a result, the computational cost of standard convolution is HWOIk².

Where a convolutional network is compressed using TT, the computation of inferencing with the tensor decomposed CNN may be as follows in Equation 14:

Y′=(h′,w′,o₁, . . . o_{d})=Σₖ_{₁}^{k}Σₖ_{₂}^{k}Σᵣ_{₁}_{. . . i}_{_{d}}^{R}^{₁}^{. . . R}^{_{d}}Σᵢ_{₁}_{. . . i}_{_{d}}^{I}^{₁}^{. . . I}^{_{d}}G₀(k₁, k₂, r₁)xG₁(r₁, o, i, r₂)x . . . G_{d}(r_{d}, o_{d}, i_{d}), Equation (14)

However, this result in a computation cost of H′W′OIk²R₁ . . . R_{d}, is R₁ . . . R_{d} times as costly as a standard convolution computation.

Accordingly, the compact TT convolution computation for inferencing with a tensor decomposed CNN may be performed in accordance with embodiments described herein using Equation 15 below:

Z₁(h,w,r₂)=Σᵢ^{I}G₃(r₂,i)X(h,w,i),

Z₂(h′,w′,r₁)=Σₖ^{k}^{₂}Σᵣ_{₂}^{r}^{₂}G₁(r₁,k,r₂)Z₁(h,w,r₂),

Y(h′,w′,o)=Σᵣ_{₁}^{R}^{₁}Z₂(h′,w′,r₁)G₁(o,r₁) Equation (15)

This results in a computation cost of HWIR₁+H′W′k²R₁R₂+H′W′OR₁, which is less costly than the conventional TT convolution scheme.

Equation 15 has been represented for a particular case of a tensor decomposed CNN. A general case compact TT convolution computation may be performed according to Equation 16 below:

$${Z}_{1} ( h , w , {i}_{2} , … , {i}_{d} , {r}_{d + 1} , {r}_{d + 2} ) = {\sum }_{{i}_{1}}^{{I}_{1}} {G}_{d + 2} ( {r}_{d + 1} , i , {r}_{d + 2} ) {X}^{′} ( h , w , {i}_{1} , … , {i}_{d} ) , \qquad Equation ( 16 )$$

$$…$$

$${Z}_{d} ( h , w , {r}_{d} ) = {\sum }_{{i}_{d}}^{{I}_{d}} {\sum }_{{r}_{2 d + 1}}^{{R}_{2 d + 1}} {G}_{2 d + 1} ( {r}_{2 d + 1} , {i}_{d} ) {Z}_{d - 1} ( h , w , {i}_{d} , {r}_{d + 1} , {r}_{2 d + 1} ) ,$$

$${Z}_{d + 1} ( {h}^{′} , {w}^{′} , {r}_{d} ) = {\sum }_{k}^{{k}^{2}} {\sum }_{{r}_{d + 1}}^{{R}_{d + 1}} {G}_{d + 1} ( {r}_{d} , k , {r}_{d + 1} ) {Z}_{d} ( h , w , {r}_{d + 1} ) , \\ … \\ Y ( {h}^{′} , {w}^{′} , {o}_{1} , … , {o}_{d} ) = {\sum }_{{r}_{1}}^{{R}_{1}} {Z}_{2 d + 1} ( {h}^{′} , {w}^{′} , {o}_{1} , … , {o}_{d} , {r}_{1} ) {G}_{1} ( o , {r}_{1} )$$

### 3. Hardware Architecture

In some embodiments, based on the efficient tensor decomposed inference scheme in TIE, a specially configured hardware architecture of tensor train-based inference engine may be produced.

### 3.1 Data Mapping and Processing Scheme

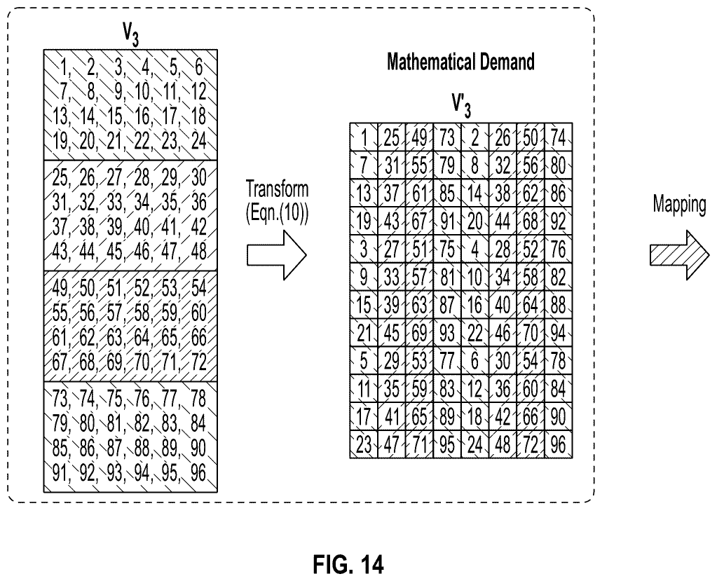

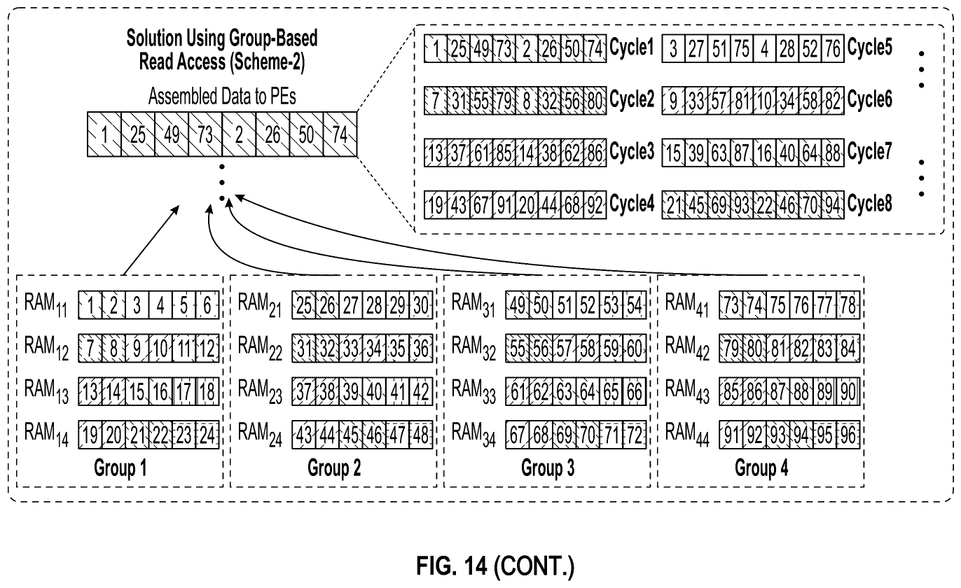

FIGS. 6A and 6B show the overall computing flow of the TIE. In some embodiments, the overall computing flow of the TIE may include two types of operation: reshaping the inputs (x to X′ and Vₕ to V′ₕ) and multiplying V′ₕ and \tilde{G}ₕ₋₁. Considering reshaping x to X′ may be prepared offline and reshaping Vₕ to V′_{h may} be performed by carefully designed memory access scheme in Section 3.4, the data-path of TIE is mainly responsible for executing matrix multiplication. FIG. 14 illustrates the detailed data mapping and processing scheme of an example 2-PE data-path for the multiplication between 3×2 \tilde{G}ₕ₋₁ and 2×4 V′ₕ matrices. In some embodiments, each PE is equipped with 3 multiply-accumulate (MAC) units. In each clock cycle, one column of \tilde{G}ₕ₋₁ is broadcast to all the PEs, where each multiplier of PE receives one element of the column. Meanwhile, in some embodiments, two elements in the same row of V′ₕ are sent to two PEs, respectively; and each of these elements in V′ₕ is broadcast to all the multipliers of their corresponding PEs. After finishing the computation in the current cycle, in the next cycle PEs may be move on to process the next column of \tilde{G}ₕ₋₁ and next row of V′ₕ. In some embodiments, with N_{PE} PEs equipped with N_{MAC} MAC units, the processing scheme may produce a N_{MAC}×N_{PE}-size sub-block of the result matrix Vₕ₋₁=\tilde{G}ₕ₋₁V′ₕ in N_{G}_{_{col}} cycles, where N_{G}_{_{col}} is the number of columns of \tilde{G}ₕ₋₁. In some embodiments, that when the number of rows of \tilde{G}ₕ₋₁ (as N_{G}_{_{row}}) is larger than N_{MAC} or number of columns of V′ₕ (as N_{V}_{_{col}}) is larger than N_{PE}, it takes PEs multiple N_{G}_{_{col}} cycles to calculate the entire Vₕ₋₁ (see FIG. 7).

### 3.2 Overall Architecture

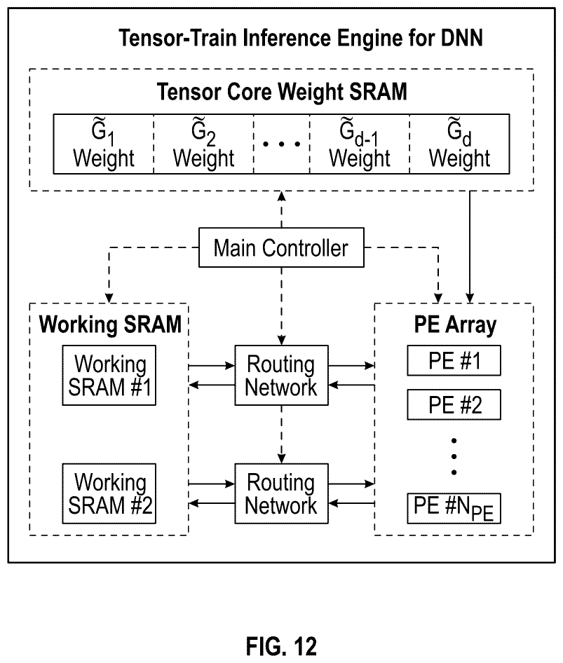

FIG. 12 illustrates an overall architecture of TIE in accordance with some embodiments of the present disclosure.

In some embodiments, based on the data mapping and processing scheme described above, the overall architecture of TIE is shown in FIG. 12. For the inference task on one layer, the data-path of TIE performs d-stage matrix multiplications between matrix V′ₕ read from the working SRAM and \tilde{G}ₕ₋₁ read from the weight SRAM. During the computation in each stage, as indicated in Section 3.1, part of the results matrix Vₕ₋₁=\tilde{G}ₕ₋₁V′ₕV′ₕ may already be calculated in the PEs, these sub-block of Vₕ₋₁, once available, may be written to another working SRAM. In some embodiments, according to this scheme, two working SRAMs may be used to avoid potential read/write conflict. In some embodiments, after some or all of the Vₕ₋₁ is written to one working SRAM, the SRAM may then output V′ₕ₋₁, as the reshaped Vₕ₋₁, to the data-path via a specifically designed memory read scheme (described in Section 3.4). Therefore, the two working SRAMs act as source and destination memories, respectively, and exchange their roles for every stage. In some embodiments, during the last stage of computations for V₁, the calculated elements of V₁ may be sent to activation units first and then written to working SRAM.

### 3.3 Data-Path &Weight SRAM

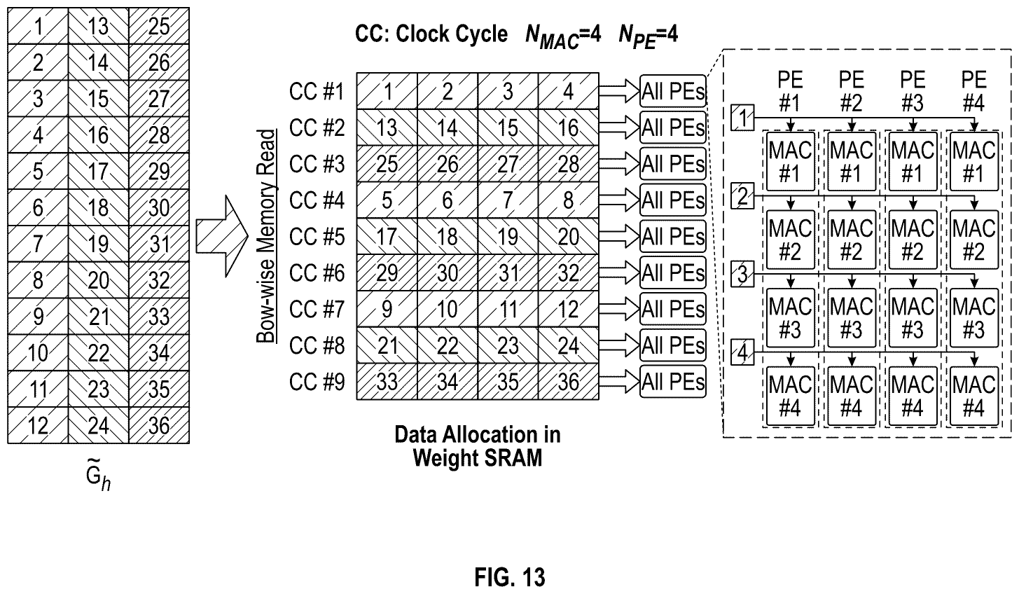

FIG. 13 illustrates a data allocation in weight SRAM in accordance with some embodiments of the present disclosure. In some embodiments, the SRAM may be defined by a data-path and weight SRAM.

In some embodiments, with respect to data-path, as shown in FIG. 12, TIE may include an array of N_{PE} PEs that perform matrix multiplication. In some embodiments, each PE contains N_{MAC} MAC units and N_{MAC} activation units. In some embodiments, by using the processing scheme in Section 3.1, the N_{MAC}N_{PE} elements of result matrix are available simultaneous in the registers of all PEs every N_{G}_{_{col}} cycles, and then they may be written to working SRAM in parallel.

In some embodiments, with respect to weight SRAM, the weight SRAM of TIE may store the weight parameters of tensor cores \tilde{G}ₕ's. In some embodiments, though each layer of tensor decomposed format DNN models is affiliated with d tensor cores, the sequential access to different \tilde{G}ₕ's in different computation stages, which is described in Section 2.2, enables the simple storing strategy of locating all \tilde{G}ₕ's in the same weight SRAM sequentially from h=1 to d. However, different from such sequential placement for the consecutive \tilde{G}ₕ's, the data allocation within the same \tilde{G}ₕ may not always be sequentially in the weight SRAM. For instance, as illustrated in FIG. 13, when the number of rows of \tilde{G}ₕ's is larger than the number of PEs, in order to be consistent with processing scheme described in Section 3.1, the elements in the same column of \tilde{G}ₕ need to be stored in the different row of weight SRAM via an interleaved way. Thus, in some embodiments, the entire data allocation of weight SRAM is sequential at the inter-\tilde{G}ₕ level and interleaved at the intra-\tilde{G}ₕ level.

### 3.4 Working SRAM

In some embodiments, as indicated in Algorithm 1, a transform from Vₕ to V′ₕ may be used in each stage of computation to ensure the functional correctness of the inference scheme. Conventionally, such transform, including matrix reshape and transpose, which demands extra memory resource to implement those matrix operations, thereby degrading the hardware performance of the entire design on both area efficiency and power efficiency.

In some embodiments, to address such problem, efficient read and write schemes may be designed for working SRAMs to achieve zero-cost matrix transform. In some embodiments, of the present general methodology is to ensure that the data-path reads the elements of V′ₕ from the working SRAM that stores Vₕ, thereby enabling on-the-fly matrix transform for Vₕ. In some embodiments, to achieve the on-the-fly transform, working SRAM may be partitioned to multiple groups with well-designed data selection mechanism.

In some embodiments, the writing scheme may be consistent with the computing scheme described above. As described above, the computing scheme (Section 3.1) each PE calculates N_{MAC} elements in the same column of Vₕ after every N_{G}_{_{col}} cycles. In some embodiments, to make data allocation in the working SRAM consistent with the corresponding matrix format of Vₕ, different PEs assemble the calculated elements in the same positions of MAC units together and write them to one row of component SRAMs. In some embodiments, during the writing phase the calculated elements in the i-th MAC units among different PEs form one row of data to be written to memory. In some embodiments, as mentioned before, each of the two working SRAMs is partitioned to multiple groups, where each group contains multiple component SRAMs. Based on this type of memory organization, multiple columns of V_{h may} be written to multiple component SRAMs concurrently without access conflict.

In some embodiments, a reading scheme may be designed for on-the-fly transform of Vₕ. As described above, the matrix transform operation on Vₕ may be performed during the reading phase using a partitioned group-based data selection mechanism. In some embodiments, Algorithm 2 describes an example of the mechanism in detail. In some embodiments, the transform mechanism may to utilize the indices of SRAM groups, component SRAMs and element to locate and read the targeted element of V′ₕ in a mathematically equivalent manner.

Algorithm 2: Data Read Scheme for Working SRAM

| | |
|---|---|
| Input | :Memory[N_{g}, Nᵣ, M]. Nᵣ component SRAMs are |
| | divided into N_{g} groups. Each group contains Nᵣ/N_{g} |
| | component SRAMs. Each component SRAM contains |
| | M elements. N_{PE} denotes the number of PE. |

Output:Data

| | |
|---|---|
| 1 | //Number of total cycles for reading data |

| 2 | ${N}_{c} = ⌊ \frac{{N}_{g} {N}_{r} M}{{N}_{PE}} ⌋$ | | | |
|---|---|---|---|---|
| 3 | while (k < N_{c}) do | | | |
| 4 | \| \| | $for j = 1 to ⌊ \frac{M}{{N}_{PE} / {N}_{g}} ⌋ do$ | | |
| 5 | \| | \| | for iᵣ = 1 to Nᵣ/N_{g} do | |
| 6 | \| \| | \| \| | \| \| | $Data = Read ( Memory ( : , {i}_{r} , [ j * ⌊ \frac{M}{{N}_{PE} / {N}_{g}} ⌋ :$ |
| | \| \| | \| \| | \| \| | $( j + 1 ) * ⌊ \frac{M}{{N}_{PE} / {N}_{g}} ⌋ ] ) )$ |
| 7 | \| | └ | └ | Data = ReArrange(Data) |
| 8 | └ | k++ | | |
| 9 | Function ReArrange (Data) | | | |
| 10 | \| \| | ${Data}^{′} = new [ {N}_{g} \times ⌊ \frac{M}{{N}_{PE} / {N}_{g}} ⌋ ]$ | | |
| 11 | \| \| | $for j = 1 to ⌊ \frac{M}{{N}_{PE} / {N}_{g}} ⌋ do$ | | |
| 12 | \| | \| | for i_{g} = 1 to N_{g} do | |
| 13 | \| | └ | └ | Data′[j * N_{g} + i_{g}] = Data(i_{g}, j) |

| | | |
|---|---|---|
| 14 | └ | Return Data′ |

FIG. 14 illustrates a perform-on-the-fly transform using well-designed working SRAM read access scheme in accordance with some embodiments of the present disclosure.

FIG. 14 illustrates the working SRAM reading scheme based on the data selection mechanism. As shown, in each cycle the elements of V′ₕ may be located and read from the rows of different component SRAMs of memory group. As shown in FIG. 14, after being assembled, these data may form the row vector of targeted V′ₕ, and then they may be distributed to their corresponding PEs for calculating Vₕ₋₁=\tilde{G}ₕ₋₁V′ₕ.

In some embodiments, besides the transform from Vₕ to V′ₕ, the inference on entire DNN models also require transform from V₁⁵ of this layer to X′ of next layer. In some embodiments, before being transformed, V₁ needs to be processed by the activation units in PEs first. Interestingly, embodiments of the present mathematical analysis shows that such inter-layer transform is identical to the intra-layer transform described before. Therefore, when the TIE is performing the computation between two consecutive layers, it may still utilize the working SRAM read scheme.

### 4 Evaluation

### 4.1 Experimental Methodology

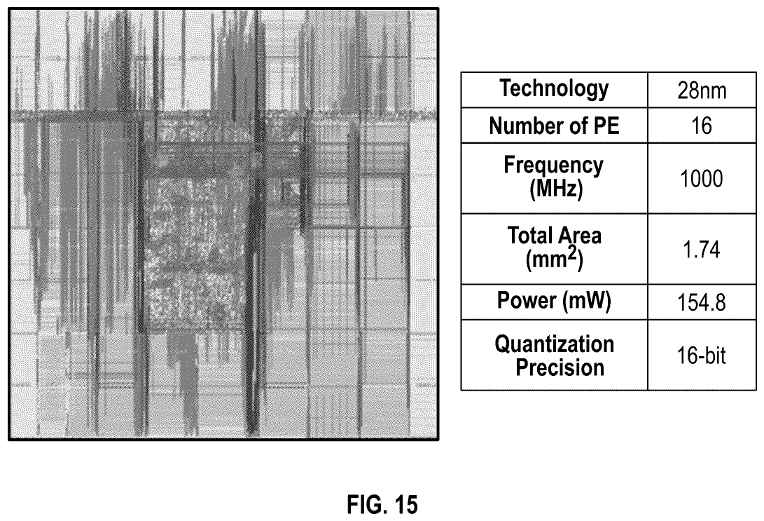

In some embodiments, high-level functional behavior of TIE may be modeled by a bit-accurate cycle-accurate simulator. Based on the model, an RTL model may be developed using Verilog and verified the functional validity of the RTL model. In some embodiments, the verified RTL model may be synthesized using Synopsis Design Compiler with CMOS 28 nm library. Here the gate-level netlist may be annotated with toggle rate that may be obtained from the extracted switching activity during the simulation. After that we used Synopsis IC Compiler to perform place and route and generate layout (see FIG. 15). Then, Synopsis Prime-Time PX may be used to estimate power consumption. Notice that the area and power of memory part were reported by Cacti.

FIG. 15 illustrates a layout and performance metrics of TIE in accordance with some embodiments of the present disclosure.

Benchmarks. To evaluate the performance of TIE on different tasks, we choose several workloads from two models used in image classification and video classification tasks, respectively. Here the same-size layers with different TT-decomposition setting are viewed as different workloads. Table 4 lists the information of four benchmark layers, including the size, TT-decomposition settings (d, n, m, and r) and compression ratio.

TABLE 4
Information of evaluated benchmarks.

| | | | | | | Compression | |
|---|---|---|---|---|---|---|---|
| Layer | Size | d | n | m | r | Ratio | Tasks |
| VGG-FC6 | (4096, 25088) | 6 | [2, 7, 8, 8, 7, 4] | [4, 4, 4, 4, 4, 4] | [1, 4, 4, 4, 4, 4, 1] | 50972× | CNN model |
| VGG-FC7 | (4096, 4096) | 6 | [4, 4, 4, 4, 4, 4] | [4, 4, 4, 4, 4, 4] | [1, 4, 4, 4, 4, 4, 1] | 14564× | for |
| | | | | | | | image |
| | | | | | | | classification |
| LSTM-UCF | (57600, 256) | 4 | [8, 20, 20, 18] | [4, 4, 4, 4] | [1, 4, 4, 4, 1] | 4954× | RNN models |
| LSTM-Youtube | (57600, 256) | 4 | [4, 20, 20, 36] | [4, 4, 4, 4] | [1, 4, 4, 4, 1] | 4608× | for video |
| | | | | | | | classification |

### 4.2 Hardware Performance

Design Configuration. Table 5 shows the configuration information of the TIE hardware. The entire design consists of 16 PEs with 16-bit quantization. For each PE, it is equipped with 16 MACs and 16 activation units, where each MAC contains one 16-bit width multiplier and one 24-bit width accumulator. Regarding the memory, a 16 KB Weight SRAM is used to store up to 8192 16-bit weights on the chip. According to Section 2.3, such memory budgeted capacity for weight SRAM is sufficient for most TT-DNN models. For working SRAM, it contains two copies acting as ping-pong buffer, where each copy has the capacity as 384 KB. Therefore, the total capacity of working RAM is 384×2=768 KB.

TABLE 5
Design configuration information.

| PE Parameter | Multiplier | Accumulator |
|---|---|---|
| Amount | 16 | 16 |
| Width | 16-bit | 24-bit |
| Memory Parameter | Weight SRAM | Working |
| | | SRAM |
| Capacity | 16 KB | 768 KB |
| TIE parameter | Amount of PEs | Quantization |
| Value | 16 | 16-bit |

Hardware Resources and Performance. FIG. 15 shows the overall hardware source and performance of TIE design. Operating on 1000 MHz, the 16-PE TIE occupies 1.74 mm₂ silicon area and consumes 154.8 mW power. Notice that all the memory used in TIE are on-chip SRAM due to the high compression ratio brought by TT decomposition. The area and power breakdown are shown in Table. 6.

TABLE 6
Power and area breakdowns.

| Component | Power (mW) | | Area (mm²) | |
|---|---|---|---|---|
| Memory | 60.8 | (39.28%) | 1.29 | (73.93%) |
| Register | 10.9 | (7.04%) | 0.019 | (1.11%) |
| Combinational | 54 | (34.88%) | 0.082 | (4.70%) |
| Clock Network | 29.1 | (18.80%) | 0.0035 | (0.02%) |

| | | |
|---|---|---|
| Other | 0.35 | (20.06%) |

| | | |
|---|---|---|
| Total | 154.8 | 1.744 |

4.3 Comparison with EIE, C_{IR}CNN, and Eyeriss

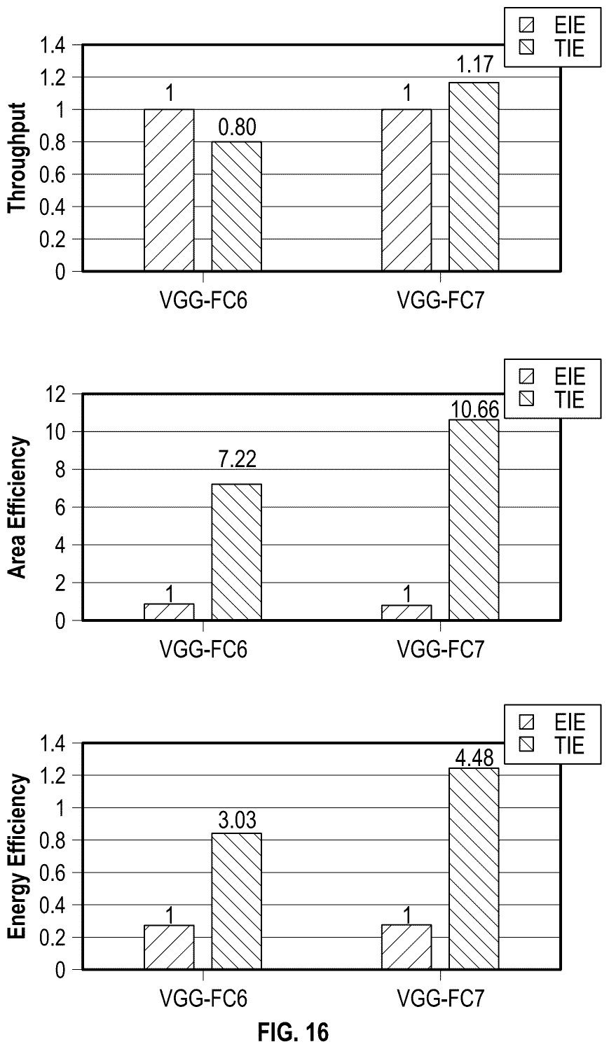

FIG. 16 illustrates performance comparison between EIE and TIE on different benchmarks in accordance with some embodiments of the present disclosure.

In this subsection, we compare TIE with two state-of-the-art compressed DNN-targeted accelerators: EIE and C_{IR}CNN. Different from TIE, model compression in EIE and C_{IR}CNN comes from other sources: For EIE, model compression is achieved via network sparsification; for C_{IR}CNN, model compression is from structuring topology. Moreover, to evaluate the performance of TIE on CONV layers, we also compare TIE with representative CONV-oriented work: Eyeriss.

Comparison with EIE. Table 7 summarizes the design parameters and hardware performance of EIE and TIE. Due to the different technology nodes adopted in the two works, the clock frequency, silicon area and power consumption of EIE are also projected under the same 28 nm technology for fair comparison. Such projection is based on the scaling rule used in linear, quadratic and constant scaling for frequency, area and power, respectively.

TABLE 7
Comparisons of EIE and TIE.

| Design | EIE | | TIE |
|---|---|---|---|
| CMOS Tech. | 45 nm | 28 nm | 28 nm |
| | (reported) | (projected) | |
| Frequency (MHz) | 800 | 1285 | 1000 |
| Memory | SRAM | | SRAM |
| Quantization | 4-bit for weight index, | | 16-bit |
| | 16-bit forshared weight | | |
| Area (mm²) | 40.8 | 15.7 | 1.74 |
| Power (mW) | 590 | 590 | 154.8 |

FIG. 16 compares the hardware performance of EIE and TIE on two benchmarks (VGG-FC6 and VGG-FC7) in terms of throughput, area efficiency and energy efficiency. We see that TIE may achieve a comparable throughput with EIE. More importantly, thanks to the high compression ratio brought by TT decomposition, TIE achieves 7.22×˜10.66× better area efficiency and 3.03×˜4.48× better energy efficiency on different workloads, respectively.

Comparison with C_{IR}CNN. Table 8 compares the hardware performance of C_{IR}CNN and TIE. Notice that here the listed performance metrics of the two designs are obtained from their synthesis reports for fair comparison since C_{IR}CNN reports synthesis results.

TABLE 8
Comparisons of C_{IR}CNN and TIE.

| Design | C_{IR}CNN | | TIE |
|---|---|---|---|
| CMOS Tech. | 45 nm | 28 nm | 28 nm |
| | (reported) | (projected) | |
| Freq (MHz) | 200 | 320 | 1000 |
| Quantization | 16-bit | | 16-bit |
| Area (mm²) | N/A | N/A | 1.40 |
| Power (mW) | 80 | 80 | 104.8 |
| Throughput | 0.8 | 1.28 | 7.64 |
| (TOPS) | | | (5.96×) |
| Energy Efficiency | 10.0 | 16.0 | 72.90 |
| (TOPS/W) | | | (4.56×) |

Meanwhile, due to the lack of area information of C_{IR}CNN, we compare the overall throughput (in term of TOPS) and energy efficiency (in term of TOPS/W) of the two designs. After projecting performance of CIRCNN to the same 28 nm technology for fair comparison, it is seen that TIE achieves 5.96× and 4.56× higher throughput and energy efficiency than C_{IR}CNN, respectively.

Comparison with Eyeriss. Table 9 summarizes the design parameters and hardware performance of Eyeriss and TIE on CONV layers of VGG. For fair comparison, the clock frequency, silicon area and power consumption of Eyeriss are also projected under the 28 nm technology. We used core area and processing latency of Eyeriss instead of chip area and total latency for fair comparison with TIE.

TABLE 9
Comparisons of Eyeriss and TIE on VGG CONV layers.⁶

| Design | Eyeriss | | TIE |
|---|---|---|---|
| CMOS Tech. | 65 nm | 28 nm | 28 nm |
| | reported | (projected) | |
| Freq (MHz) | 200 | 464 | 1000 |
| Quantization | 16-bit | | 16-bit |
| Area (mm²) | 12.25 | 2.27 | 1.74 |
| Power (mW) | 236 | 236 | 170 |
| Throughput | 0.8 | 1.86 | 6.72 |
| (Frame/s) | | | (3.61×) |
| Area Efficiency | 0.065 | 0.82 | 3.86 |
| (Frame/s/W) | | | (4.71×) |
| Energy Efficiency | 3.39 | 7.89 | 39.5 |
| (Frame/s/mm²) | | | (5.01×) |

### 4.4 Flexibility

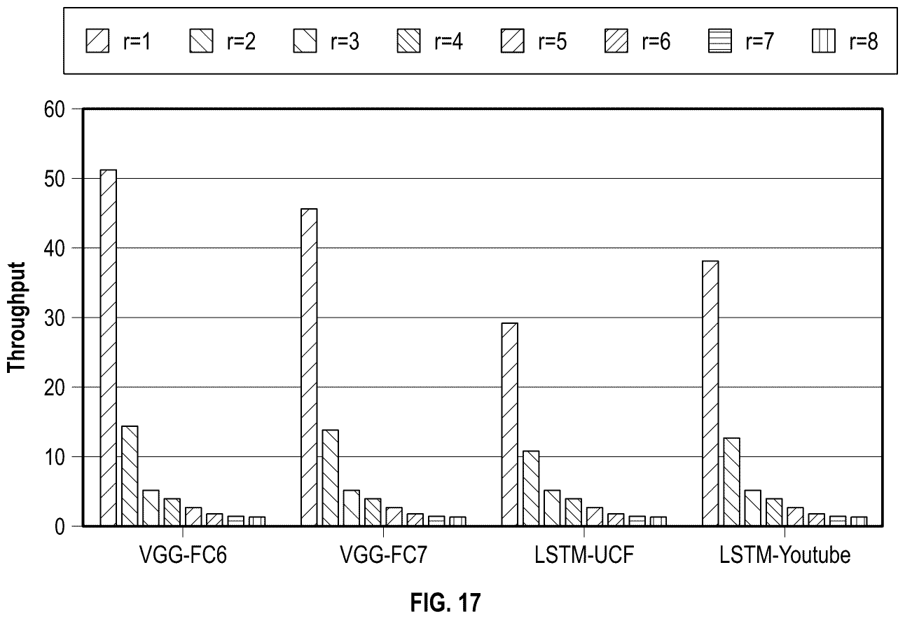

FIG. 17 illustrates a flexibility of TIE on different decomposition ranks in accordance with some embodiments of the present disclosure.

TIE is designed to provide sufficient flexibility to support the needs of different TT models having different layer sizes and decomposition settings. As illustrated in FIG. 17, different workloads with different d,m, n and r may be executed on the same TIE accelerator hardware efficiently in a flexible way. In addition, we also investigate the throughput with different r's for the same workload (see FIG. 17. Here the change of r is specifically studied since it is an important metric to provide flexible control the compression and acceleration effect of TT decomposition. From the FIG. we may see that TIE exhibits great flexibility to support the flexibility for this important TT decomposition parameter.

### Example—Training of Tensor Decomposition Deep Neural Network

In some embodiments, tensor decomposition is a tool that explores the low tensor rank characteristics of the largescale tensor data. Different from other model compression methods, tensor decomposition, uniquely, may provide ultra-high compression ratio for DNNs, including CNN and RNN models. The advanced tensor decomposition approaches, such as tensor train (TT) and tensor ring (TR), among others, may bring more than one thousand times parameter reduction to the input-to-hidden layers of DNN models, and meanwhile the corresponding classification accuracy in the video recognition task may be even significantly improved.

In some embodiments, typical tensor decomposition approaches, including TT and TR, suffer accuracy loss when compressing a trained DNN. CNN models exhibit the greatest accuracy loss.

The accuracy loss due to tensor decomposition is mainly due to the unique challenges involved in training the tensor decomposed format DNN models. In general, there are typically two ways to use tensor decomposition to obtain a compressed model: 1) Train from scratch in the decomposed format; and 2) Decompose a pre-trained uncompressed model and then retrain. In the former case, when the required tensor decomposition-based, e.g., tensor decomposed format model, is directly trained from scratch, because the structure of the models are already pre-set to low tensor rank format before the training, the corresponding model capacity is typically limited as compared to the full-rank structure, thereby causing the training process being very sensitive to initialization and more challenging to achieve high accuracy. In the latter scenario, though the pre-trained uncompressed model provides good initialization position, the straightforwardly decomposing full-rank uncompressed model into low tensor rank format causes inevitable and non-negligible approximation error, which is very difficult to be recovered even after long-time re-training period. Moreover, in either training approach, tensor decomposition always brings linear increase in network depth, which implies training the tensor decomposition-format DNNs are typically more prone to gradient vanishing problem and hence being difficult to be trained well.

In some embodiments, to overcome the current limitations of tensor decomposition and fully unlock its potentials for model compression, a systematic framework for tensor decomposition-based model compression using a dual problem optimization problem, such as, e.g., alternating direction method of multipliers (ADMM), dual ascent method (DAM), dual decomposition, among other suitable dual problem optimization problems or any combination thereof. By formulating TT decomposition-based model compression to an optimization problem with constraints on tensor ranks, the dual problem optimization problem may be leveraged to systemically solve the optimization problem in an iterative way. During this procedure the entire DNN model is trained in the original structure instead of tensor decomposed format, but gradually enjoys the desired low tensor rank characteristics. The trained uncompressed model may then be decomposed to tensor decomposed format and fine-tuned to finally obtain a high-accuracy trained tensor decomposed format DNN model.

In some embodiments, the systematic framework may include formulating and solving the tensor decomposition-based model compression problem. With formulating this problem to a constrained non-convex optimization problem, embodiments of the present framework gradually restricts the DNN model to the target tensor ranks without explicitly training on the tensor decomposed, thereby maintaining the model capacity as well as minimizing approximation error and increased network depth.

In some embodiments, the systematic framework employs a dual optimization problem such as ADMM to efficiently solve the reformulated optimization problem via separately solving two sub-problems. In some embodiments, a first sub-problem may be to directly optimize the loss function with a regularization of the DNN, e.g., by stochastic gradient descent or other suitable optimization method. In some embodiments, the second sub-problem may use the introduced projection to constrain the tensor ranks analytically.

In an example implementation of the framework, on an evaluation of different example DNN models for image classification and video recognition tasks are described. The example evaluation results show that embodiments of the present dual optimization problem-based tensor decomposed format models demonstrate high compression performance with high accuracy. For example, on CIFAR-100, with 2.3 times and 2.4 times compression ratios, embodiments of the present models have 1.96% and 2.21% higher top-1 accuracy than the original ResNet-20 and ResNet-32, respectively. For compressing an example ResNet-18 on ImageNet, embodiments of the present model achieves 2.47 FLOPs reduction with no accuracy loss.

### 5 Framework Initialization

### 5.1. Notation

In some embodiments, [symbol] ∈ [symbol] ⁿ^{₁}^{×n}^{₂}^{×. . . , ×n}^{_{d}}, X∈ [symbol] ⁿ^{₁}^{×n}^{₂}, and x∈ [symbol] ⁿ^{₁}, represent d-order order tensor, matrix and vector, respectively. Also, [symbol] ₍ᵢ_{₁}_{, . . , i}_{_{d}}₎ and X_{(i,j)} denote the single entry of tensor [symbol] and matrix X, respectively.

### 5.2. Tensor Train (TT) Decomposition

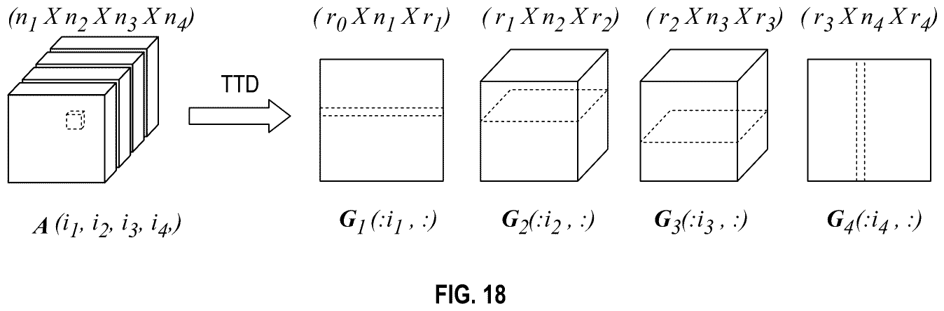

In some embodiments, given a tensor [symbol] ∈ [symbol] ⁿ^{₁}^{×n}^{₂}^{×. . . ,×n}d, the tensor may be decomposed to a sort of 3-order tensors via Tensor Train Decomposition (TTD) as follows:

$$\begin{matrix}{𝒜}_{( {i}_{1} , {i}_{2} , … , {i}_{d} )} = {𝒢}_{1 ( : , {i}_{1} , : )} {𝒢}_{2 ( : , {i}_{2} , : )} … {𝒢}_{d ( : , {i}_{d} , : )} \\ = {\sum }_{{α}_{0} , {α}_{1} … {α}_{d}}^{{r}_{0} , {r}_{1} , … {r}_{d}} {𝒢}_{1 ( {α}_{0} , {i}_{1} , {α}_{1} )} {𝒢}_{2 ( {α}_{1} , {i}_{2} , {α}_{2} )} … \\ {𝒢}_{d ( {α}_{d - 1} , {i}_{d} , {α}_{d} )}\end{matrix} , \qquad Equation ( 17 )$$

where [symbol] ₖ∈ [symbol] ^{r}k−1^{×n}^{ₖ}^{×r}^{ₖ} are called TT-cores for k=1,2, . . . , d, and r=[r₀,r₁, . . . , r_{d}], r₀=r_{d}=1 are called TT-ranks, which determine the storage complexity of tensor decomposed format tensor. An example is demonstrated in FIG. 18.

### 5.3. Tensor Train (TT)-Format DNN

In some embodiments, a simple fully-connected layer with weight matrix [symbol] ∈ [symbol] ^{M×N} and input x∈ [symbol] ^{N}, where M=Πₖ₌₁^{d}mₖ and N=Πₖ₌₁^{d}nₖ, the output x∈ [symbol] ^{M} may be obtained by y= [symbol] x. In some embodiments, in order to transform this standard layer to TT fully-connected (TT-FC) layer, the weight matrix [symbol] may be tensorized to a weight tensor [symbol] ∈ [symbol] ^{(m}^{₁}^{×n}^{₁}^{)×. . . ×(m}^{_{d}}^{×n}^{_{d}}⁾ by reshaping and order transposing. Then [symbol] may be decomposed to tensor decomposed format:

[symbol]

₍₍ᵢ_{₁}_{,j}_{₁}_{), . . . , (i}_{_{d}}_{,j}_{_{d}}₎₎= [symbol] _{1(i, i}_{₁}_{,j}_{₁}_{,:)} . . . [symbol] _{d(:,i}_{_{d}}_{,j}_{_{d}}_{,:)}. Equation (18)

In some embodiments, each TT-core [symbol] ₖ∈ [symbol] ^{r}^{_{k−1}}^{×m}^{ₖ}^{×n}^{ₖ}^{×r}^{ₖ} may be a 4-order tensor, which is one dimension more than the standard one since the output and input dimensions of [symbol] are divided separately. Hence, the forward propagation on the TT-FC layer may be expressed in tensor format as follows:

$${𝓎}_{( {i}_{1} , … , {i}_{d} )} = {\sum }_{{j}_{1} , … , {j}_{d}} {𝒢}_{1 ( : , {i}_{1} , {j}_{1} , : )} … {𝒢}_{d ( : , {i}_{d} , {j}_{d} , : )} {𝒳}_{( {j}_{1} , … , {j}_{d} )} , \qquad Equation ( 19 )$$

where [symbol] ∈ [symbol] ^{m}^{₁}^{×. . . , ×m}^{_{d}} and [symbol] ∈ [symbol] ⁿ^{₁}^{×, . . . ,×n}^{_{d}}, are the tensorized input and output corresponding to x and y, respectively. In some embodiments, additional details about a TT-FC layer may be found in Xuefei Ning, Tianchen Zhao, Wenshuo Li, Peng Lei, Yu Wang, and Huazhong Yang. Dsa: “More efficient memory budgeted pruning via differentiable sparsity allocation.” In the European Conference on Computer Vision (ECCV), 2020, which is herein incorporated by reference in its entirety.

In some embodiments, for a conventional convolutional layer, forward computation performs convolution between a 3-order input tensor [symbol] ∈ [symbol] ^{W×H×N} and a 4-order weight tensor [symbol] ∈ [symbol] ^{K×K×M×N} to produce the 3-order output tensor [symbol] ∈ [symbol] ^{(W-K+1)×(H-K+1)×M}. In some embodiments, in a TT convolutional (TT-CONV) layer, the input tensor [symbol] is reshaped to a tensor [symbol] ∈ [symbol] ^{W×H×n}^{₁}^{×. . . , ×n}^{_{d}}, while the weight tensor [symbol] is reshaped and transposed to a tensor [symbol] ∈ [symbol] ^{(K×K)×(m}^{₁}^{×n}^{₁}^{)×. . . ×(m}^{_{d}}^{×n}^{_{d}}⁾ and then decomposed to tensor decomposed format:

[symbol]

₍₍ₖ_{₁}_{,k}_{₂}_{),(i}_{₁}_{,j}_{₁}_{), . . . ,(i}_{₁}_{,j}_{_{d}}₎₎= [symbol] ₀₍ₖ_{₁}_{,k}_{₂}₎ [symbol] _{1(:,i}_{₁}_{,j}_{₁}_{,:)} . . . [symbol] _{d(:,i}_{_{d}}_{,j}_{_{d}}_{,:)}, Equation (20)

where M=Πₖ₌₁^{d}mₖ and N=Πₖ₌₁^{d}nₖ. Similar with TT-FC layer, here [symbol] ₖ∈ [symbol] ^{r}^{_{k−1}}^{×m}^{ₖ}^{×n}^{ₖ}^{×r}^{ₖ} is a 4-order tensor except [symbol] ₀∈ [symbol] ^{K×K}. In some embodiments, the new output tensor [symbol] ∈ [symbol] ^{(W-K+1)×(H-K+1)×m}^{₁}^{×. . . , ×m}^{_{d}} may then be obtained by

$${𝓎}_{( w , h , {i}_{1} , … , {i}_{d} )} = \qquad Equation ( 21 )$$

$${\sum }_{{k}_{1} = 1}^{K} {\sum }_{{k}_{2} = 1}^{K} {\sum }_{{j}_{1} , … , {j}_{d}} {𝒳}_{( {k}_{1} + w - 1 , {k}_{2} + h - 1 , {j}_{1} , … , {j}_{d} )} {𝒢}_{0 ( {k}_{1} , {k}_{2} )} {𝒢}_{1 ( : , {i}_{1} , {j}_{1} , : )} … {𝒢}_{d ( : , {i}_{d} , {j}_{d} , : )} .$$

In some embodiments, additional description of a TT-CONV layer may be found in Timur Garipov, Dmitry Podoprikhin, Alexander Novikov, and Dmitry Vetrov. “Ultimate tensorization: compressing convolutional and fc layers alike.” arXiv preprint arXiv:1611.03214, 2016, which is herein incorporated by reference in its entirety.

In some embodiments, tensor decomposed format as the TT-FC layer, the TT-CONV layer and the corresponding forward propagation schemes are formulated, a suitable optimization method, such as, standard stochastic gradient descent (SGD) algorithm, may be used to update the TT-cores with the rank set r, which determines the target compression ratio. The initialization of the TT-cores may be either randomly set or obtained from directly TT-decomposing a pre-trained uncompressed model.

### 6 Systematic Compression Framework

In some embodiments, tensor decomposed format as described above, currently a tensor decomposed format DNN is either 1) trained from with randomly initialized tensor cores; or 2) trained from a direct decomposition of pre-trained model. For the first strategy, information related to the high-accuracy uncompressed model is unused and thus lost. For the second strategy, though the knowledge of the pre-trained model is indeed utilized, because the pre-trained model generally lacks low TT-rank property, after direct low-rank tensor decomposition the approximation error is too significant to be properly recovered even using long-time re-training. Such inherent limitations of the existing training strategies, consequently, cause significant accuracy loss for the compressed tensor decomposed format DNN models.

In some embodiments, to overcome the above described limitations to maximally retain the knowledge contained in the uncompressed model, or in other words, minimize the approximation error after tensor decomposition with given target tensor ranks, an optimization problem is formulated to minimize the loss function of the uncompressed model with low tensor rank constraints. With proper advanced optimization technique (e.g., a dual optimization problem such as ADMM, Dam, dual decomposition, etc.) regularized training procedure, the uncompressed DNN models may gradually exhibit low tensor rank properties. After the regularized training phase, the approximation error brought by the explicit low-rank tensor decomposition becomes negligible and may be easily recovered by the fine-tuning (e.g., with stochastic gradient descent or other suitable optimization method). FIG. 19 illustrates the steps of the framework of embodiments of the present disclosure.

### 6.1. Problem Formulation

In some embodiments, as described above, the first phase of the present framework may be to iteratively impose low tensor rank characteristics onto a high-accuracy uncompressed DNN model. Mathematically, this goal may be formulated as an optimization problem to minimize the loss function of the object model with constraints on TT-ranks of each layer (convolutional or fully-connected):

$${min}_{𝒲} ℓ ( 𝒲 ) , \\ s . t . rank ( 𝒲 ) ⩽ {r}^{*} , \qquad Equation ( 22 )$$

where [symbol] is the loss function of the DNN , rank(⋅) is a function that returns the TT-ranks r=[r₀, . . . ,r_{d}] of the weight tensor cores, and r*=[r*₀, . . . , r*_{d}] are the desired TT-ranks for the layer. To simplify the notation, here r≤r* means rᵢ≤r*_{i, i=}0, . . . , d, for each rᵢ in r.

### 6.2. Optimization Using ADMM

In some embodiments, solving the equation (22) may be generally difficult via normal optimization algorithms since rank(⋅) is non-differentiable. In some embodiments, to overcome this challenge, Equation 22 may be rewritten as:

$${min}_{𝒲} ℓ ( 𝒲 ) , \\ s . t . 𝒲 ∈ 𝒮 , \qquad Equation ( 23 )$$

where [symbol] ={ [symbol] |rank( [symbol] )≤r*}. Hence, the objective form (23) is a classic non-convex optimization problem with constraints, which may be properly solved by the dual optimization problem. Specifically, we may first introduce an auxiliary variable [symbol] and an indicator function g(⋅) of [symbol] , i.e.

$$g ( 𝒲 ) = \{ \begin{matrix}0 & 𝒲 ∈ 𝒮 , \\ + ∞ & otherwise\end{matrix} . \qquad Equation ( 24 )$$

And then the equation (23) is equivalent to the following form:

$${min}_{𝒲 ,} ℓ ( 𝒲 ) + g ( ) , \\ s . t . 𝒲 = . \qquad Equation ( 25 )$$

In some embodiments, to ensure convergence without assumptions like strict convexity or finiteness of [symbol] , instead of Lagrangian, the corresponding augmented Lagrangian in the scaled dual form of the above equation is given by:

$${ℒ}_{ρ} ( 𝒲 , , 𝒰 ) = ℓ ( 𝒲 ) + g ( ) + \frac{ρ}{2} {‖ 𝒲 - + 𝒰 ‖}_{F}^{2} + \frac{ρ}{2} {‖ 𝒰 ‖}_{F}^{2} , \qquad Equation ( 26 )$$

where [symbol] is the dual multiplier, and ρ>0 is the penalty parameter. Thus, the iterative ADMIVI scheme may be explicitly performed as

$${𝒲}^{t + 1} = {arg min}_{𝒲} {ℒ}_{ρ} ( 𝒲 , {t}^{} , {𝒰}^{t} ) , \qquad Equation ( 27 )$$

$${t + 1}^{} = {arg min}_{} {ℒ}_{ρ} ( {𝒲}^{t + 1} , , {𝒰}^{t} ) , \qquad Equation ( 28 )$$

$${𝒰}^{t + 1} = {𝒰}^{t} + {𝒲}^{t + 1} - {t + 1}^{} , \qquad Equation ( 29 )$$

where t is the iterative step. In some embodiments, the original equation (25) may be separated to two sub-equations (27) and (28), which may be solved individually. In some embodiments, each sub-equation may be solved at each training iteration.

In some embodiments, with regards to the [symbol] -sub-equation (29). The [symbol] -sub-equation (27) may be reformulated as follows:

$${min}_{𝒲} ℓ ( 𝒲 ) + \frac{ρ}{2} {‖ 𝒲 - {t}^{} + {𝒰}^{t} ‖}_{F}^{2} , \qquad Equation ( 30 )$$

where the first term is the loss function, e.g., cross-entropy loss in classification tasks, of the DNN model, and the second term is the L₂ -regularization. In some embodiments, sub-problem (30) may be directly solved by stochastic gradient descent since both of the two terms are differentiable. Correspondingly, the partial derivative of (30) with respect to [symbol] is calculated as:

$$\frac{\partial {ℒ}_{ρ} ( 𝒲 , {t}^{} , {𝒰}^{t} )}{\partial 𝒲} = \frac{\partial ℓ ( 𝒲 )}{\partial 𝒲} + ρ ( 𝒲 - {t}^{} + {𝒰}^{t} ) . \qquad Equation ( 31 )$$

And hence [symbol] may be updated by:

$${𝒲}^{t + 1} = {𝒲}^{t} - η \frac{\partial {ℒ}_{ρ} ( 𝒲 , {t}^{} , {𝒰}^{t} )}{\partial 𝒲} , \qquad Equation ( 32 )$$

where ρ is the learning rate.

In some embodiments, with regards to the [symbol] -sub-problem (28), to solve [symbol] -sub-problem (28) may be explicitly formulated it as follows:

$${min}_{} g ( ) + \frac{ρ}{2} {‖ {𝒲}^{t + 1} - + {𝒰}^{t} ‖}_{F}^{2} , \qquad Equation ( 33 )$$

where the indicator function g(⋅) of the non-convex set [symbol] is non-differentiable. Then, in this format updating [symbol] may be performed as:

[symbol]

^{t+1}= [symbol] ( [symbol] ^{t+1}+ [symbol] ^{t}), Equation (34)

where [symbol] (⋅) is the projection of singular values onto [symbol] , by which the TT-ranks of ( [symbol] ^{t+1}+ [symbol] ^{t}) are truncated to target ranks r*. Algorithm 3 describes an example of a specific procedure of this projection in the tensor decomposed format scenario.

In some embodiments, in each dual optimization problem iteration, upon the update of [symbol] and [symbol] , the dual multiplier [symbol] is updated by (29). In overall, to solve (25), the entire dual optimization problem-regularized training procedure is performed in an iterative way until convergence or reaching the pre-set maximum iteration number. The overall procedure is summarized in Algorithm 4.

Algorithm 3: TT-SVD-based Project for Solving Equation (34)

```
Input: d-order tensor [symbol]     ϵ [symbol]    ⁿ¹ [symbol] ^{nd}, target TT-ranks r*.
Output: [symbol]    ( [symbol]   ).
  1: Temporary tensor [symbol]     = [symbol]    ;
  2: for k = 1 to d − 1 do
  3: [symbol]     = reshape( [symbol]   , [rₖ₋₁*nₖ, −1]);
  4:  Compute matrix SVD: U, S, V := SVD( [symbol]   );
  5:  U := U₍₁ [symbol] ₎;
  6:  S := S₍₁ [symbol] ₎;
  7:  V := V₍ [symbol] ₎;
  8: [symbol]    ₖ := reshape(U, [rₖ₋₁*, nₖ, rₖ*]);
  9: [symbol]     := SV^{T};
10: [symbol]     := [symbol]    ₁;
11: for k = 1 to d − 1 do
12:  T₁ := reshape( [symbol]   , [−1, rₖ*]);
13:  T₂ := reshape( [symbol]   ₖ₊₁, [rₖ*, −1]);
14: [symbol]     := T₁T₂;
15: [symbol]     = reshape( [symbol]   , [n₁, . . . , n_{d}]). [symbol]
indicates data missing or illegible when filed
```

Algorithm 4: ADMM-Regularized Training Procedure

```
Input: Weight tensor [symbol]    , target TT-ranks r*, penalty pa-
    rameter ρ, feasibility tolerance ϵ, maximum iterations
    T.
Output: Optimized [symbol]    .
  1: Randomly initialize [symbol]    ;
  2: [symbol]     := [symbol]    , [symbol]     := 0;
  3: while ∥ [symbol]   ^{t} − [symbol]    ^{t}∥ > ϵ and t ≤ T do
  4: Updating [symbol]     via (16);
  5: Updating [symbol]     via (17) (Algorithm 1);
  6: Updating [symbol]     via (13);
  7: end
```

### 6.3. Fine-Tuning

In some embodiments, upon dual optimization problem-regularized training, decompose the trained uncompressed DNN model may be decomposed into tensor decomposed. Here the decomposition may be performed with the target TT-ranks r* for tensor cores. Because the optimization procedure has already imposed the desired low TT-rank structure to the uncompressed model, such direction decomposition, unlike their counterpart in the existing tensor decomposed format DNN training, may be not bring significant approximation error (more detail may be provided below in Section 7.1). In some embodiments, the decomposed tensor decomposed format model may then be fine-tuned using standard stochastic gradient descent or other suitable optimization method. In some embodiments, in the fine-tuning phase the loss function is [symbol] ({ [symbol] ᵢ}) may be formulated without another regularization term that would be introduced by the dual optimization problem. In some embodiments, the fine-tuning phase may be very fast relative to the initial training, e.g., requiring only a few iterations. In some embodiments, the speed of tine-tuning may be because the decomposed TT model at the starting point of the fine-tuning phase may benefit from decreased accuracy loss relative to the original uncompressed model.

### 7 Experiments

To demonstrate the effectiveness and generality of the compression framework, examples of different DNN models in different computer vision tasks may be evaluated. For image classification tasks, multiple CNN models may be evaluated on MNIST, CIFAR-10, CIFAR-100 and ImageNet datasets. For video classification tasks, different LSTM models may be evaluated on UCF11 and HMDB51 datasets. To simplify selection procedure, some, all or more than half of the ranks in the same layer may be set to equal.

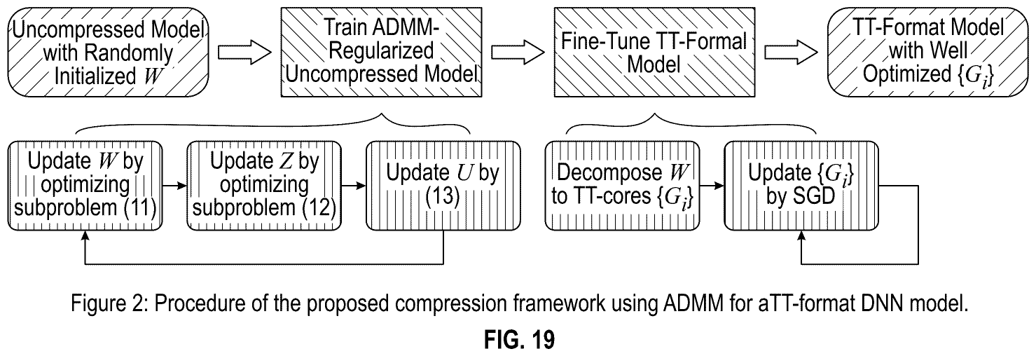

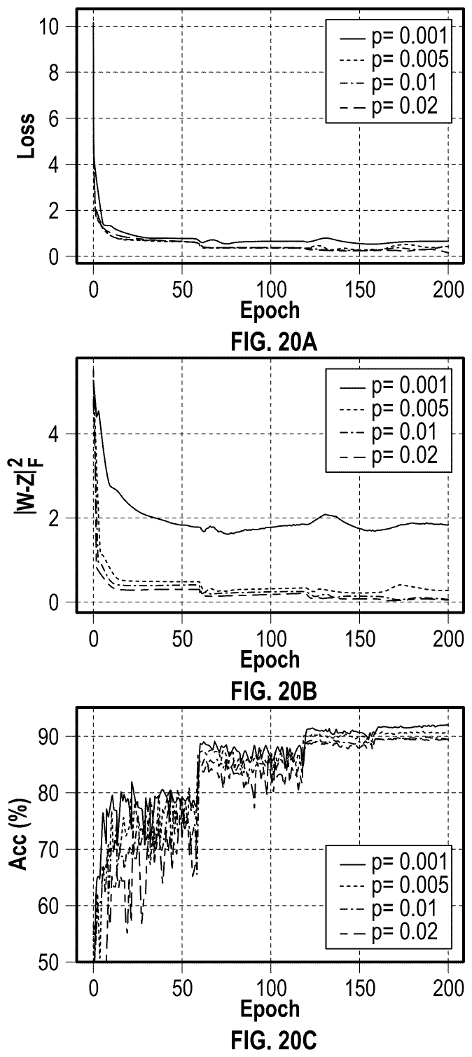

FIGS. 20A through 20C illustrate training loss, Frobenius norm and test accuracy in dual optimization problem-regularized training procedure with different ρ in accordance with one or more embodiments of the present disclosure.

### 7.1. Convergence and Sensitivity Analysis

In some embodiments, as shown in (26), ρ is the additional hyperparameter introduced in the dual optimization problem-regularized training phase. To study the effect of p on the performance as well as facilitating hyperparameter selection, we study the convergence and sensitivity of the ADMM-regularized training for ResNet-32 model with different p settings on CIFAR-10 dataset.

In some embodiments, as shown in FIG. 20A, the loss curves in the dual optimization problem-regularized training phase. As shown in FIG. 20A, different curves with very different ρ values (e.g., 0.001 vs 0.02) may exhibit comparable convergence speed. This phenomenon therefore demonstrates that ρ has little impact on the convergence of dual optimization problem-regularized training.

In some embodiments, considering the similar convergence behavior does not necessarily mean that different ρ would bring the similar accuracy, the performance sensitivity of dual optimization problem-regularized training with respect to ρ may be analyzed. In some embodiments, after dual optimization problem-regularized training, W, in the uncompressed format, may exhibit strong low TT-rank characteristics and meanwhile enjoy high accuracy. Once [symbol] meets such two criteria concurrently, the TT-cores{ [symbol] ᵢ}, whose initialization is decomposed from [symbol] , may have high accuracy even before fine-tuning.

In some embodiments, to examine the required low TT-rank behavior of [symbol] , ∥ [symbol] − [symbol] ∥_{F}², which measures the similarity between [symbol] and [symbol] , may be observed in the dual optimization problem-regularized training (see FIG. 20B). Since according to (33) [symbol] is always updated with low TT-rank constraints, the curves shown in FIG. 20B reveal that [symbol] indeed quickly exhibits low TT-rank characteristics during the training, except when ρ=0.001. This phenomenon indicates that to ensure the weight tensors are well regularized to the target TT-ranks by the dual optimization problem, ρ may be not be too small (e.g., less than 0.001). On the other hand, FIG. 20C shows the test accuracy of [symbol] as training progresses. Here it is seen that smaller ρ tends to bring better performance. Based on these observations, ρ=0.005 may be an appropriate choice to let the trained W meet the aforementioned two criteria.

### 7.2. Image Classification

Table 10 shows the experimental results of LeNet-5 model on MNIST dataset. Embodiments of the present dual optimization problem-based tensor decomposed format model may be compared with the uncompressed model as well as a typical TT/TR-format. It is seen that embodiments of the present dual optimization problem-based compression may achieve the highest compression ratio and the best accuracy.

TABLE 10
LeNet-5 on MNIST dataset using different TT/TR-format
compression approaches.

| | Comp. | Top-1 | Comp. |
|---|---|---|---|
| Model | Method | (%) | Ratio |
| Uncompressed | — | 99.21 | 1.0\hat{ } |
| Standard TR | TR | 99.10 | 10.5\hat{ } |
| PSTRN-M | | 99.43 | 16.5\hat{ } |
| PSTRN-S | | 99.51 | 6.5\hat{ } |
| Standard TT | TT | 99.07 | 17.9\hat{ } |
| Ours | | 99.48 | 17.9\hat{ } |
| | | 99.51 | 8.3\hat{ } |

Table 11 compares embodiments of the present dual optimization problem-based tensor decomposed format ResNet-20 and ResNet-32 models with the typical TT/TR-format on CIFAR-10 dataset. For ResNet-20, it is seen that standard training on TT/TR-format models causes greater accuracy loss. Even for the typical design using some advanced techniques, such as heuristic rank selection (PSTRN-M/S) and reinforcement learning (TR-RL), the performance degradation is still larger than the dual optimization problem-regularization framework of the present disclosure, especially with high compression ratio 6.8 times. On the other side, with the same high compression ratio embodiments of the present dual optimization problem-based tensor decomposed format model has only 0.22% accuracy drop, which means 2.53% higher than the typical PSTRN-M. Furthermore, with moderate compression ratio 4.5 time embodiments of the present method may even outperform the uncompressed model with 0.22% accuracy increase.

TABLE 11
ResNet-20 and ResNet-32 on CIFAR-10 dataset using different
TT/TR-format compression approaches.

| | | | |
|---|---|---|---|
| | Comp. | Top-1 | Comp. |
| Model | Method | (%) | Ratio |

ResNet-20

| | | | |
|---|---|---|---|
| Uncompressed | — | 91.25 | 1.0\hat{ } |
| Standard TR | TR | 87.5 | 5.4\hat{ } |
| TR-RL | | 88.3 | 6.8\hat{ } |
| PSTRN-M | | 88.50 | 6.8\hat{ } |
| PSTRN-S | | 90.80 | 2.5\hat{ } |
| Standard TT | TT | 86.7 | 5.4\hat{ } |
| Ours | | 91.03 | 6.8\hat{ } |
| | | 91.47 | 4.5\hat{ } |

ResNet-32

| | | | |
|---|---|---|---|
| Uncompressed | — | 92.49 | 1.0\hat{ } |
| Standard TR | TR | 90.6 | 5.1\hat{ } |
| PSTRN-M | | 90.6 | 5.8\hat{ } |
| PSTRN-S | | 91.44 | 2.7\hat{ } |
| Standard TT | TT | 88.3 | 4.8\hat{ } |
| Ours | | 91.96 | 5.8\hat{ } |
| | | 92.87 | 4.8\hat{ } |

For ResNet-32, again, standard training on compressed models using TT or TR decomposition causes larger performance degradation than other techniques. The typical PSTRN-S/M indeed brings performance improvement, but the test accuracy is still not satisfied. Instead, embodiments of the present highly compressed (5.8 times) dual optimization problem-regularized tensor decomposed format model has 0.53% accuracy loss, which means it has 1.36% higher accuracy than PSTRN-M with the same compression ratio. More importantly, when compression ratio is relaxed to 4.8 times, embodiments of the present dual optimization problem-based tensor decomposed format model achieves 92.87%, which is even 0.38% higher than the uncompressed model.

Table 12 shows the experimental results on CIFAR-100 dataset. Again, embodiments of the present dual optimization problem-based tensor decomposed format model outperforms the typical techniques. For ResNet-20, with even higher compression ratio (5.6 times the dual optimization problem-based tensor decomposed format model versus 4.7 times in PSTRN-M), embodiments of the present model achieves 1.3% accuracy increase. With 2.3 times compression ratio, embodiments of the present model achieves 67.36% Top-1 accuracy, which is even 1.96% higher than the uncompressed model. For ResNet-32, with the same 5.2 times compression ratio, embodiments of the present approach brings 0.4% accuracy increase over the typical PSTRN-M. With the same 2.4 times compression ratio, embodiments of the present approach has 2.26% higher accuracy than PSTRN-S. embodiments of the present model even outperforms the uncompressed model with 2.21% accuracy increase.

TABLE 12
ResNet-20 and ResNet-32 on CIFAR-100 dataset using different
TT/TR-format compression approaches.

| | | | |
|---|---|---|---|
| | Comp. | Top-1 | Comp. |
| Model | Method | (%) | Ratio |

ResNet-20

| | | | |
|---|---|---|---|
| Uncompressed | — | 65.4 | 1.0\hat{ } |
| Standard TR | TR | 63.55 | 4.7\hat{ } |
| PSTRN-M | | 63.62 | 4.7\hat{ } |
| PSTRN-S | | 66.13 | 2.3\hat{ } |
| Standard TT | TT | 61.64 | 5.6\hat{ } |
| Ours | | 64.92 | 5.6\hat{ } |
| Ours | | 67.36 | 2.3\hat{ } |

ResNet-32

| | | | |
|---|---|---|---|
| Uncompressed | — | 68.10 | 1\hat{ } |
| Standard TR | TR | 66.70 | 4.8\hat{ } |
| PSTRN-M | | 66.77 | 5.2\hat{ } |
| PSTRN-S | | 68.05 | 2.4\hat{ } |
| Standard TT | TT | 62.90 | 4.6\hat{ } |
| Ours | | 67.17 | 5.2\hat{ } |
| Ours | | 70.31 | 2.4\hat{ } |

Table 13 shows the results of compressing ResNet-18 on ImageNet dataset. Because no prior TT/TR compression works report results on this dataset, a standard TT and TR-based training may be used for comparison. Embodiments of the present approach may also be compared with other compression methods, including pruning and matrix SVD. Since these works report FLOPs reduction instead of compression ratio, the FLOPs reduction brought by tensor decomposition according to embodiments of the present dual optimization problem-based tensor decomposed format model may be compared. It is shown that with the similar FLOPs reduction ratio (4.62 times), embodiments of the present dual optimization problem-based tensor decomposed format model has 1.83% and 1.18% higher accuracy than standard TT and TR, respectively. Compared with other compression approaches with non-negligible accuracy loss, embodiments of the present dual optimization problem-based tensor decomposed format model tensor decomposed format achieves better accuracy with more FLOPs reduction. In particular, with 2.47 times FLOPs reduction, embodiments of the present model has the same accuracy as the uncompressed baseline model.

TABLE 13
ResNet-18 on ImageNet dataset using compression approaches. The
uncompressed baseline model is from Torchvision. Note that the
reported Top-5 accuracy of FBS and FPGM in this table are obtained
from pruning the baselines with higher accuracy.

| | | | |
|---|---|---|---|
| | Comp. | Top-5 | |
| Model | Method | (%) | FLOPsÓ |

ResNet-18

| | | | |
|---|---|---|---|
| Uncompressed | — | 89.08 | 1.00\hat{ } |
| Standard TR | TR | 86.29 | 4.28\hat{ } |
| TRP | Matrix | 86.74 | 2.60\hat{ } |
| TRP + Nu | SVD | 86.61 | 3.18\hat{ } |
| DACP | Pruning | 87.60 | 1.89\hat{ } |
| FBS | | 88.22 | 1.98\hat{ } |
| FPGM | | 88.53 | 1.72\hat{ } |
| DSA | | 88.35 | 1.72\hat{ } |
| Standard TT | TT | 85.64 | 4.62\hat{ } |
| Ours | | 87.47 | 4.62\hat{ } |
| Ours | | 89.08 | 2.47\hat{ } |

### 7.3. Video Recognition

Table 14 compares embodiments of the present dual optimization problems-based tensor decomposed format LSTM with an uncompressed LSTM model and the typical TT-LSTM and TR-LSTM. Note that does not report the performance of PSTRN-M/S on UCF11 dataset.

From Table 14, it is seen that both TT-LSTM and TR-LSTM provide performance improvement and compression ratio improvement relative to the uncompressed LSTM due to the feature extraction capabilities of TT/TR-format LSTM models on the ultra-high-dimensional inputs. In comparison, embodiments of the present dual optimization problems-based tensor decomposed LSTM tensor decomposed format achieves even greater performance. With fewer parameters, embodiments of the present dual optimization problems-based tensor decomposed LSTM results in 2.1% higher top-1 accuracy than the typical TR-LSTM.

TABLE 14
LSTM on UCF11 dataset using different TT/TR-format compression
approaches.

| | Comp. | Top-1 | | Comp. |
|---|---|---|---|---|
| Model | Method | (%) | # Para. | Ratio |
| Uncompressed | — | 69.7 | 59M | 1.0\hat{ } |
| TR-LSTM | TR | 86.9 | 1,725 | 34.2K\hat{ } |
| TT-LSTM | TT | 79.6 | 3,360 | 17.6K\hat{ } |
| Ours | | 89.0 | 1,656 | 35.6K\hat{ } |

An Inception-V3 as the front-end pre-trained CNN model, and a backend uncompressed LSTM model may be compared to a dual optimization problems-based tensor decomposed version.

Table 15 summarizes the experimental results. It is seen that comparing with the typical TT/TR-format designs, embodiments of the present dual optimization problems-based tensor decomposed tensor decomposed format model results in greater performance. With the highest compression ratio (84.0 times), embodiments of the present model achieves 64.09% top-1 accuracy. Compared with the typical TR-LSTM, embodiments of the present model brings 3.35 times more compression ratio with additional 0.29% accuracy increase.

TABLE 15
LSTM on HMDB51 dataset using different TT/TR-format compression
approaches.

| | Comp. | Top-1 | | Comp. |
|---|---|---|---|---|
| Model | Method | (%) | # Para. | Ratio |
| Uncompressed | — | 62.9 | 16.8M | 1.0\hat{ } |
| TR-LSTM | TR | 63.8 | 0.67M | 25.0\hat{ } |
| PSTRN-M | | 59.67 | 0.36M | 46.7\hat{ } |
| PSTRN-S | | 60.04 | 0.48M | 34.7\hat{ } |
| TT-LSTM | TT | 62.24 | 0.67M | 25.0\hat{ } |
| Ours | | 64.09 | 0.20M | 84.0\hat{ } |

### 7.4. Discussion on Tensor Format and Generality

As described above, the dual optimization problem-based tensor decomposed format models consistently outperform the existing TT/TR-format models with higher accuracy and higher compression ratio over various datasets, thereby comprehensively demonstrating the huge benefits brought by embodiments of the present framework.

In some embodiments, embodiments of the present disclosure may use tensor train-format DNN models. However, because dual optimization problems such as ADMM are general optimization techniques, embodiments of the present framework may be easily applied for model compression using other tensor decomposition approaches, such as Tensor Ring (TR), Block-term (BT), Tucker, Hierarchical Tucker, singular value decomposition (SVD), higher-order singular value decomposition (HOSVD), etc. To adapt to other tensor decomposition scenario, the main modification on embodiments of the present framework is to modify the Euclidean projection (Algorithm 3) to make the truncating methods being compatible to the corresponding tensor decomposition methods.

### 8 Example—Rank Optimization via Tensor Core Hyperparameter Training

In some embodiments, as described above, training of a tensor decomposed format DNN may be further improved by leveraging the tensor rank as a hyperparameter during training. Selecting the optimal rank is very challenging. Different from the rank selection in matrix decomposition, where the rank is a scalar, the rank selection in tensor decomposition needs to identify the proper vector-format tensor ranks. As indicated in, exact determination of tensor ranks for linear tensor problem is theoretically NP-hard. Even worse, since a modern DNN model typically consists of tens or even hundreds of layers, the overall search space for determining the rank for the decomposed DNN model is extremely huge.

In some embodiments, to systematically overcome the rank selection challenge and obtain high-performance compressed DNN models within the desired memory budget (e.g., model size or computational cost), an optimization-based framework may be configured to automatically select the rank configurations for the tensor decomposed format DNN models. Embodiments of the present framework may integrate the rank selection procedure into the training procedure, and let the models automatically learn the suitable rank setting from the data. For example, as described above, the original complicated NP-hard rank selection problem may be relaxed to a tensor nuclear norm-regularized optimization problem with the constraint of model size for DNN training. After such reformulation, during the training procedure a suitable dual optimization problem technique may be used to solve this optimization problem via solving two sub-problems in an iterative way. Upon the end of this iterative solving, the suitable tensor ranks are automatically learned, and thereby bringing highly-compressed highly-accurate tensor decomposed format DNN models with target compression ratio. Herein, boldface calligraphic script letters denote tensor, e.g., eq. [symbol] 2-dimensional tensor is a matrix, and a 1-dimensional tensor is a vector, which are represented by boldface capital letters and boldface lower-case letters, respectively, e.g. A and a. Also, non-boldface letters with indices [symbol] (i₁, . . . , i_{d}), A(i, j) and a(i) denote the entry of d-dimensional tensor [symbol] , matrix A and vector a, respectively.

Let A=UΣV^{T} be the singular value decomposition (SVD) of matrix A. The shrinkage operation is defined as

[symbol]

(A)=UΣ_{T}V^{T}, Equation (36)

where Σ_{τ}=diag(max(σᵢ−τ), 0) denotes the i-th largest singular value.

Given a tensor [symbol] ∈ [symbol] ⁿ^{₁}^{×. . . ×n}^{_{d}} 2, the mode-k matricization (also called unfolding) of [symbol] is denoted as A₍ₖ₎∈ [symbol] ⁿ^{ₖ}⁽ⁿ^{ₖ}^{. . . n}^{_{k−1}}ⁿ^{ₖ₊₁}^{. . . n}^{_{d}}). The entry (i₁, . . . , i_{d}) of the given tensor is mapped to the entry (iₖ,j) of the unfolded matrix, e.g., [symbol] (i₁, . . , i_{d})=A₍ₖ₎(iₖ,j), where:

j=1+Σ_{p=1,p≠k}^{d}(iₚ−1)Jₚ with Jₚ=Π_{q=1,q≠k}^{p-1}n_{q}, Equation (37)

Based on the matricization, the following two operations may be defined as:

unfoldₖ( [symbol] )=A₍ₖ₎,

foldₖ(A₍ₖ₎)= [symbol] . Equation (38)

The Tucker rank of a d-dimensional tensor [symbol] is denoted as n-rank( [symbol] ), which is the tuple of the ranks of mode-k matricizations:

n−rank( [symbol] )=[R₁, . . . , R_{d}]; Equation (39)

where Rₖ=rank(A₍ₖ₎), and k=1, . . . , d.

The Tucker decomposition of a tensor [symbol] ∈ [symbol] ⁿ^{₁}^{×. . . ×n}^{_{d}} with n−rank( [symbol] )=[R₁, . . . , R_{d}] may be represented as:

[symbol]

(i₁, . . . , i_{d})=Σᵣ_{₁}_{, . . . , r}_{_{d}}^{R}^{₁}^{, . . . , R}^{_{d}} [symbol] (r₁, . . . , r_{d})B₁(r₁, i₁) . . . B_{d}(r_{d}, i_{d}), Equation (40)

where [symbol] ∈ [symbol] ^{R}^{₁}^{×. . . ×R}^{_{d}} is the core tensor and B₁∈ [symbol] ^{R}^{₁}^{×n}^{₁}, . . . , B_{d}∈ [symbol] ^{R}^{_{d}}^{×n}^{_{d}} are the factor matrices.

Considering a convolutional layer with kernel tensor [symbol] ∈ [symbol] ^{S×C×K×K}, the input tensor [symbol] ∈ [symbol] ^{W×H×C} is transformed into the output tensor [symbol] ∈ [symbol] ^{W′×H′×S} convolving with the kernel:

[symbol]

(w′, h′, s)=Σᵢ₌₁^{K}Σⱼ₌₁^{K}Σ_{c=1}^{C} [symbol] (s, c, i, j) [symbol] (w, h, c) with w=w; +i and h=h′+j−1, Equation (41)

where W′=W−K+1 and H′=H−K+1.

In some embodiments, in a Tucker-format convolutional layer, in order to retain the spatial information, the orders associated to the kernel size are not decomposed. This decomposing approach is called Tucker-2 decomposition, by which the kernel tensor may be represented as:

$$𝒲 ( s , c , i , j ) = {\sum }_{{r}_{1} = 1}^{{R}_{1}} {\sum }_{{r}_{2} = 1}^{{R}_{2}} C ( {r}_{1} , {r}_{2} , i , j ) {B}_{1} ( {r}_{1} , s ) {B}_{2} ( {r}_{2} , c ) , \qquad Equation ( 42 )$$

where [symbol] ∈ [symbol] ^{R}^{₁}^{×R}^{₂}^{×K×K}, B₁∈ [symbol] ^{R}^{₁}^{×S} and B₂∈ [symbol] ^{R}^{₂}^{×C}. Correspondingly, the Tucker rank of the decomposed kernel [symbol] is n−rank( [symbol] )=[R₁, R₂], R₁=rank(W₍₁₎), R₂=rank(W₍₂₎).

With the Tucker-2 format, the original full convolution layer is decomposed into a sequence of small convolutions, thus the output tensor is obtained by:

$${𝒯}_{1} ( w , h , {r}_{2} ) = {\sum }_{c = 1}^{C} {B}_{2} ( {r}_{2} , c ) 𝒳 ( w , h , e ) , \qquad Equation ( 43 )$$

$${𝒯}_{2} ( {w}^{′} , {h}^{′} , {r}_{1} ) = {\sum }_{i = 1}^{K} {\sum }_{j = 1}^{K} {\sum }_{{r}_{2} = 1}^{{R}_{2}} 𝒞 ( {r}_{1} , {r}_{2} , i , j ) {𝒯}_{1} ( w , h , {r}_{2} ) , \qquad Equation ( 44 )$$

$$y ( {w}^{′} , {h}^{′} , s ) = {\sum }_{{r}_{s} = 1}^{{R}_{1}} {B}_{1} ( {r}_{1} , s ) {𝒯}_{2} ( {w}^{′} , {h}^{′} , {r}_{1} ) , \\ where {𝒯}_{1} ∈ {ℝ}^{W \times H \times {R}_{2}} and {𝒯}_{2} ∈ {ℝ}^{{W}^{′} \times {H}^{′} \times {R}_{1}} . \qquad Equation ( 45 )$$

### 8.1 Problem Analysis & Formulation

Without loss of generality, we aim to compress an L-layer convolutional neural network (CNN) using Tucker decomposition. While Tucker decomposition is used here, Tucker decomposition is just an illustration of a particular form of tensor decomposition with the tensor cores used as a hyperparameter to be trained during the training process. Any suitable tensor decomposition may be used according to similar processes described below. To compress other types of DNNs, e.g., recurrent neural network (RNN), or use other tensor decomposition, e.g., tensor train or tensor ring, similar solution as described above may also be derived under the optimization framework. To simplify the notation, [symbol] may be used without subscript to represent the weight of all layers ({ [symbol] ᵢ}ᵢ₌₁^{L}, [symbol] ᵢ) is a 4-dimensional kernel tensor) and omit the bias parameters. The loss function is denoted by [symbol] ( [symbol] ) (e.g., crossentropy loss for classification task).

With such notation, embodiments of the present optimization framework is to minimize the loss function and the Tucker rank of each layer simultaneously, e.g., min [symbol] [symbol] ( [symbol] ) and min [symbol] n−rank( [symbol] ), with memory budget constraints to satisfy the target compression ratio. In some embodiments, decreasing the tensor ranks may lower the capacity of the CNN model, thus making it more difficult for the loss function to reach the optimal point. Therefore, the problem may be solved by identifying the loss in the acceptable range and while the tensor ranks also satisfy the compression demand. Since exact determination of tensor ranks for linear tensor problem is NP-hard, it is impossible to obtain the optimal tensor ranks via direct searching approaches.

In some embodiments, to overcome this challenge, based on the fact that the nuclear norm or trace norm ∥⋅∥, is the tightest surrogate for rank(⋅), the second objective may be relaxed and the original equation may be approximated in a reformulation as follows:

$${min}_{𝒲} ℓ ( 𝒲 ) + {‖ 𝒲 ‖}_{*} , \\ s . t . 𝒫 ( n - rank ( 𝒲 ) ) \leq {P}^{*} , \qquad Equation ( 46 )$$

where ∥ [symbol] ∥_{*} is the tensor nuclear norm of [symbol] , [symbol] (⋅) returns the overall model size with the current ranks, and [symbol] *, as the “memory budget”, is the desired model size after compression. The tensor nuclear norm of a d-dimensional tensor [symbol] is the convex combination of the nuclear norms of all unfolded matrices along each mode:

$${‖ 𝒳 ‖}_{*} = {\sum }_{i = 1}^{d} {α}_{i} {‖ {X}_{( i )} ‖}_{*} , \qquad Equation ( 47 )$$

where {αᵢ}ᵢ₌₁^{d} are constants that satisfy a αᵢ≥0 and Σᵢ₌₁^{d}αᵢ=1. Recall for the Tucker-2 convolution, only the first mode and the second mode are decomposed to retain the spatial information. Therefore, the tensor nuclear norm of the kernel tensor [symbol] is the sum of the nuclear norms of the mode-1 and mode-2 matricization:

∥ [symbol] ∥_{*}=α₁∥W₍₁₎∥_{*}α₂∥W₍₂₎∥_{*}. Equation (48)

In some embodiments, the dimensions of input channel and the output channel may have the same influence on the kernel tensor, thus a 1 and a 2 may be set to be equal such that they may be eliminated in the above equation. Hence, the formulated optimization equation (46) may be rewritten as:

$${min}_{𝒲} ℓ ( 𝒲 ) + {‖ {W}_{( 1 )} ‖}_{*} + {‖ {W}_{( 2 )} ‖}_{*} , \\ s . t . 𝒫 ( {R}_{1} , {R}_{2} ) \leq {P}^{*} . \qquad Equation ( 49 )$$

### 8.2 Automatic Compression: Learn the Tensor Ranks via Dual Optimization Problem-Based Optimization

Minimizing the objective that contains two entries-shared non-smooth nuclear norm terms (e.g., W₍₁₎ and W₍₂₎), as the problem format that Equation (43) exactly exhibits, is challenging. Therefore, in some embodiments, a dual optimization problem may provide an efficient optimization technique for problems containing non-smooth terms, e.g., via equation (49). Thus, in some embodiments, the objective may be transformed into a format that fits the dual optimization problem framework. For example, separate variables may be attributed to mode-1 and mode-2 matricizations of [symbol] , e.g., introduce auxiliary variables [symbol] ₁ and [symbol] ₂ whose shapes are identical to [symbol] such that [symbol] ₁_{₍₁₎}=W₍₁₎ and [symbol] ₂_{₍₂₎}=W₍₂₎. Then, with the introduced variables, the optimization equation (49) may be reformulated as:

$${min}_{𝒲 , {1}_{} , {2}_{}} ℓ ( 𝒲 ) + {‖ {Z}_{1 ( 1 )} ‖}_{*} + {‖ {Z}_{{2}_{( 2 )}} ‖}_{*} , \\ s . t . 𝒲 = {1}_{} , 𝒲 = {2}_{} , 𝒫 ( {R}_{1} , {R}_{2} ) \leq {P}^{*} . \qquad Equation ( 50 )$$

Hence, the corresponding augmented Lagrangian with dual multipliers of (50) may be defined as:

$${ℒ}_{ρ} ( 𝒲 , {1}_{} , {2}_{} , {ℳ}_{1} , {ℳ}_{2} ) = ℓ ( 𝒲 ) + {‖ {Z}_{{1}_{( 1 )}} ‖}_{*} + {‖ {Z}_{{2}_{( 2 )}} ‖}_{*} + 〈 𝒲 - {1}_{} , {ℳ}_{1} 〉 + 〈 𝒲 - {2}_{} , {ℳ}_{2} 〉 + \frac{ρ}{2} {‖ 𝒲 - {1}_{} ‖}_{F}^{2} + \frac{ρ}{2} {‖ 𝒲 - {2}_{} ‖}_{F}^{2} , \qquad Equation ( 51 )$$

Where [symbol] ₁ and [symbol] ₂ are the dual multipliers.

In some embodiments, the dual optimization problem technique may be directly applied with the augmented Lagrangian function and solve the equation iteratively.

8.2.1 Updating Step for Z₁;Z₂-Variable

In some embodiments, considering the terms in Equation (51) either contain [symbol] ₁ or [symbol] ₂ and they are independent non-negative functions, thus each [symbol] may be minimized with respect to [symbol] ₁ and [symbol] ₂ separately. Taking the sub-equation of [symbol] ₂ as a detailed example, the matrix form of [symbol] ₁ along mode-1 is updated by:

$$\begin{matrix}{Z}_{{1}_{( 1 )}}^{k + 1} = {arg min}_{{Z}_{{1}_{( 1 )}}} {‖ {Z}_{{1}_{( 1 )}} ‖}_{*} + 〈 {W}_{( 1 )}^{k} - {Z}_{{1}_{( 1 )}} , {M}_{{1}_{( 1 )}}^{k} 〉 + \\ \frac{ρ}{2} {‖ {W}_{( 1 )}^{k} - {Z}_{1 ( 1 )} ‖}_{F}^{2} \\ = {arg min}_{{Z}_{{1}_{( 1 )}}} {‖ {Z}_{{1}_{( 1 )}} ‖}_{*} + \\ \frac{ρ}{2} {‖ {W}_{( 1 )}^{k} - {Z}_{{1}_{( 1 )}} + {M}_{{1}_{( 1 )}}^{k} / ρ ‖}_{F}^{2}\end{matrix} , \qquad Equation ( 52 )$$

where k is the iteration step. According to, Equation (46) has the closed-form solution [symbol] _{τ}_{₁}(W^{k}₍₁₎+M₁_{₍₁₎}^{k}/ρ). Hence, [symbol] may be updated by:

[symbol]

₁^{k+1}=fold₁(S_{τ}_{₁}(W₍₁₎^{k}+M₁_{₍₁₎}^{k}/ρ)). Equation (53)

For updating [symbol] ₂, since this procedure is independent from [symbol] ₁-update, [symbol] ₂ may be updated in parallel using the similar way as follows:

[symbol]

₂^{k+1}=fold₂(S_{τ}_{₂}(W₍₂₎^{k}+M₂_{₍₂₎}^{k}/ρ)). Equation (54)

In such updating steps, the automatic determination of the Tucker ranks R₁ and R₂ may be performed via the shrinkage operation [symbol] (⋅) in Equation (47) and (48) with τ₁, τ₂ for the current iteration. In some embodiments, the singular value decomposition U₁diag(σ₁)V₁^{T}=W₍₁₎^{k}+M₁_{₍₁₎}^{k}/ρ and U₂diag(σ₂)V₂^{T}=W₍₂₎^{k}+M₂_{₍₂₎}^{k}/ρ may be computed, where the singular values σ₁_{ᵢ}, σ₂_{ᵢ} in σ₁, σ₂ are sorted in a decreasing order, respectively.

In some embodiments, τ₁ and τ₂ may then be calculated by solving the following 0-1 knapsack problem:

$${max}_{{s}_{1} , {s}_{2} ∈ \{ 0 , 1 \}} 〈 {σ}_{1} , {s}_{1} 〉 + 〈 {σ}_{2} , {s}_{2} 〉 , \\ s . t . 𝒫 ( {R}_{1} , {R}_{2} ) \leq {P}^{*} , \qquad Equation ( 55 )$$

where s₁ and s₂ are binary vectors. In some embodiments, the lengths of s₁ and s₂ may be identical to σ₁ and σ₂, respectively, and the number of non-zero elements in s₁ and s₂ may be equal to R₁ and R₂, respectively. Thus, once τ₁ and τ₂ are obtained, R₁ and R₂ are also correspondingly determined. In such knapsack problem, σ₁ and σ₂ may be the “profit” and [symbol] (⋅) is the “weight”. In some embodiments, to determine the optimal ranks, the selected “profit” may be maximized and the overall “weight” may be prevented from exceeding the memory budget. Although perfectly solving such 0-1 knapsack problem is very challenging, an efficient greedy algorithm may obtain sub-optimal solution with very low computational complexity. Thus, in some embodiments, the largest value in σ₁ and σ₂ may be selected every time. When the “weight” reaches the memory budget [symbol] *, the algorithm terminates. Hence, τ₁ and τ₂ may be set as the current selected values in σ₁ and σ₂. Correspondingly, R₁ and R₂ may be naturally obtained by:

R₁=max{i|σ₁ᵢ>τ₁, i=1, 2, . . . }, Equation (56)

R₂=max{i|σ₂ᵢ>τ₂, i=1, 2, . . . }. Equation (57)

Upon finding the solution, the singular values that are smaller than τ₁ and τ₂ are truncated.

### 8.2.2 Updating Step for w Variable

In some embodiments, after determining the tensor ranks and updating [symbol] ₁, [symbol] ₂-variable at the current iteration, [symbol] may be updated via minimizing [symbol] over [symbol] . In some embodiments, fixing all variables except [symbol] , the minimization of [symbol] ( [symbol] ) reformulates to minimizing a quadratic function:

$${min}_{𝒲} ℓ ( 𝒲 ) + 〈 𝒲 - {1}_{k}^{} , {ℳ}_{1}^{k} 〉 + 〈 𝒲 - {2}_{k}^{} , {ℳ}_{2}^{k} 〉 + \frac{ρ}{2} {‖ 𝒲 - {1}_{k}^{} ‖}_{F}^{2} + \frac{ρ}{2} {‖ 𝒲 - {2}_{k}^{} ‖}_{F}^{2} , \qquad Equation ( 58 )$$

which is differentiable. Hence, the gradient of [symbol] ( [symbol] ) over [symbol] is given by:

$$\frac{\partial {ℒ}_{ρ} ( 𝒲 )}{\partial 𝒲} = \frac{\partial ℓ ( 𝒲 )}{\partial 𝒲} + \frac{ρ}{2} ( 𝒲 - {𝒵}_{1}^{k} + {ℳ}_{1}^{k} / ρ ) + \frac{ρ}{2} ( 𝒲 - {𝒵}_{2}^{k} + {ℳ}_{2}^{k} / ρ ) . \qquad Equation ( 59 )$$

Then, in some embodiments, [symbol] may be updated by an optimization algorithm such as standard stochastic gradient descent as:

$${𝒲}^{k + 1} = {𝒲}^{k} - β \frac{\partial {ℒ}_{ρ} ( 𝒲 )}{\partial 𝒲} , \qquad Equation ( 60 )$$

where is the learning rate for DNN training.

In some embodiments, once [symbol] -variable is updated, another round of [symbol] ₁, [symbol] ₂-variable update may be performed based on the latest [symbol] -variable. Such iterative update may continue until the end of training procedure. After that, the desired tensor decomposed weight tensor are well trained and obtained. Meanwhile, the finally selected tensor ranks are automatically determined as the R₁ and R₂ calculated by Equation (56) (57) at the last iteration. Thus, in some embodiments, the overall procedure of the dual optimization problem-regularized training procedure with automatic rank selection may be summarized in Algorithm 5.

Algorithm 5: Dual Optimization Problem-Regularized Training
Algorithm with Automatic Tensor Rank Selection

1: Inputs: Weight tensor [symbol] , learning rate β, penalty parameter ρ, number of epochs T,
target compressing model size (“memory budget”) P*.
2: Output: Optimized weight tensor [symbol] , selected rank R₁ and R₂.
3: [symbol] ₁ := [symbol] , [symbol] ₂ = [symbol] ;
4: [symbol] ₁ := zeros_like( [symbol] );
5: [symbol] ₂ := zeros_like( [symbol] );
6: while k < T do
7: Obtain τ₁ and τ₂ by solving Equation (15);
8: Determine R₁ and R₂ using Equation (16) and (17);
9: Update [symbol] ₁^{k+1} using Equation (13);
10: Update [symbol] ₂^{k+1} using Equation (14);
11: Update [symbol] ^{k+1} using Equation (20);
12: [symbol] ₁^{k+1} = [symbol] ₁^{k} + ρ( [symbol] ₁^{k} − [symbol] ₁^{k});
13: [symbol] ₂^{k+1} = [symbol] ₂^{k} + ρ( [symbol] ₂^{k} − [symbol] ₂^{k});
14: End while

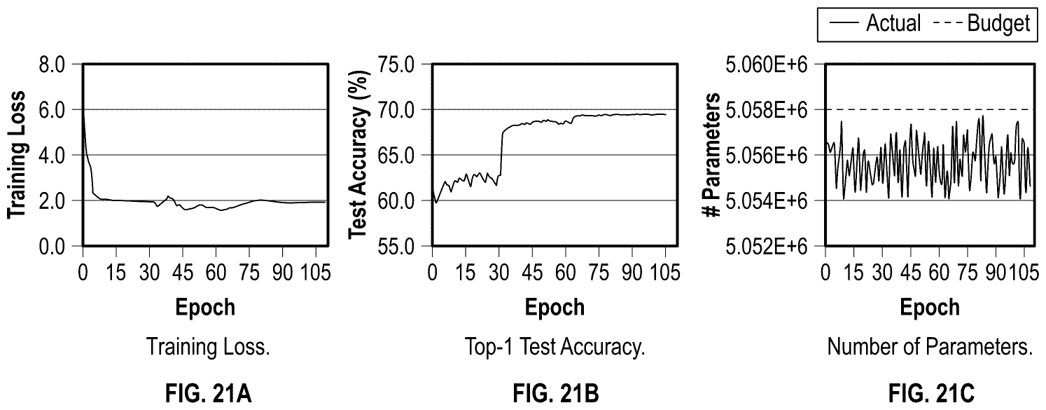

FIGS. 21A through 21C illustrate a change of (a) training loss and (b) Top-1 test accuracy, and (c) number of parameters during the training process for ResNet-18 on ImageNet dataset in accordance with aspects of embodiments of the present disclosure. The compression memory budget is set as 5.058×10⁶ parameters.

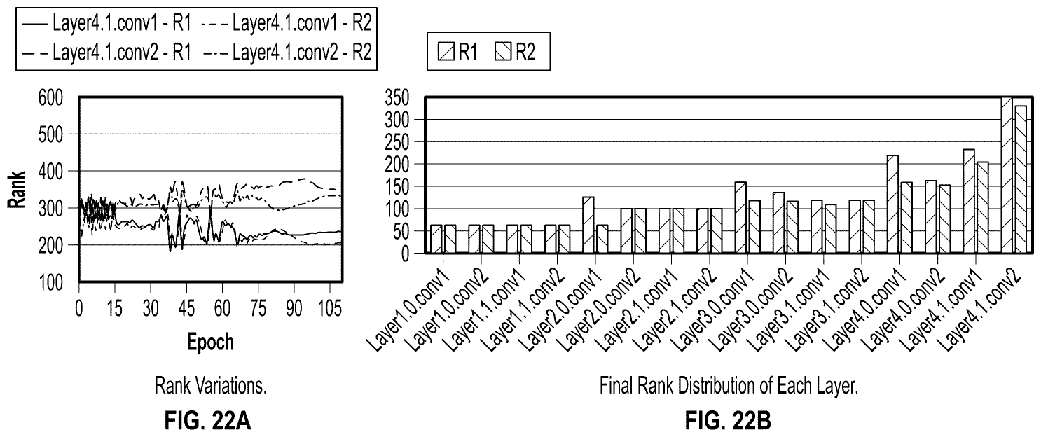

FIG. 22A and 22B illustrate (a) Rank variations for two example component convolutional layer during training, and (b) final rank distribution using embodiments of the present method of ResNet-18 on ImageNet dataset in accordance with aspects of embodiments of the present disclosure.

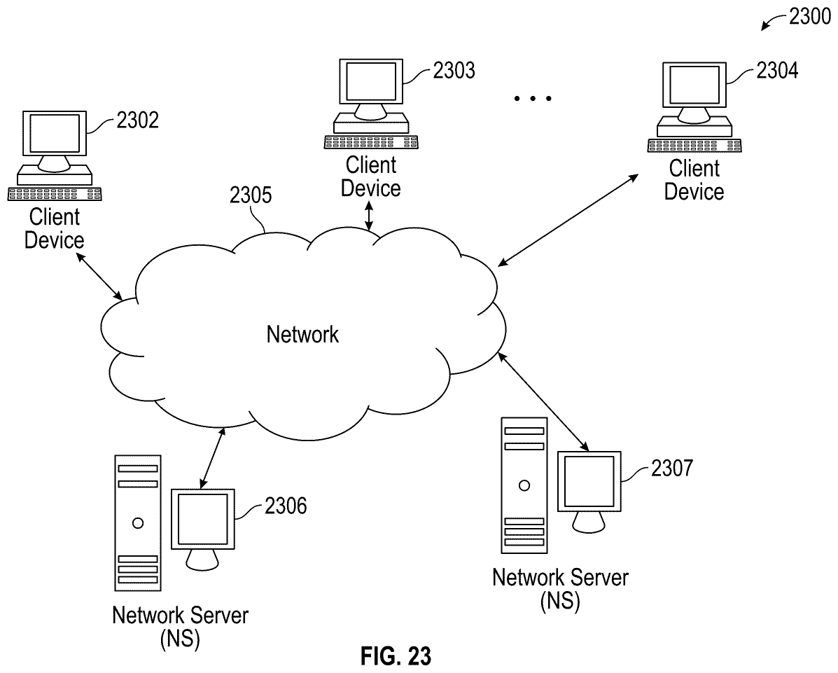

FIG. 23 depicts a block diagram of an exemplary computer-based system and platform 2300 in accordance with one or more embodiments of the present disclosure. However, not all of these components may be required to practice one or more embodiments, and variations in the arrangement and type of the components may be made without departing from the spirit or scope of various embodiments of the present disclosure. In some embodiments, the illustrative computing devices and the illustrative computing components of the exemplary computer-based system and platform 2300 may be configured to manage a large number of members and concurrent transactions, as detailed herein. In some embodiments, the exemplary computer-based system and platform 2300 may be based on a scalable computer and network architecture that incorporates varies strategies for assessing the data, caching, searching, and/or database connection pooling. An example of the scalable architecture is an architecture that is capable of operating multiple servers.

In some embodiments, referring to FIG. 23, member computing device 2302, member computing device 2303 through member computing device 2304 (e.g., clients) of the exemplary computer-based system and platform 2300 may include virtually any computing device capable of receiving and sending a message over a network (e.g., cloud network), such as network 2305, to and from another computing device, such as servers 2306 and 2307, each other, and the like. In some embodiments, the member devices 2302-2304 may be personal computers, multiprocessor systems, microprocessor-based or programmable consumer electronics, network PCs, and the like. In some embodiments, one or more member devices within member devices 2302-2304 may include computing devices that typically connect using a wireless communications medium such as cell phones, smart phones, pagers, walkie talkies, radio frequency (RF) devices, infrared (IR) devices, citizens band radio, integrated devices combining one or more of the preceding devices, or virtually any mobile computing device, and the like. In some embodiments, one or more member devices within member devices 2302-2304 may be devices that are capable of connecting using a wired or wireless communication medium such as a PDA, POCKET PC, wearable computer, a laptop, tablet, desktop computer, a netbook, a video game device, a pager, a smart phone, an ultra-mobile personal computer (UMPC), and/or any other device that is equipped to communicate over a wired and/or wireless communication medium (e.g., NFC, RFID, NBIOT, 3G, 4G, 5G, GSM, GPRS, WiFi, WiMax, CDMA, OFDM, OFDMA, LTE, satellite, ZigBee, etc.). In some embodiments, one or more member devices within member devices 2302-2304 may include may run one or more applications, such as Internet browsers, mobile applications, voice calls, video games, videoconferencing, and email, among others. In some embodiments, one or more member devices within member devices 2302-2304 may be configured to receive and to send web pages, and the like. In some embodiments, an exemplary specifically programmed browser application of the present disclosure may be configured to receive and display graphics, text, multimedia, and the like, employing virtually any web based language, including, but not limited to Standard Generalized Markup Language (SMGL), such as HyperText Markup Language (HTML), a wireless application protocol (WAP), a Handheld Device Markup Language (HDML), such as Wireless Markup Language (WML), WMLScript, XML, JavaScript, and the like. In some embodiments, a member device within member devices 2302-2304 may be specifically programmed by either Java, .Net, QT, C, C++, Python, PHP and/or other suitable programming language. In some embodiment of the device software, device control may be distributed between multiple standalone applications. In some embodiments, software components/applications may be updated and redeployed remotely as individual units or as a full software suite. In some embodiments, a member device may periodically report status or send alerts over text or email. In some embodiments, a member device may contain a data recorder which is remotely downloadable by the user using network protocols such as FTP, SSH, or other file transfer mechanisms. In some embodiments, a member device may provide several levels of user interface, for example, advance user, standard user. In some embodiments, one or more member devices within member devices 2302-2304 may be specifically programmed include or execute an application to perform a variety of possible tasks, such as, without limitation, messaging functionality, browsing, searching, playing, streaming or displaying various forms of content, including locally stored or uploaded messages, images and/or video, and/or games.

In some embodiments, the exemplary network 2305 may provide network access, data transport and/or other services to any computing device coupled to it. In some embodiments, the exemplary network 2305 may include and implement at least one specialized network architecture that may be based at least in part on one or more standards set by, for example, without limitation, Global System for Mobile communication (GSM) Association, the Internet Engineering Task Force (IETF), and the Worldwide Interoperability for Microwave Access (WiMAX) forum. In some embodiments, the exemplary network 2305 may implement one or more of a GSM architecture, a General Packet Radio Service (GPRS) architecture, a Universal Mobile Telecommunications System (UMTS) architecture, and an evolution of UMTS referred to as Long Term Evolution (LTE). In some embodiments, the exemplary network 2305 may include and implement, as an alternative or in conjunction with one or more of the above, a WiMAX architecture defined by the WiMAX forum. In some embodiments and, optionally, in combination of any embodiment described above or below, the exemplary network 2305 may also include, for instance, at least one of a local area network (LAN), a wide area network (WAN), the Internet, a virtual LAN (VLAN), an enterprise LAN, a layer 3 virtual private network (VPN), an enterprise IP network, or any combination thereof. In some embodiments and, optionally, in combination of any embodiment described above or below, at least one computer network communication over the exemplary network 2305 may be transmitted based at least in part on one of more communication modes such as but not limited to: NFC, RFID, Narrow Band Internet of Things (NBIOT), ZigBee, 3G, 4G, 5G, GSM, GPRS, WiFi, WiMax, CDMA, OFDM, OFDMA, LTE, satellite and any combination thereof. In some embodiments, the exemplary network 2305 may also include mass storage, such as network attached storage (NAS), a storage area network (SAN), a content delivery network (CDN) or other forms of computer or machine readable media.

In some embodiments, the exemplary server 2306 or the exemplary server 2307 may be a web server (or a series of servers) running a network operating system, examples of which may include but are not limited to Apache on Linux or Microsoft IIS (Internet Information Services). In some embodiments, the exemplary server 2306 or the exemplary server 2307 may be used for and/or provide cloud and/or network computing. Although not shown in FIG. 23, in some embodiments, the exemplary server 2306 or the exemplary server 2307 may have connections to external systems like email, SMS messaging, text messaging, ad content providers, etc. Any of the features of the exemplary server 2306 may be also implemented in the exemplary server 2307 and vice versa.

In some embodiments, one or more of the exemplary servers 2306 and 2307 may be specifically programmed to perform, in non-limiting example, as authentication servers, search servers, email servers, social networking services servers, Short Message Service (SMS) servers, Instant Messaging (IM) servers, Multimedia Messaging Service (MMS) servers, exchange servers, photo-sharing services servers, advertisement providing servers, financial/banking-related services servers, travel services servers, or any similarly suitable service-base servers for users of the member computing devices 2301-2304.

In some embodiments and, optionally, in combination of any embodiment described above or below, for example, one or more exemplary computing member devices 2302-2304, the exemplary server 2306, and/or the exemplary server 2307 may include a specifically programmed software module that may be configured to send, process, and receive information using a scripting language, a remote procedure call, an email, a tweet, Short Message Service (SMS), Multimedia Message Service (MMS), instant messaging (IM), an application programming interface, Simple Object Access Protocol (SOAP) methods, Common Object Request Broker Architecture (CORBA), HTTP (Hypertext Transfer Protocol), REST (Representational State Transfer), SOAP (Simple Object Transfer Protocol), MLLP (Minimum Lower Layer Protocol), or any combination thereof.

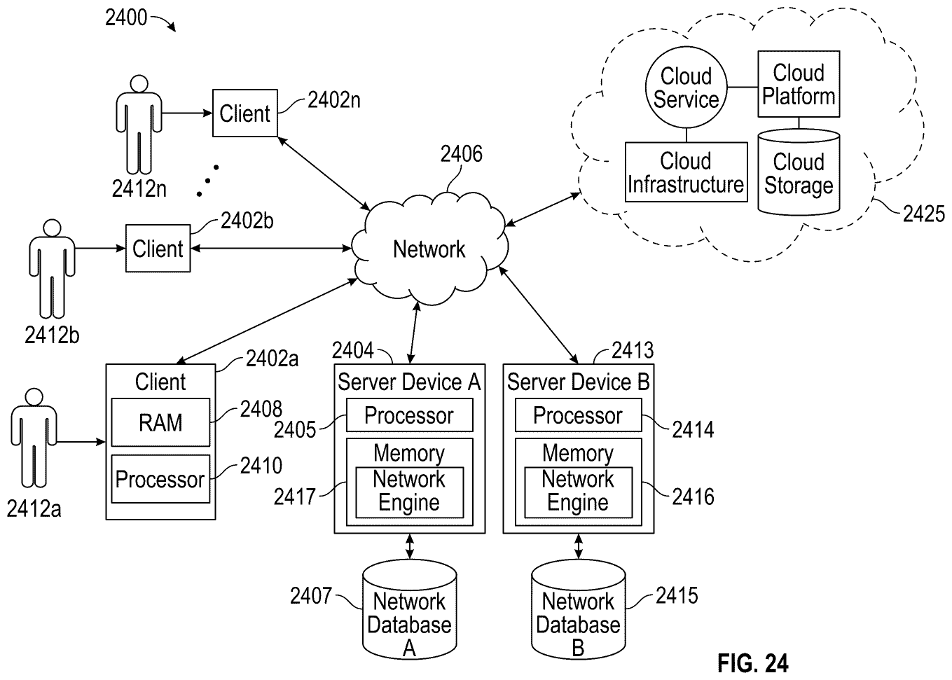

FIG. 24 depicts a block diagram of another exemplary computer-based system and platform 2400 in accordance with one or more embodiments of the present disclosure. However, not all of these components may be required to practice one or more embodiments, and variations in the arrangement and type of the components may be made without departing from the spirit or scope of various embodiments of the present disclosure. In some embodiments, the member computing device 2402a, member computing device 2402b through member computing device 2402n shown each at least includes a computer-readable medium, such as a random-access memory (RAM) 2408 coupled to a processor 2410 or FLASH memory. In some embodiments, the processor 2410 may execute computer-executable program instructions stored in memory 2408. In some embodiments, the processor 2410 may include a microprocessor, an ASIC, and/or a state machine. In some embodiments, the processor 2410 may include, or may be in communication with, media, for example computer-readable media, which stores instructions that, when executed by the processor 2410, may cause the processor 2410 to perform one or more steps described herein. In some embodiments, examples of computer-readable media may include, but are not limited to, an electronic, optical, magnetic, or other storage or transmission device capable of providing a processor, such as the processor 2410 of client 2402a, with computer-readable instructions. In some embodiments, other examples of suitable media may include, but are not limited to, a floppy disk, CD-ROM, DVD, magnetic disk, memory chip, ROM, RAM, an ASIC, a configured processor, all optical media, all magnetic tape or other magnetic media, or any other medium from which a computer processor may read instructions. Also, various other forms of computer-readable media may transmit or carry instructions to a computer, including a router, private or public network, or other transmission device or channel, both wired and wireless. In some embodiments, the instructions may comprise code from any computer-programming language, including, for example, C, C++, Visual Basic, Java, Python, Perl, JavaScript, and etc.

In some embodiments, member computing devices 2402a through 2402n may also comprise a number of external or internal devices such as a mouse, a CD-ROM, DVD, a physical or virtual keyboard, a display, or other input or output devices. In some embodiments, examples of member computing devices 2402a through 2402n (e.g., clients) may be any type of processor-based platforms that are connected to a network 2406 such as, without limitation, personal computers, digital assistants, personal digital assistants, smart phones, pagers, digital tablets, laptop computers, Internet appliances, and other processor-based devices. In some embodiments, member computing devices 2402a through 2402n may be specifically programmed with one or more application programs in accordance with one or more principles/methodologies detailed herein. In some embodiments, member computing devices 2402a through 2402n may operate on any operating system capable of supporting a browser or browser-enabled application, such as Microsoft™, Windows™, and/or Linux. In some embodiments, member computing devices 2402a through 2402n shown may include, for example, personal computers executing a browser application program such as Microsoft Corporation's Internet Explorer™, Apple Computer, Inc.'s Safari™, Mozilla Firefox, and/or Opera. In some embodiments, through the member computing client devices 2402a through 2402n, user 2412a, user 2412b through user 2412n, may communicate over the exemplary network 2406 with each other and/or with other systems and/or devices coupled to the network 2406. As shown in FIG. 24, exemplary server devices 2404 and 2413 may include processor 2405 and processor 2414, respectively, as well as memory 2417 and memory 2416, respectively. In some embodiments, the server devices 2404 and 2413 may be also coupled to the network 2406. In some embodiments, one or more member computing devices 2402a through 2402n may be mobile clients.

In some embodiments, at least one database of exemplary databases 2407 and 2415 may be any type of database, including a database managed by a database management system (DBMS). In some embodiments, an exemplary DBMS-managed database may be specifically programmed as an engine that controls organization, storage, management, and/or retrieval of data in the respective database. In some embodiments, the exemplary DBMS-managed database may be specifically programmed to provide the ability to query, backup and replicate, enforce rules, provide security, compute, perform change and access logging, and/or automate optimization. In some embodiments, the exemplary DBMS-managed database may be chosen from Oracle database, IBM DB2, Adaptive Server Enterprise, FileMaker, Microsoft Access, Microsoft SQL Server, My SQL, PostgreSQL, and a NoSQL implementation. In some embodiments, the exemplary DBMS-managed database may be specifically programmed to define each respective schema of each database in the exemplary DBMS, according to a particular database model of the present disclosure which may include a hierarchical model, network model, relational model, object model, or some other suitable organization that may result in one or more applicable data structures that may include fields, records, files, and/or objects. In some embodiments, the exemplary DBMS-managed database may be specifically programmed to include metadata about the data that is stored.

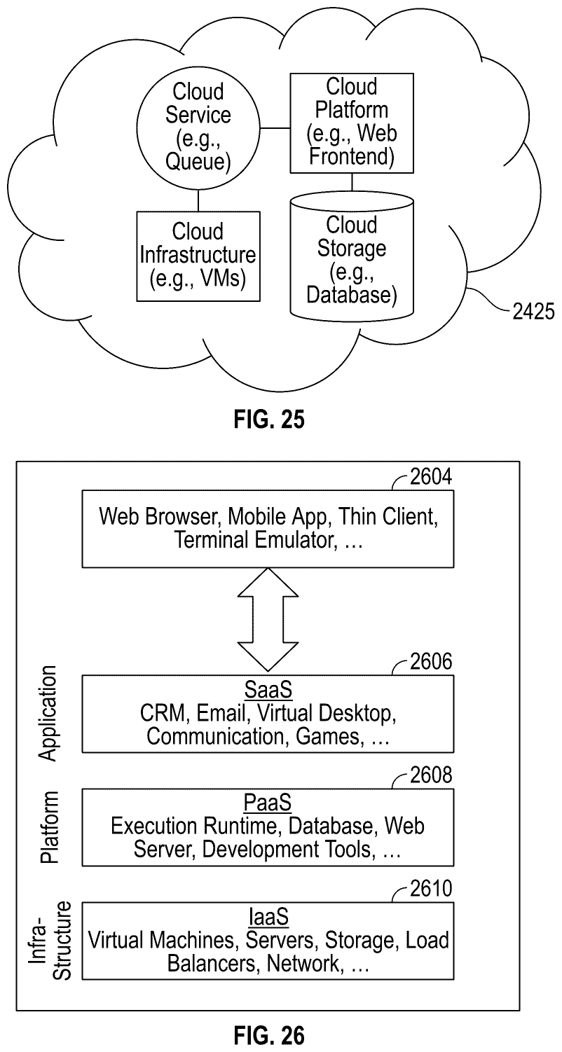

In some embodiments, the exemplary inventive computer-based systems/platforms, the exemplary inventive computer-based devices, and/or the exemplary inventive computer-based components of the present disclosure may be specifically configured to operate in a cloud computing/architecture 2425 such as, but not limiting to: infrastructure a service (IaaS) 2610, platform as a service (PaaS) 2608, and/or software as a service (SaaS) 2606 using a web browser, mobile app, thin client, terminal emulator or other endpoint 2604. FIGS. 25 and 26 illustrate schematics of exemplary implementations of the cloud computing/architecture(s) in which the exemplary inventive computer-based systems/platforms, the exemplary inventive computer-based devices, and/or the exemplary inventive computer-based components of the present disclosure may be specifically configured to operate.

It is understood that at least one aspect/functionality of various embodiments described herein may be performed in real-time and/or dynamically. As used herein, the term “real-time” is directed to an event/action that may occur instantaneously or almost instantaneously in time when another event/action has occurred. For example, the “real-time processing,” “real-time computation,” and “real-time execution” all pertain to the performance of a computation during the actual time that the related physical process (e.g., a user interacting with an application on a mobile device) occurs, in order that results of the computation may be used in guiding the physical process.

As used herein, the term “dynamically” and term “automatically,” and their logical and/or linguistic relatives and/or derivatives, mean that certain events and/or actions may be triggered and/or occur without any human intervention. In some embodiments, events and/or actions in accordance with the present disclosure may be in real-time and/or based on a predetermined periodicity of at least one of: nanosecond, several nanoseconds, millisecond, several milliseconds, second, several seconds, minute, several minutes, hourly, several hours, daily, several days, weekly, monthly, etc.

As used herein, the term “runtime” corresponds to any behavior that is dynamically determined during an execution of a software application or at least a portion of software application.

In some embodiments, exemplary inventive, specially programmed computing systems and platforms with associated devices are configured to operate in the distributed network environment, communicating with one another over one or more suitable data communication networks (e.g., the Internet, satellite, etc.) and utilizing one or more suitable data communication protocols/modes such as, without limitation, IPX/SPX, X.25, AX.25, AppleTalk™, TCP/IP (e.g., HTTP), near-field wireless communication (NFC), RFID, Narrow Band Internet of Things (NBIOT), 3G, 4G, 5G, GSM, GPRS, WiFi, WiMax, CDMA, satellite, ZigBee, and other suitable communication modes.

In some embodiments, the NFC may represent a short-range wireless communications technology in which NFC-enabled devices are “swiped,” “bumped,” “tap” or otherwise moved in close proximity to communicate. In some embodiments, the NFC could include a set of short-range wireless technologies, typically requiring a distance of 10 cm or less. In some embodiments, the NFC may operate at 13.56 MHz on ISO/IEC 18000-3 air interface and at rates ranging from 106 kbit/s to 424 kbit/s. In some embodiments, the NFC may involve an initiator and a target; the initiator actively generates an RF field that may power a passive target. In some embodiment, this may enable NFC targets to take very simple form factors such as tags, stickers, key fobs, or cards that do not require batteries. In some embodiments, the NFC's peer-to-peer communication may be conducted when a plurality of NFC-enable devices (e.g., smartphones) within close proximity of each other.

The material disclosed herein may be implemented in software or firmware or a combination of them or as instructions stored on a machine-readable medium, which may be read and executed by one or more processors. A machine-readable medium may include any medium and/or mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others.

As used herein, the terms “computer engine” and “engine” identify at least one software component and/or a combination of at least one software component and at least one hardware component which are designed/programmed/configured to manage/control other software and/or hardware components (such as the libraries, software development kits (SDKs), objects, etc.).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether an embodiment is implemented using hardware elements and/or software elements may vary in accordance with any number of factors, such as desired computational rate, power levels, heat tolerances, processing cycle memory budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores,” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, etc.).

In some embodiments, one or more of illustrative computer-based systems or platforms of the present disclosure may include or be incorporated, partially or entirely into at least one personal computer (PC), laptop computer, ultra-laptop computer, tablet, touch pad, portable computer, handheld computer, palmtop computer, personal digital assistant (PDA), cellular telephone, combination cellular telephone/PDA, television, smart device (e.g., smart phone, smart tablet or smart television), mobile internet device (MID), messaging device, data communication device, and so forth.

As used herein, term “server” may be understood to refer to a service point which provides processing, database, and communication facilities. By way of example, and not limitation, the term “server” may refer to a single, physical processor with associated communications and data storage and database facilities, or it may refer to a networked or clustered complex of processors and associated network and storage devices, as well as operating software and one or more database systems and application software that support the services provided by the server. Cloud servers are examples.

In some embodiments, as detailed herein, one or more of the computer-based systems of the present disclosure may obtain, manipulate, transfer, store, transform, generate, and/or output any digital object and/or data unit (e.g., from inside and/or outside of a particular application) that may be in any suitable form such as, without limitation, a file, a contact, a task, an email, a message, a map, an entire application (e.g., a calculator), data points, and other suitable data. In some embodiments, as detailed herein, one or more of the computer-based systems of the present disclosure may be implemented across one or more of various computer platforms such as, but not limited to: (1) FreeBSD, NetBSD, OpenBSD; (2) Linux; (3) Microsoft Windows™; (4) OpenVMS™; (5) OS X (MacOS™); (6) UNIX™; (7) Android; (8) iOS™; (9) Embedded Linux; (10) Tizen™; (11) WebOS™; (12) Adobe AIR™; (13) Binary Runtime Environment for Wireless (BREW™); (14) Cocoa™ (API); (15) Cocoa™ Touch; (16) Java™ Platforms; (17) JavaFX™; (18) QNX™; (19) Mono; (20) Google Blink; (21) Apple WebKit; (22) Mozilla Gecko™; (23) Mozilla XUL; (24) .NET Framework; (25) Silverlight™; (26) Open Web Platform; (27) Oracle Database; (28) Qt™; (29) SAP NetWeaver™; (30) Smartface™; (31) Vexi™; (32) Kubernetes™ and (33) Windows Runtime (WinRT™) or other suitable computer platforms or any combination thereof. In some embodiments, illustrative computer-based systems or platforms of the present disclosure may be configured to utilize hardwired circuitry that may be used in place of or in combination with software instructions to implement features consistent with principles of the disclosure. Thus, implementations consistent with principles of the disclosure are not limited to any specific combination of hardware circuitry and software. For example, various embodiments may be embodied in many different ways as a software component such as, without limitation, a stand-alone software package, a combination of software packages, or it may be a software package incorporated as a “tool” in a larger software product.

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

In some embodiments, illustrative computer-based systems or platforms of the present disclosure may be configured to handle numerous concurrent users that may be, but is not limited to, at least 100 (e.g., but not limited to, 100-999), at least 1,000 (e.g., but not limited to, 1,000-9,999), at least 10,000 (e.g., but not limited to, 10,000-99,999), at least 100,000 (e.g., but not limited to, 100,000-999,999), at least 1,000,000 (e.g., but not limited to, 1,000,000-9,999,999), at least 10,000,000 (e.g., but not limited to, 10,000,000-99,999,999), at least 100,000,000 (e.g., but not limited to, 100,000,000-999,999,999), at least 1,000,000,000 (e.g., but not limited to, 1,000,000,000-999,999,999,999), and so on.

In some embodiments, illustrative computer-based systems or platforms of the present disclosure may be configured to output to distinct, specifically programmed graphical user interface implementations of the present disclosure (e.g., a desktop, a web app., etc.). In various implementations of the present disclosure, a final output may be displayed on a displaying screen which may be, without limitation, a screen of a computer, a screen of a mobile device, or the like. In various implementations, the display may be a holographic display. In various implementations, the display may be a transparent surface that may receive a visual projection. Such projections may convey various forms of information, images, or objects. For example, such projections may be a visual overlay for a mobile augmented reality (MAR) application.

In some embodiments, illustrative computer-based systems or platforms of the present disclosure may be configured to be utilized in various applications which may include, but not limited to, gaming, mobile-device games, video chats, video conferences, live video streaming, video streaming and/or augmented reality applications, mobile-device messenger applications, and others similarly suitable computer-device applications.

As used herein, the term “mobile electronic device,” or the like, may refer to any portable electronic device that may or may not be enabled with location tracking functionality (e.g., MAC address, Internet Protocol (IP) address, or the like). For example, a mobile electronic device may include, but is not limited to, a mobile phone, Personal Digital Assistant (PDA), Blackberry™, Pager, Smartphone, or any other reasonable mobile electronic device.

As used herein, terms “proximity detection,” “locating,” “location data,” “location information,” and “location tracking” refer to any form of location tracking technology or locating method that may be used to provide a location of, for example, a particular computing device, system or platform of the present disclosure and any associated computing devices, based at least in part on one or more of the following techniques and devices, without limitation: accelerometer(s), gyroscope(s), Global Positioning Systems (GPS); GPS accessed using Bluetooth™; GPS accessed using any reasonable form of wireless and non-wireless communication; WiFi™ server location data; Bluetooth™ based location data; triangulation such as, but not limited to, network based triangulation, WiFi™ server information based triangulation, Bluetooth™ server information based triangulation; Cell Identification based triangulation, Enhanced Cell Identification based triangulation, Uplink-Time difference of arrival (U-TDOA) based triangulation, Time of arrival (TOA) based triangulation, Angle of arrival (AOA) based triangulation; techniques and systems using a geographic coordinate system such as, but not limited to, longitudinal and latitudinal based, geodesic height based, Cartesian coordinates based; Radio Frequency Identification such as, but not limited to, Long range RFID, Short range RFID; using any form of RFID tag such as, but not limited to active RFID tags, passive RFID tags, battery assisted passive RFID tags; or any other reasonable way to determine location. For ease, at times the above variations are not listed or are only partially listed; this is in no way meant to be a limitation.

As used herein, terms “cloud,” “Internet cloud,” “cloud computing,” “cloud architecture,” and similar terms correspond to at least one of the following: (1) a large number of computers connected through a real-time communication network (e.g., Internet); (2) providing the ability to run a program or application on many connected computers (e.g., physical machines, virtual machines (VMs)) at the same time; (3) network-based services, which appear to be provided by real server hardware, and are in fact served up by virtual hardware (e.g., virtual servers), simulated by software running on one or more real machines (e.g., allowing to be moved around and scaled up (or down) on the fly without affecting the end user).

In some embodiments, the illustrative computer-based systems or platforms of the present disclosure may be configured to securely store and/or transmit data by utilizing one or more of encryption techniques (e.g., private/public key pair, Triple Data Encryption Standard (3DES), block cipher algorithms (e.g., IDEA, RC2, RCS, CAST and Skipjack), cryptographic hash algorithms (e.g., MD5, RIPEMD-160, RTRO, SHA-1, SHA-2, Tiger (TTH),WHIRLPOOL, RNGs).

As used herein, the term “user” shall have a meaning of at least one user. In some embodiments, the terms “user”, “subscriber” “consumer” or “customer” may be understood to refer to a user of an application or applications as described herein and/or a consumer of data supplied by a data provider. By way of example, and not limitation, the terms “user” or “subscriber” may refer to a person who receives data provided by the data or service provider over the Internet in a browser session or may refer to an automated software application which receives the data and stores or processes the data.

The aforementioned examples are, of course, illustrative and not restrictive.

Publications cited throughout this document are hereby incorporated by reference in their entirety. While one or more embodiments of the present disclosure have been described, it is understood that these embodiments are illustrative only, and not restrictive, and that many modifications may become apparent to those of ordinary skill in the art, including that various embodiments of the inventive methodologies, the illustrative systems and platforms, and the illustrative devices described herein may be utilized in any combination with each other. Further still, the various steps may be carried out in any desired order (and any desired steps may be added and/or any desired steps may be eliminated).

What is claimed is:

1. A method comprising:
receiving, by at least one processor, at least:
i) a memory capacity metric defining a maximum memory size available;
ii) a model identifier that identifies a deep neural network, the deep neural network comprising at least one weight matrix that is arranged in at least one layer and comprises a plurality of weights; and
iii) a training data comprising a plurality of input data records and a plurality of ground truth data records;
wherein each input data record is associated with a corresponding ground truth data record;
wherein the corresponding ground truth data record defines a ground truth output;
training, by the at least one processor, based on the training data and an optimization problem, the deep neural network to produce a trained deep neural network by iteratively updating the at least one layer of the deep neural network, at each iteration, with:
a rank value representing a tensor rank to apply to the at least one weight matrix, and
the plurality of weights of the at least one weight matrix upon decomposition to the tensor of the rank value;
wherein the optimization problem is configured to:
minimize the rank value at each iteration until the memory capacity metric is satisfied,
minimize a loss function based at least in part on the training data and the plurality of weights,
backpropagate the loss function to the plurality weights, and
stop iteratively updating the at least one layer upon the memory capacity metric being satisfied and the loss function being minimized within the memory capacity metric;
utilizing, by the at least one processor, a tensor-based decomposition to compress the trained deep neural network based at least in part on the rank value and the plurality of weights to obtain a trained tensor decomposition format deep neural network;
training, by the at least one processor, the trained tensor decomposition format deep neural network based at least in part on the training data to obtain a fine-tuned trained tensor decomposition format deep neural network; and
deploying, by the at least one processor, the fine-tuned trained tensor decomposition format deep neural network to at least one hardware device that satisfies the memory capacity metric.

2. The method of claim 1, wherein the tensor-based decomposition comprises at least one of:
tensor train decomposition,
tensor ring decomposition,
singular value decomposition (SVD),
higher-order singular value decomposition (HOSVD),
Tucker decomposition,
hierarchical Tucker decomposition, or
block term decomposition.

3. The method of claim 1, wherein the optimization problem comprises a dual problem optimization method.

4. The method of claim 3, wherein the dual problem optimization method comprises dual ascent method (DAM).

5. The method of claim 3, wherein the dual problem optimization method comprises dual decomposition.

6. The method of claim 3, wherein the dual problem optimization method comprises Alternating Direction Method of Multipliers (ADMM).

7. The method of claim 1, further comprising:
determining, by the at least one processor, a minimum tensor rank based at least in part on the memory capacity metric; and
terminating, by the at least one processor, the iteratively updating of the at least one layer of the deep neural network upon the rank value reaching the minimum tensor rank.

8. The method of claim 1, wherein the deep neural network comprises at least one of:
a transformer,
a multi-layer perceptron,
a convolutional neural network, or
a recurrent neural network.

9. The method of claim 8, wherein the transformer comprises at least one vision transformer.

10. The method of claim 1, wherein the at least one hardware device comprises an embedded internet-of-things (IoT) device.

11. A system comprising:
at least one processor; and
at least one non-transitory computer readable medium having software instructions stored thereon, wherein, upon execution of the software instructions, the at least one processor is configured to:
receive at least:
i) a memory capacity metric defining a maximum memory size available;
ii) a model identifier that identifies a deep neural network, the deep neural network comprising at least one weight matrix that is arranged in at least one layer and comprises a plurality of weights; and
iii) a training data comprising a plurality of input data records and a plurality of ground truth data records;
wherein each input data record is associated with a corresponding ground truth data record;
wherein the corresponding ground truth data record defines a ground truth output;
train based on the training data and an optimization problem, the deep neural network to produce a trained deep neural network by iteratively updating the at least one layer of the deep neural network, at each iteration, with:
a rank value representing a tensor rank to apply to the at least one weight matrix, and
the plurality of weights of the at least one weight matrix upon decomposition to the tensor of the rank value;
wherein the optimization problem is configured to:
minimize the rank value at each iteration until the memory capacity metric is satisfied,
minimize a loss function based at least in part on the training data and the plurality of weights,
backpropagate the loss function to the plurality weights, and
stop iteratively updating the at least one layer upon the memory capacity metric being satisfied and the loss function being minimized within the memory capacity metric;
utilize a tensor-based decomposition to compress the trained deep neural network based at least in part on the rank value and the plurality of weights to obtain a trained tensor decomposition format deep neural network;
train the trained tensor decomposition format deep neural network based at least in part on the training data to obtain a fine-tuned trained tensor decomposition format deep neural network; and
deploy the fine-tuned trained tensor decomposition format deep neural network to at least one hardware device that satisfies the memory capacity metric.

12. The system of claim 11, wherein the tensor-based decomposition comprises at least one of:
tensor train decomposition,
tensor ring decomposition,
singular value decomposition (SVD),
higher-order singular value decomposition (HOSVD),
Tucker decomposition,
hierarchical Tucker decomposition, or
block term decomposition.

13. The system of claim 11, wherein the optimization problem comprises a dual problem optimization system.

14. The system of claim 13, wherein the dual problem optimization system comprises dual ascent system (DAM).

15. The system of claim 13, wherein the dual problem optimization system comprises dual decomposition.

16. The system of claim 13, wherein the dual problem optimization system comprises Alternating Direction System of Multipliers (ADMM).

17. The system of claim 11, wherein, upon execution of the software instructions, the at least one processor is further configured to:
determine a minimum tensor rank based at least in part on the memory capacity metric; and
terminate the iteratively updating of the at least one layer of the deep neural network upon the rank value reaching the minimum tensor rank.

18. The system of claim 11, wherein the deep neural network comprises at least one of:
a transformer,
a multi-layer perceptron,
a convolutional neural network, or
a recurrent neural network.

19. The system of claim 18, wherein the transformer comprises at least one vision transformer.

20. The system of claim 11, wherein the at least one hardware device comprises an embedded internet-of-things (IoT) device.
